(19) United States
(12) Patent Application Publication
(10) Pub. No.: US 2016/0077440 A1
(43) Pub. Date: Mar. 17, 2016

(54) PATTERN PEELING METHOD, ELECTRONIC DEVICE AND METHOD FOR MANUFACTURING THE SAME

(71) Applicant: FUJIFILM CORPORATION, Tokyo (JP)

(72) Inventors: Tsukasa YAMANAKA, Haibara-gun (JP); Toru FUJIMORI, Haibara-gun (JP)

(73) Assignee: FUJIFILM CORPORATION, Tokyo (JP)

(21) Appl. No.: 14/946,206

(22) Filed: Nov. 19, 2015

Related U.S. Application Data
(63) Continuation of application No. PCT/JP2014/061859, filed on Apr. 28, 2014.

(30) Foreign Application Priority Data
May 20, 2013 (JP) 2013-106626
Apr. 25, 2014 (JP) 2014-091452

(51) Int. Cl. G03F 7/42

(52) U.S. Cl. CPC G03F 7/426; G03F 7/425

(57) ABSTRACT

The present invention has an object to provide a pattern peeling method which is excellent in peelability and causes less damage to a substrate, a method for manufacturing an electronic device, including the pattern peeling method, and an electronic device manufactured by the method for manufacturing an electronic device. The present invention includes a resist film forming step of applying an actinic ray-sensitive or radiation-sensitive resin composition onto a substrate to form a resist film; an exposing step of exposing the resist film; a developing step of developing the exposed resist film using a developing liquid containing an organic solvent to form a negative-type pattern; and a peeling step of peeling the negative-type pattern using the following liquid A or B:
A: a liquid containing a sulfoxide compound and/or an amide compound; or
B: a liquid containing sulfuric acid and hydrogen peroxide.

### CROSS REFERENCE TO RELATED APPLICATIONS

This application is a continuation of PCT International Application No. PCT/JP2014/061859 filed on Apr. 28, 2014, which claims priority under 35 U.S.C. §119(a) to Japanese Patent Application No. 2013-106626 filed on May 20, 2013 and Japanese Patent Application No. 2014-091452 filed on Apr. 25, 2014. Each of the above applications is hereby expressly incorporated by reference, in its entirety, into the present application.

### BACKGROUND OF THE INVENTION

The present invention relates to a pattern peeling method which is used for a process for manufacturing a semiconductor such as an IC, for the manufacture of a circuit board for a liquid crystal, a thermal head, or the like, and for a lithography process of photofabrication in addition to these; a method for manufacturing an electronic device, including the pattern peeling method; and an electronic device manufactured by the method for manufacturing an electronic device.

After resists for a KrF excimer laser (248 nm) were developed, an image forming method called chemical amplification has been used as an image forming method for a resist in order to compensate for a decrease in sensitivity due to light absorption. By way of an example of an image forming method for positive-type chemical amplification, an acid generator in exposed areas formed by exposure decomposes to generate an acid, the generated acid is used as a reaction catalyst through baking (PEB: Post Exposure Bake) after the exposure to change an alkali-insoluble group into an alkali-soluble group, and the exposed areas are remove by alkali development to form an image (see, for example, JP2010-61043A).

On the other hand, as various electronic device structures become finer using semiconductors or the like, patterns (resist patterns) in a lithography process are required to be finer.

In this regard, for example, JP2013-4820A discloses a pattern forming method including a step of forming a resist film on a substrate by a chemical amplification resist composition containing (A) a resin capable of increasing polarity by the action of an acid to decrease the solubility in a developing liquid containing an organic solvent and (B) a compound capable of generating an acid by irradiation with actinic rays or radiation; a step of exposing the resist film; and a step of developing the exposed resist film using a developing liquid containing an organic solvent to form a pattern (claim 1). JP2013-4820A describes a spirit for forming a pattern with fine pitches in a good and easy manner by the above method (paragraph [0020]).

On the other hand, the formed pattern is intended to protect a substrate from processing treatments such as etching, and is required to be peeled from the substrate after the processing treatments.

### SUMMARY OF THE INVENTION

In comparison of the method of JP2010-61043A with the method of JP2013-4820A, the both methods commonly increase the polarity of exposed areas by exposure. On the other hand, they are different from each other in that in the method of JP2010-61043A, the exposed areas are removed using an alkali developing liquid, whereas in the method of JP2013-4820A, the unexposed areas are removed using a developing liquid containing an organic solvent.

That is, the pattern formed by the method of JP2013-4820A is in a state where its polarity is increased by the action of an acid, which corresponds to the exposed areas in the method of JP2010-61043A. Accordingly, when the pattern formed by the method of JP2013-4820A is peeled from the substrate, a method of using an alkali developing liquid (for example, an aqueous alkali solution such as an aqueous tetramethylammonium hydroxide (TMAH) solution) used in the method of JP2010-61043A can be considered above all.

Under these circumstances, the present inventors have formed a negative-type pattern on a substrate such as a silicon wafer with reference to JP2013-4820A, and thus have peeled the negative-type pattern in a state where its polarity is increased by the action of an acid, using an aqueous alkali solution. As a result, it has become apparent that the peelability of the pattern is sufficient, but depending on the type of a substrate, there may be damage to the substrate according to the peeling treatment conditions (an alkali concentration, a treatment temperature, or a treatment time).

Considering this situation, the present invention has an object to provide a pattern peeling method which is excellent in peelability and causes less damage to a substrate.

The present inventors have conducted extensive studies on the above-described problems, and as a result, they have found that damage to a substrate is reduced while maintaining the peelability by peeling the formed negative-type pattern using a specific peeling solution, thereby completing the present invention. That is, the present inventors have found that the above-described problems can be solved by the following configurations.

(1) A pattern peeling method including:

a resist film forming step of applying an actinic ray-sensitive or radiation-sensitive resin composition onto a substrate to form a resist film;

an exposing step of exposing the resist film;

a developing step of developing the exposed resist film using a developing liquid containing an organic solvent to form a negative-type pattern; and

a peeling step of peeling the negative-type pattern using the following liquid (A) or (B):

(A) a liquid containing a sulfoxide compound and/or an amide compound; or

(B) a liquid containing sulfuric acid and hydrogen peroxide.

(2) The pattern peeling method as described in (1), in which the liquid (A) is a liquid containing at least one selected from the group consisting of dimethylsulfoxide and N-methylpyrrolidone.

(3) The pattern peeling method as described in (1) or (2), in which the actinic ray-sensitive or radiation-sensitive resin composition contains a resin capable of decreasing the solubility in a developing liquid containing an organic solvent by the action of an acid, and a compound capable of generating an acid by irradiation with actinic rays or radiation.

(4) The pattern peeling method as described in (3), in which the actinic ray-sensitive or radiation-sensitive resin composition further contains a hydrophobic resin.

(5) The pattern peeling method as described in any one of (1) to (4), in which the organic solvent is butyl acetate.

(6) A method for manufacturing an electronic device, including the pattern peeling method as described in any one of (1) to (5).

(7) An electronic device manufactured by the method for manufacturing the electronic device as described in (6).

As described below, according to the present invention, a pattern peeling method which is excellent in peelability and causes less damage to a substrate can be provided.

### DETAILED DESCRIPTION OF THE INVENTION

Hereinafter, embodiments of the present invention will be described in detail.

In citations for a group (atomic group) in the present specification, when the group is denoted without specifying whether it is substituted or unsubstituted, the group includes both a group having no substituent and a group having a substituent. For example, an “alkyl group” includes not only an alkyl group having no substituent (unsubstituted alkyl group) but also an alkyl group having a substituent (substituted alkyl group).

“Actinic ray(s)” or “radiation” in the present specification means, for example, a bright line spectrum of a mercury lamp or the like, far ultraviolet rays represented by an excimer laser, extreme ultraviolet rays (EUV light), X-rays, electron beams (EB), or the like. In addition, in the present invention, light means actinic rays or radiation.

“Exposure” in the present specification includes, unless otherwise specified, not only an exposure by a mercury lamp, far ultraviolet rays represented by an excimer laser, extreme ultraviolet rays, X-rays, EUV light, or the like, but also writing by particle rays such as electron beams and an ion beam.

In the present specification, “(meth)acryl-based monomer” refers to at least one monomer having a structure of “CH₂═CH—CO—” or “CH₂═C(CH₃)—CO—”. Similarly, “(meth)acrylate” and “(meth)acrylic acid” mean “at least one of acrylate and methacrylate” and “at least one of acrylic acid and methacrylic acid”, respectively.

Hereinafter, the pattern peeling method of the present invention will be described.

The pattern peeling method of the present invention includes at least the following four steps:

(1) a resist film forming step of applying an actinic ray-sensitive or radiation-sensitive resin composition onto a substrate to form a resist film;

(2) an exposing step of exposing the resist film;

(3) a developing step of developing the exposed resist film using a developing liquid containing an organic solvent to form a negative-type pattern; and

(4) a peeling step of peeling the negative-type pattern using the following liquid (A) or (B):

(A) a liquid containing a sulfoxide compound and/or an amide compound; or

(B) a liquid containing sulfuric acid and hydrogen peroxide.

Hereinafter, the respective steps ((1) to (4)) and arbitrary steps (a rinsing step, a heating step, and a dry etching step) will be described in detail.

[Step (1): Resist Film Forming Step]

The step (1) is a step of applying an actinic ray-sensitive or radiation-sensitive resin composition onto a substrate to form a resist film. First, the actinic ray-sensitive or radiation-sensitive resin composition will be described in detail, and then the procedure of the step will be described in detail.

<Actinic Ray-Sensitive or Radiation-Sensitive Resin Composition>

The actinic ray-sensitive or radiation-sensitive resin composition (hereinafter also referred to as a “resist composition”) used in the pattern peeling method of the present invention is not particularly limited, but it preferably contains a resin capable of decreasing the solubility in a developing liquid containing an organic solvent by the action of an acid, a compound capable of generating an acid by irradiation with actinic rays or radiation, and a solvent.

[1] Resin Capable of Decreasing Solubility in Developing Liquid Containing Organic Solvent by Action of Acid

Examples of the resin capable of decreasing the solubility in a developing liquid containing an organic solvent by the action of an acid include a resin (hereinafter also referred to as an “acid decomposable resin” or a “resin (A)”) having a group capable of decomposing by an action of an acid to generate a polar group (hereinafter also referred to as an “acid-decomposable group”), on either one or both of the main chain and the side chain of the resin.

It is preferable that the acid-decomposable group has a structure in which a polar group is protected by a group capable of leaving, by decomposing by the action of an acid. Preferred examples of the polar group include a carboxyl group, a phenolic hydroxyl group, a fluorinated alcohol group (preferably a hexafluoroisopropanol group), and a sulfonic acid group.

A preferred group as the acid-decomposable group is a group having a hydrogen atom thereof substituted with a group capable of leaving by an acid.

Examples of the group capable of leaving by an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ to R₀₂ each independently represent a hydrogen atom, an alkyl group, a cycloalkyl group, an aryl group, an aralkyl group, or an alkenyl group.

The acid-decomposable group is preferably a cumyl ester group, an enol ester group, an acetal ester group, a tertiary alkyl ester group, or the like, and more preferably a tertiary alkyl ester group. Further, in the case where pattern formation is carried out by exposure using KrF light or EUV light, or using irradiation with electron beams, an acid-decomposable group having a phenolic hydroxyl group is protected by a group capable of leaving by an acid.

The resin (A) preferably has a repeating unit having an acid-decomposable group.

Specific examples of this repeating unit are shown below.

In the specific examples, Rx represents a hydrogen atom, CH₃, CF₃, or CH₂OH. Rxa and Rxb each represent an alkyl group having 1 to 4 carbon atoms. Xa₁ represents a hydrogen atom, CH₃, CF₃, or CH₂OH. Z represents a substituent, and if present in plural numbers, plural numbers of Z's may be the same as or different from each other. The substituent represented by Z is not particularly limited, and examples thereof include an alkyl group (having 1 to 4 carbon atoms), a cycloalkyl group (having 3 to 8 carbon atoms), a halogen atom, an alkoxy group (having 1 to 4 carbon atoms), a carboxyl group, and an alkoxycarbonyl group (having 2 to 6 carbon atoms), with the number of carbon atoms being preferably 8 or less. Among these, a substituent having no heteroatom such as an oxygen atom, a nitrogen atom, and a sulfur atom is more preferred (still more preferably, for example, a group which is not an alkyl group substituted with a hydroxyl group, or the like), from the viewpoint of further improving dissolution contrast for a developing liquid including an organic solvent before and after acid-decomposition, a group formed only from hydrogen atoms and carbon atoms is still more preferred, and a linear or branched alkyl group, or a cycloalkyl group is particularly preferred. p represents 0 or a positive integer.

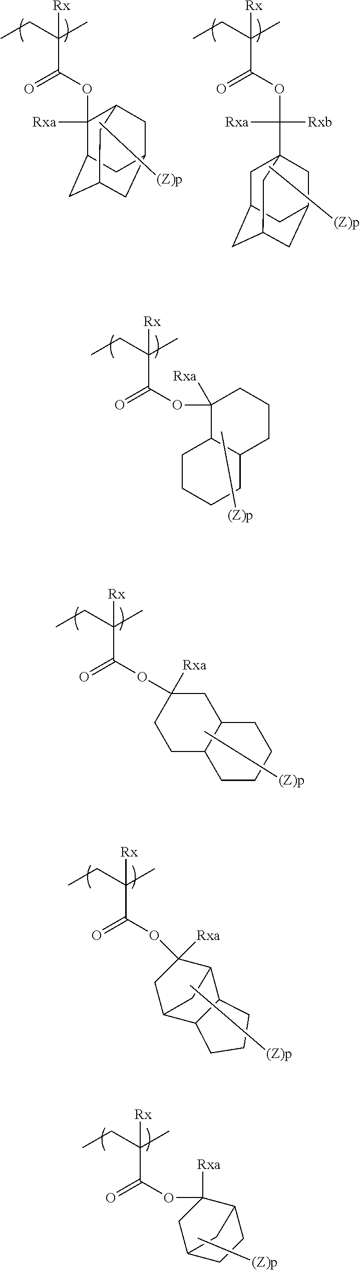

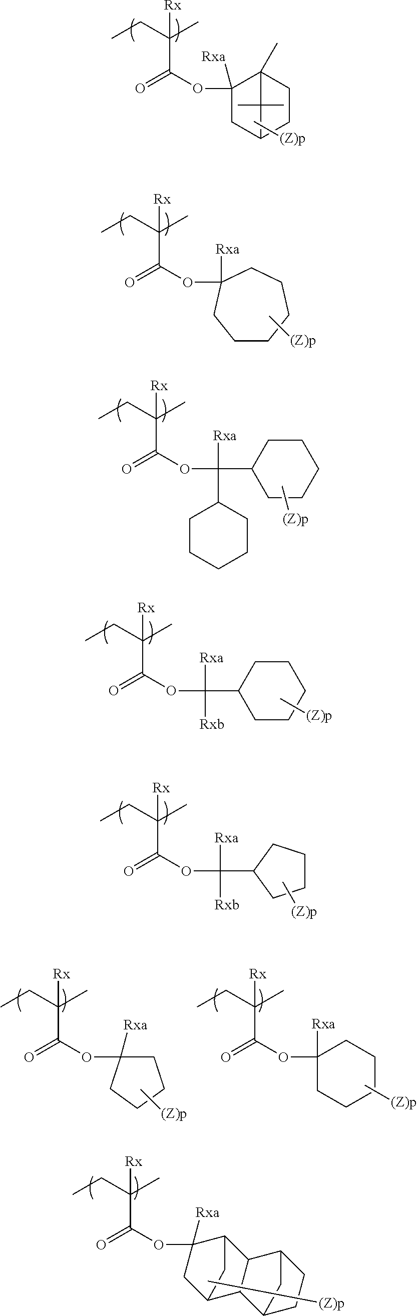

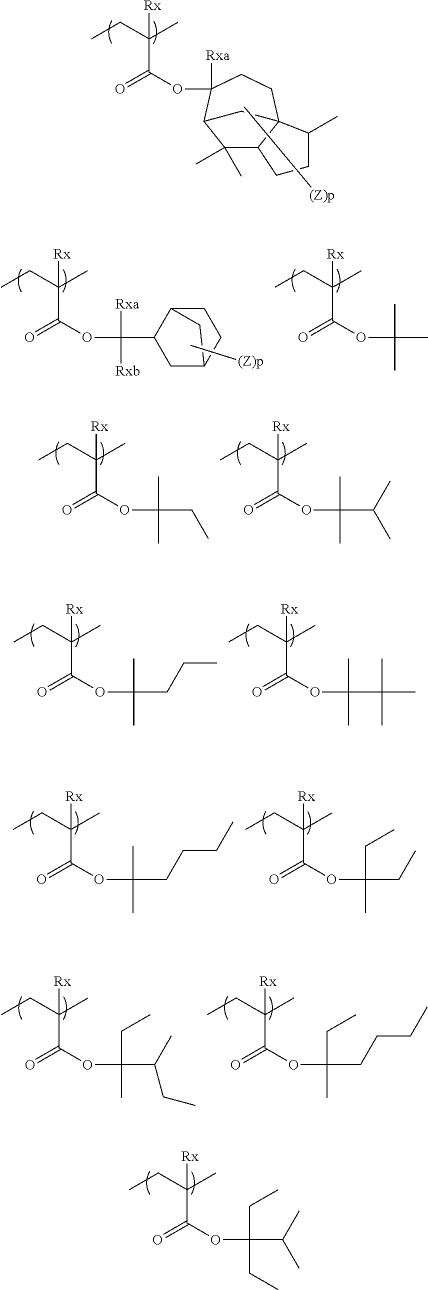

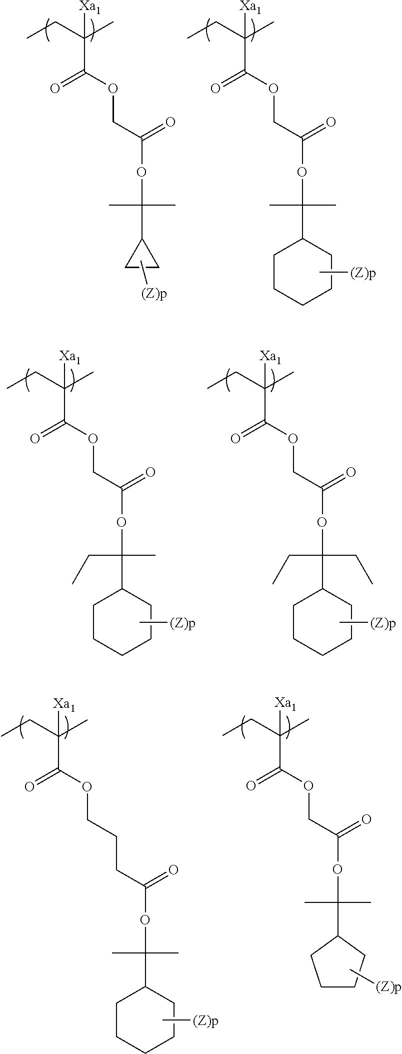

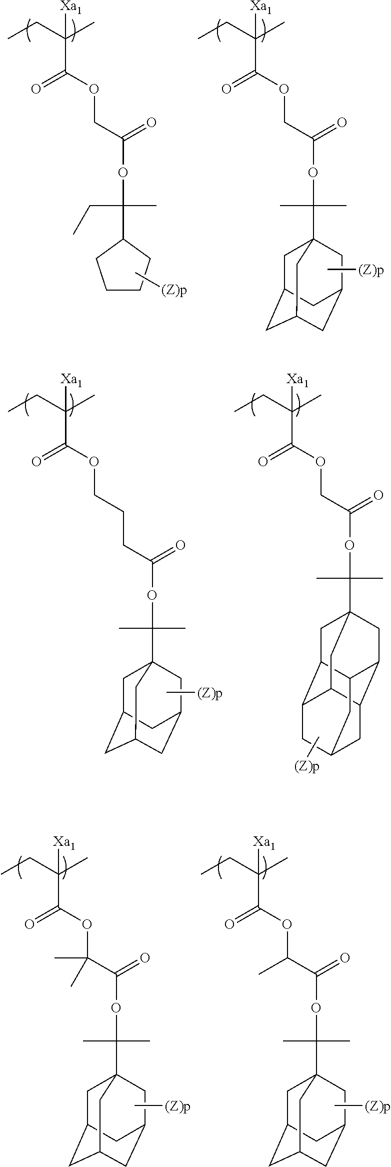

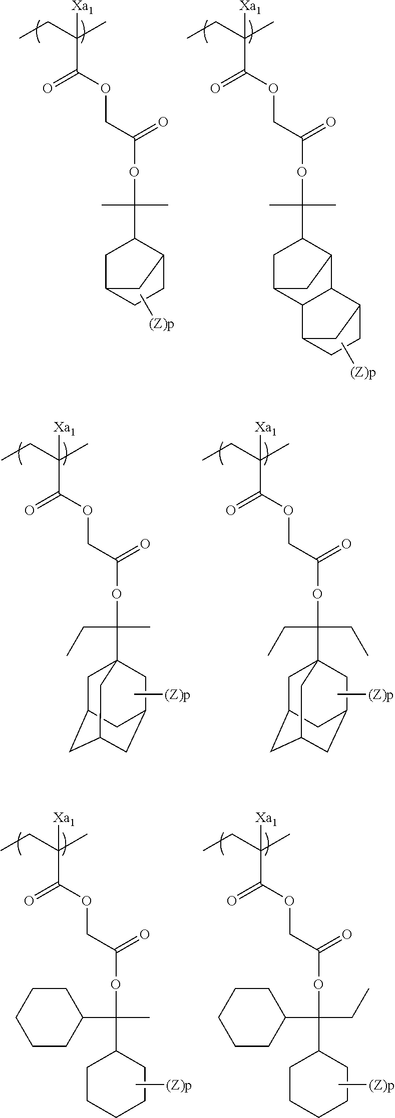

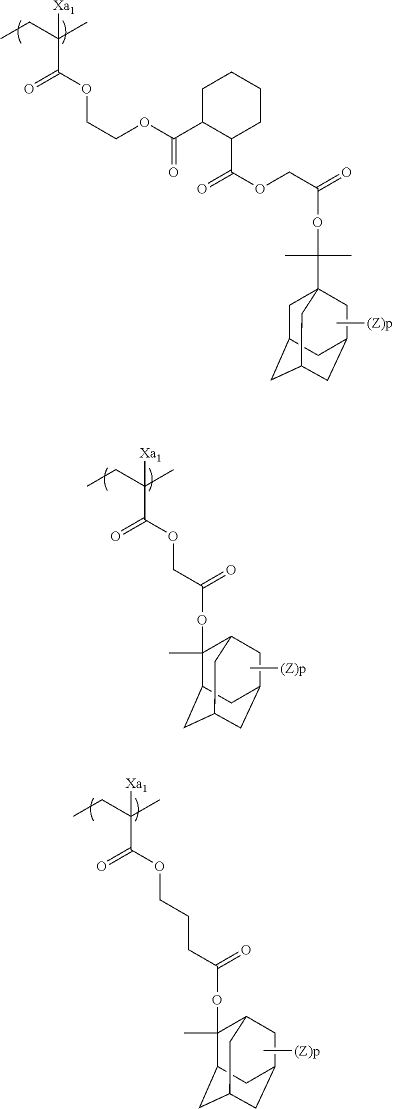

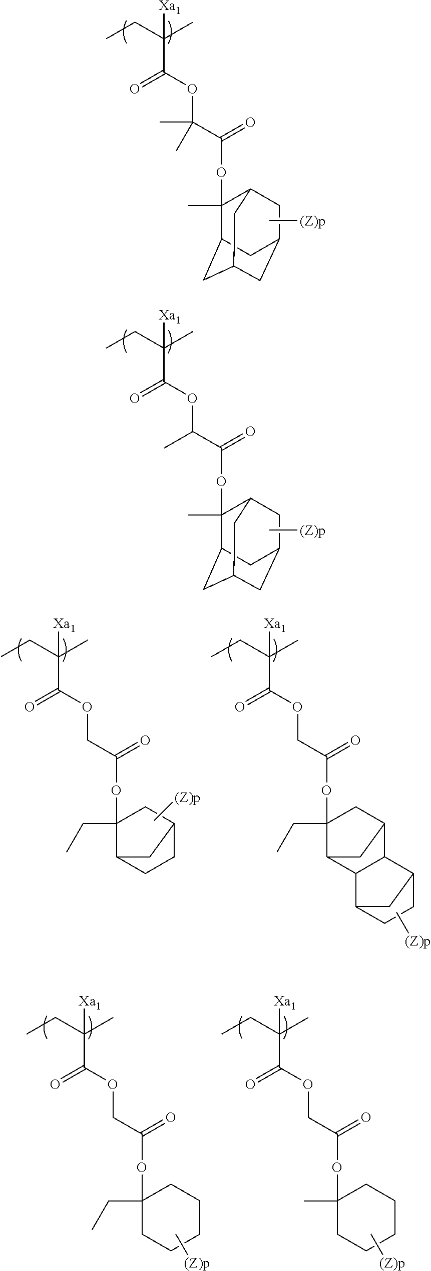

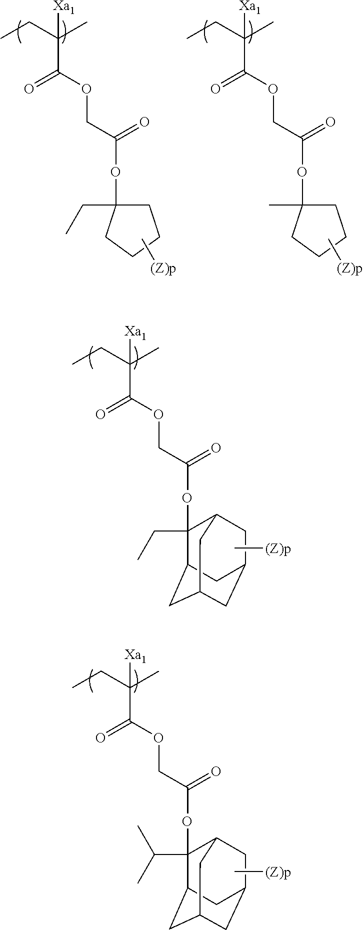

In the following specific examples, Xa represents a hydrogen atom, an alkyl group, a cyano group, or a halogen atom.

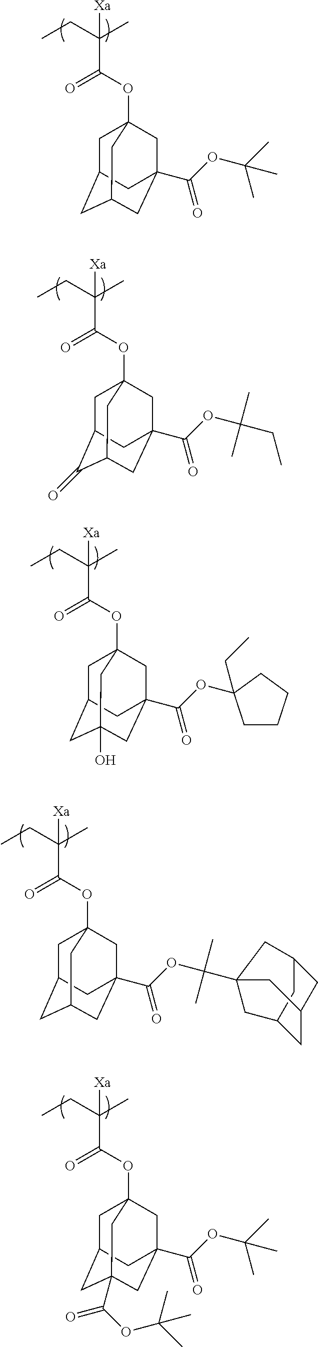

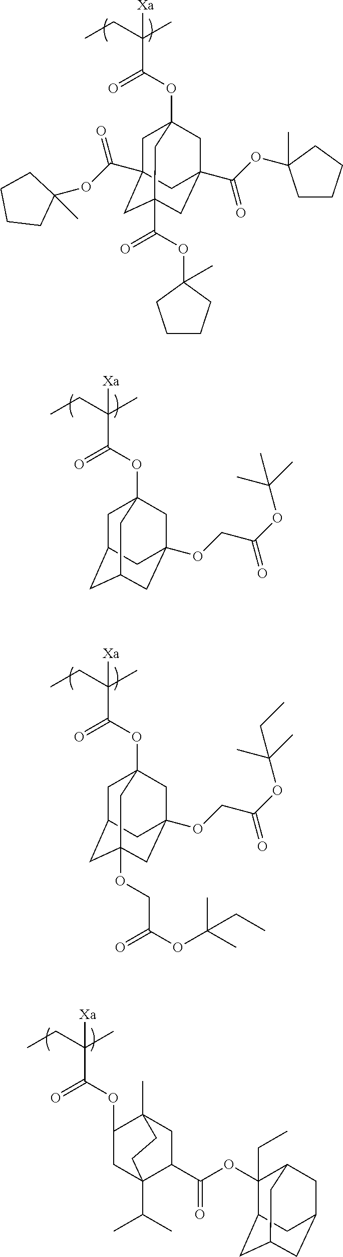

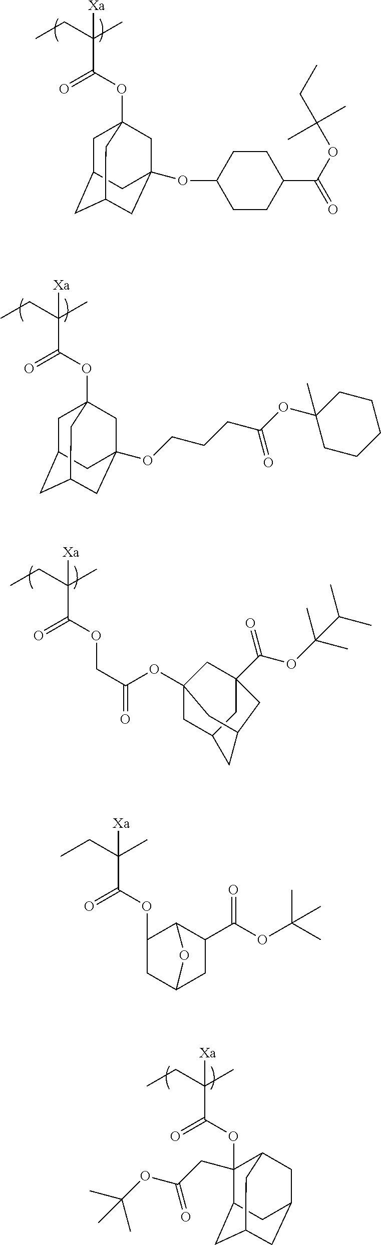

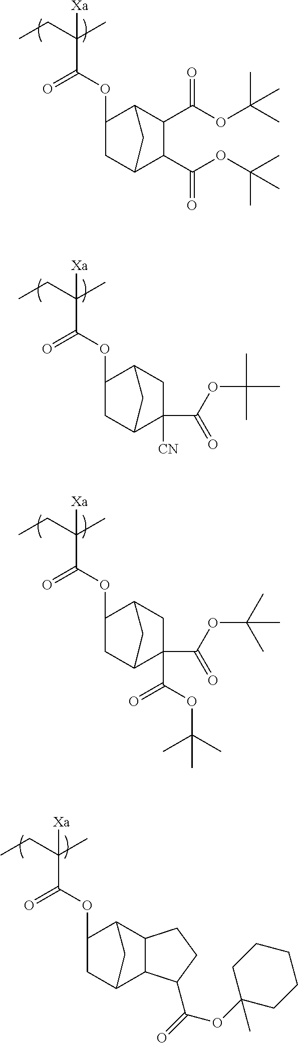

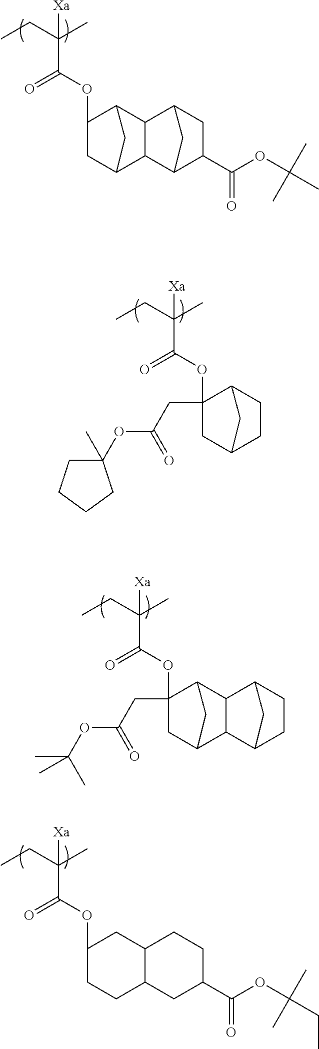

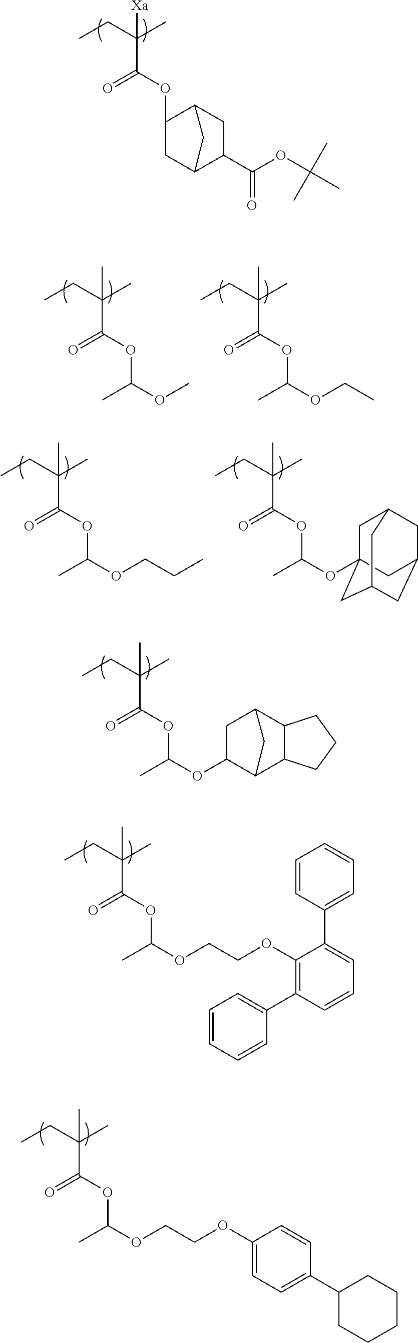

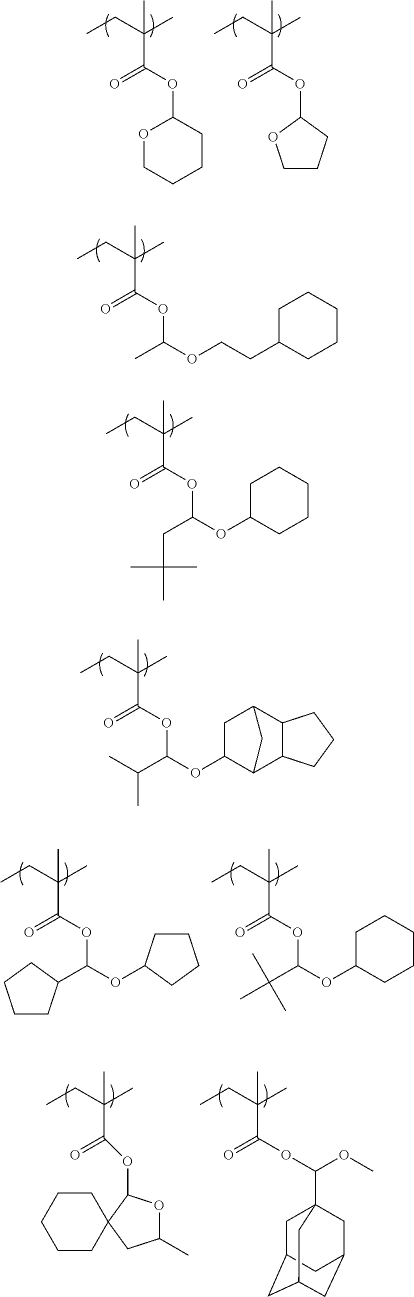

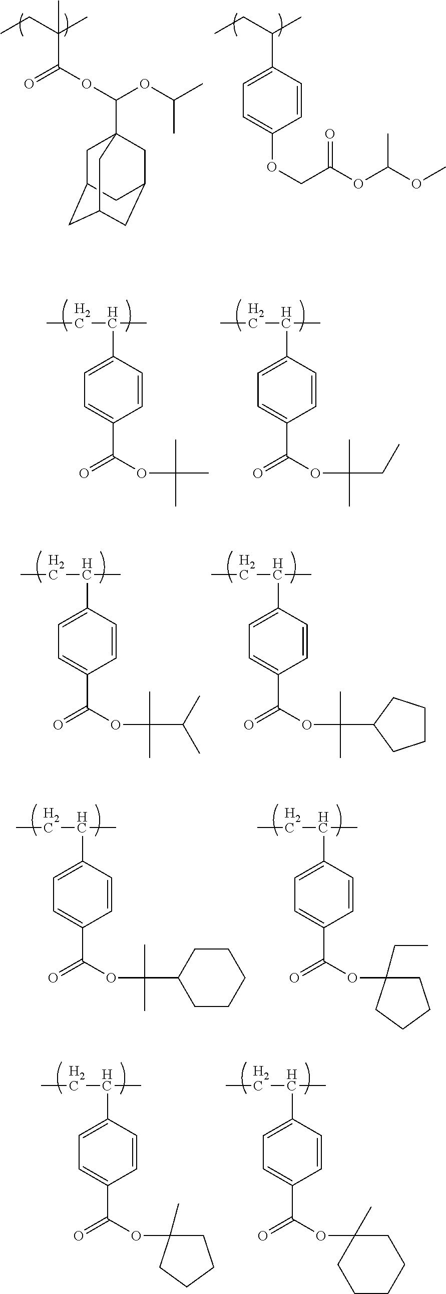

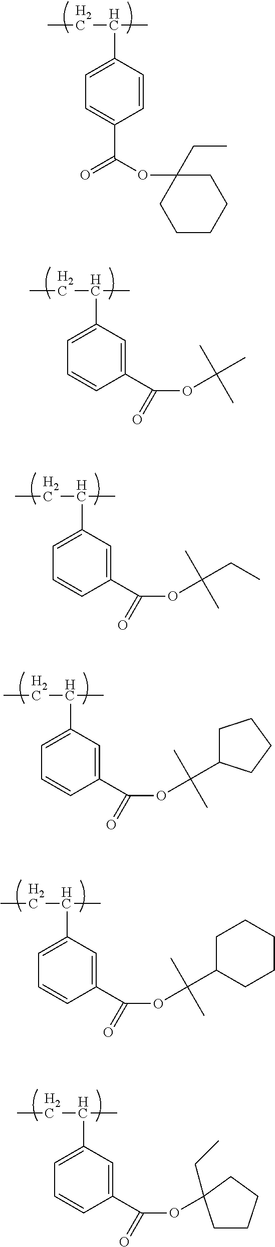

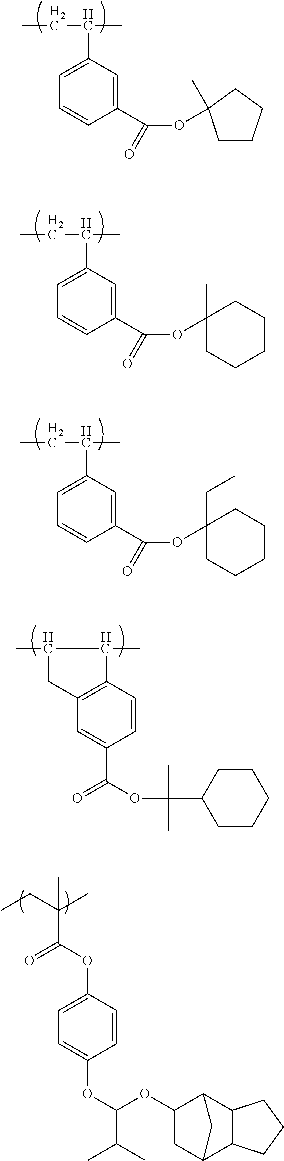

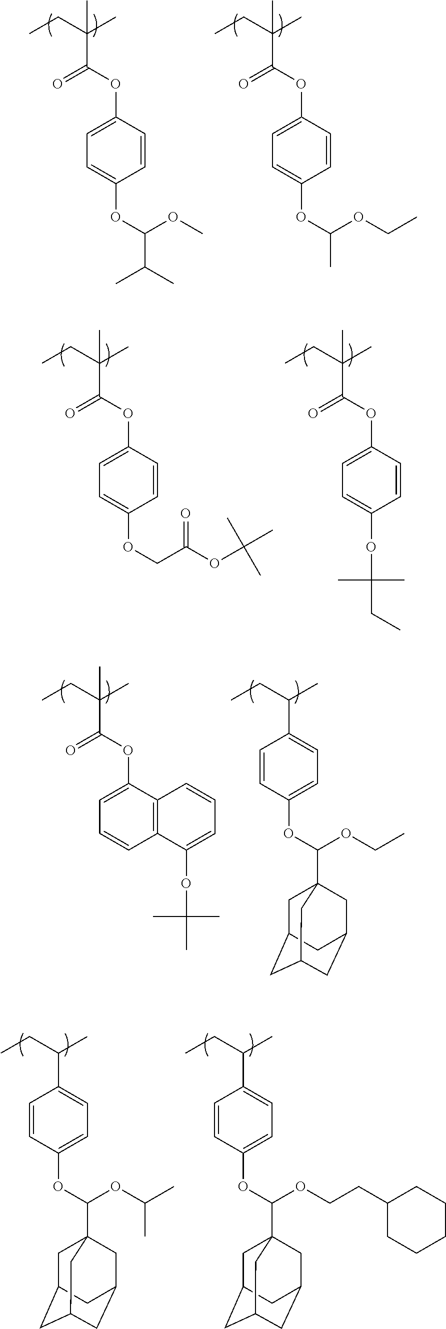

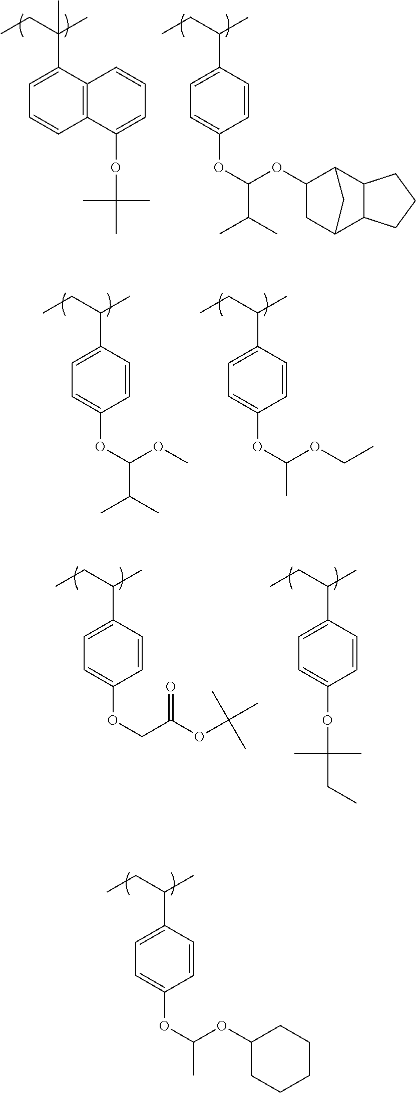

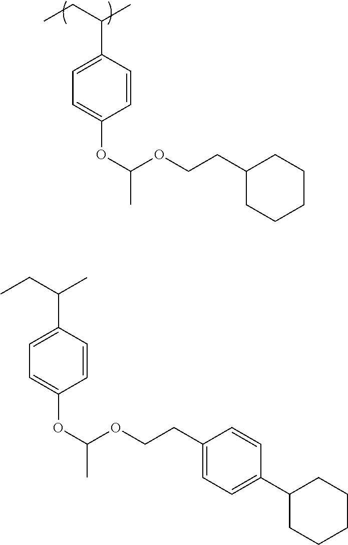

In the following specific examples, Xa₁ represents a hydrogen atom, CH₃, CF₃, or CH₂OH.

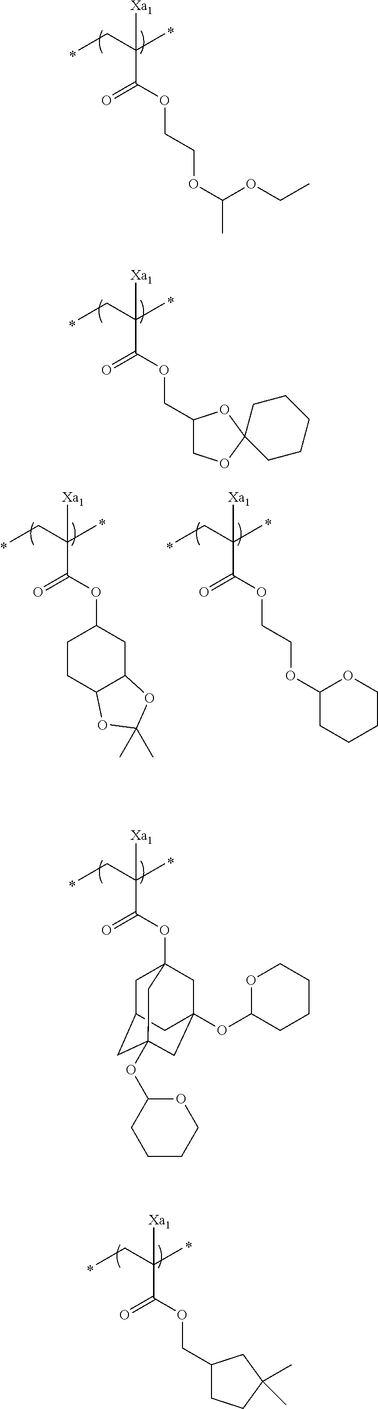

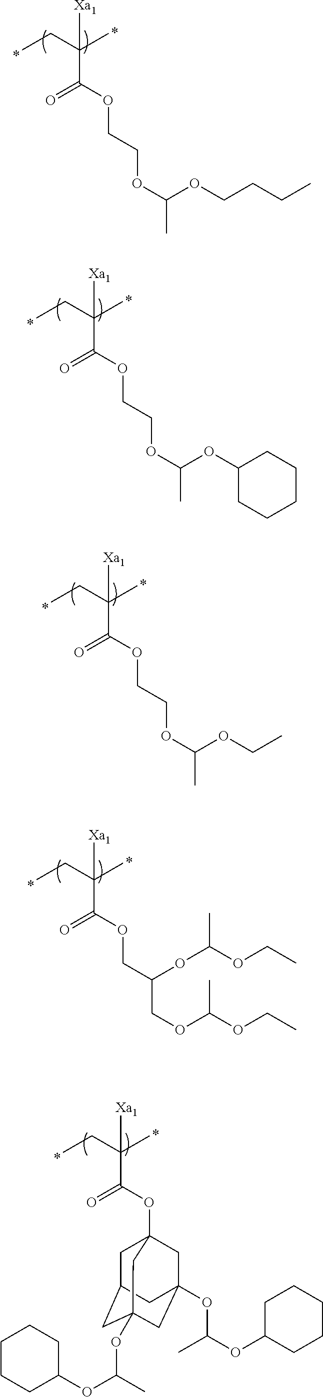

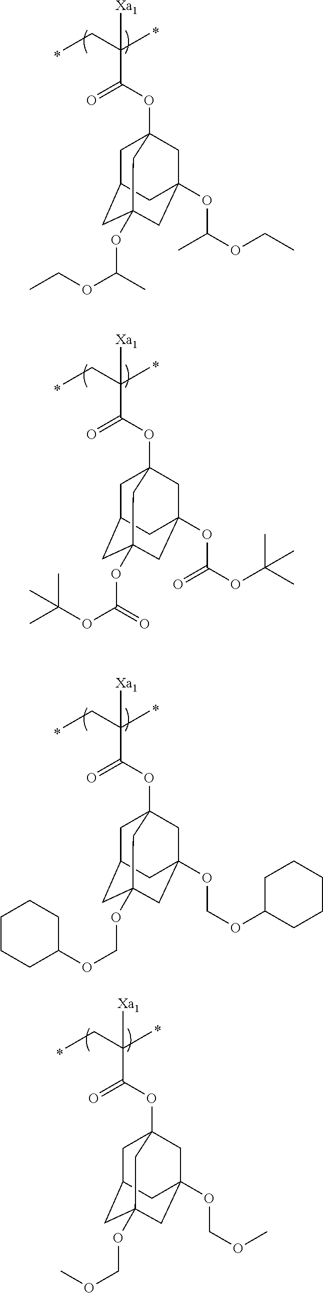

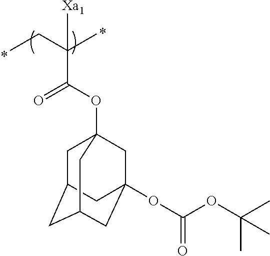

The repeating units having an acid-decomposable group may be used alone or in combination of two or more kinds thereof. A case of use of the combination of two or more kinds is not particularly limited, but for example, use of combination of the repeating unit represented by General Formula (I) and the repeating unit represented by General Formula (II) is preferred.

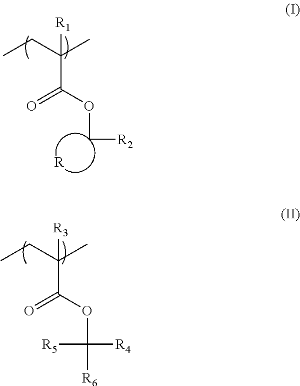

In General Formulae (I) and (II),

R₁ and R₃ each independently represent a hydrogen atom or an alkyl group which may have a substituent;

R₂, R₄, R₅, and R₆ each independently represent an alkyl group or a cycloalkyl group; and

R represents an atomic group required to be combined with a carbon atom to which R₂ is bonded to form an alicyclic structure.

R₁ and R₃ are preferably a hydrogen atom, a methyl group, a trifluoromethyl group, or a hydroxymethyl group.

The alkyl group in R₂ may be linear or branched, and may have a substituent.

The cycloalkyl group in R₂ may be monocyclic or polycyclic, and may have a substituent.

R₂ is preferably an alkyl group, more preferably an alkyl group having 1 to 10 carbon atoms, and still more preferably an alkyl group having 1 to 5 carbon atoms, and examples thereof include a methyl group and an ethyl group.

R represents an atomic group required to be combined with a carbon atom to form an alicyclic structure. As the alicyclic structure formed by R in combination with the carbon atom, a monocyclic alicyclic structure is preferred, and the number of carbon atoms thereof is preferably from 3 to 7, and more preferably 5 or 6.

R₃ is preferably a hydrogen atom or a methyl group, and more preferably a methyl group.

The alkyl group in R₄, R₅, or R₆ may be linear or branched, and may have a substituent. As the alkyl group, alkyl groups having 1 to 4 carbon atoms, such as a methyl group, an ethyl group, an n-propyl group, an isopropyl group, an n-butyl group, an isobutyl group, and a t-butyl group, are preferred.

The cycloalkyl group in R₄, R₅, or R₆ may be monocyclic or polycyclic, and may have a substituent. As the cycloalkyl group, monocyclic cycloalkyl groups such as a cyclopentyl group and a cyclohexyl group, or polycyclic cycloalkyl groups such as a norbomyl group, a tetracyclodecanyl group, a tetracyclododecanyl group, and an adamantyl group, are preferred.

Furthermore, in another embodiment, a resin including at least two kinds of the repeating units represented by General Formula (I) is more preferred. In the case of including at least two kinds of the repeating unit of General Formula (I), any one of (i) an embodiment including both of a repeating unit in which an alicyclic structure formed of an atomic group represented by R is a monocyclic alicyclic structure, and a repeating unit in which an alicyclic structure formed of an atomic group represented by R is a polycyclic alicyclic structure; and (ii) an embodiment in which both of the two kinds of the repeating units are repeating units in which an alicyclic structure formed of an atomic group represented by R is a monocyclic alicyclic structure is preferred. For the monocyclic alicyclic structure, the number of carbon atoms is preferably from 5 to 8, more preferably 5 or 6, and particularly preferably 5. Preferred examples of the polycyclic alicyclic structure include a norbornyl group, a tetracyclodecanyl group, a tetracyclododecanyl group, and an adamantyl group.

Preferred specific examples of use of the combination of two or more kinds include ones as follows.

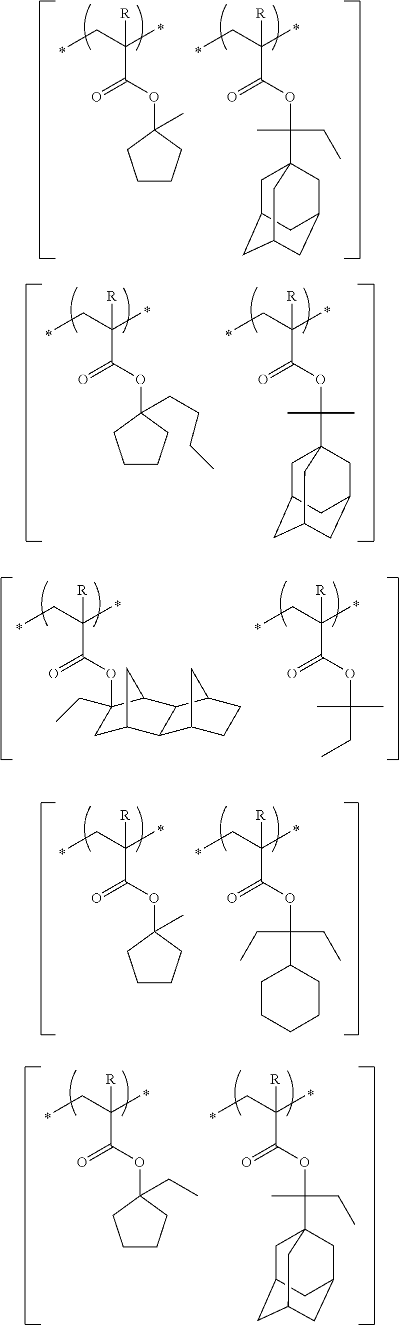

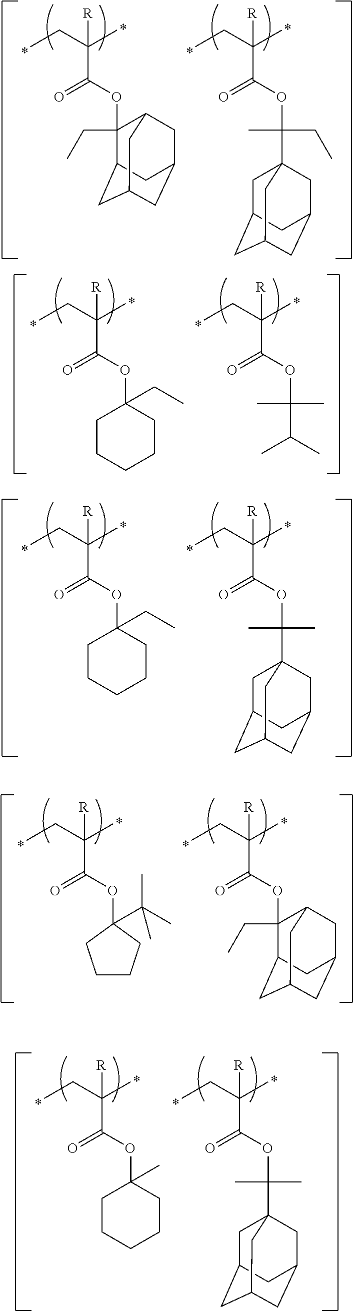

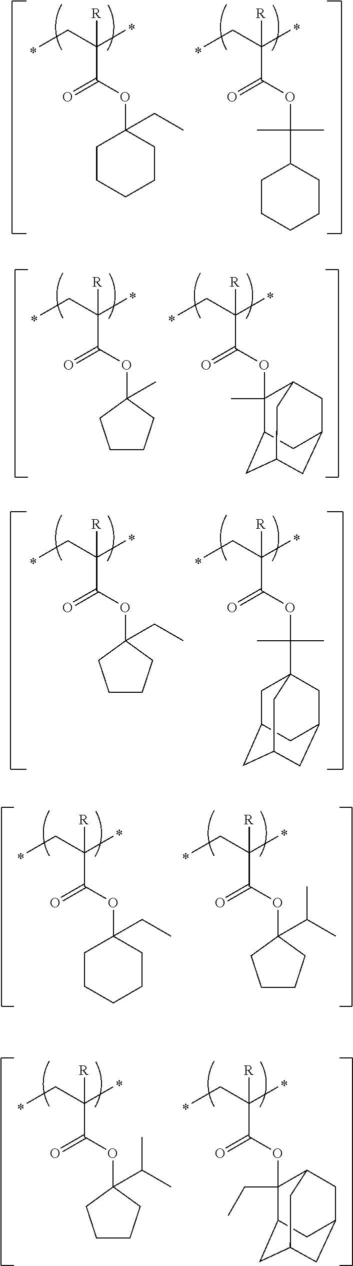

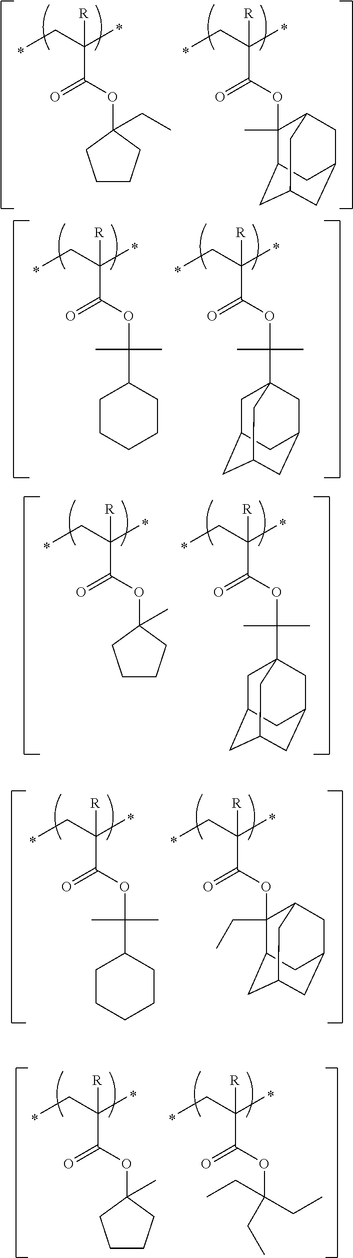

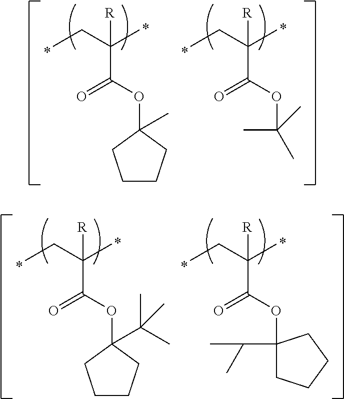

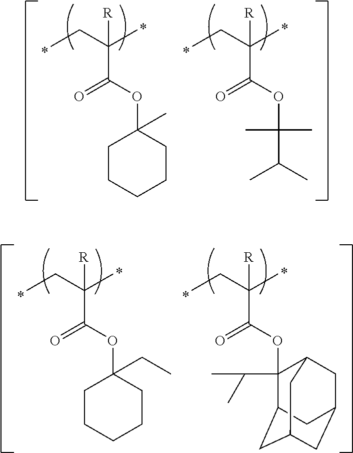

The content of the repeating units having an acid-decomposable group contained in the resin (A) (in the case where a plurality of repeating units having an acid-decomposable group are present, the content corresponds to the total amount of the repeating units) is preferably 15% by mole or more, more preferably 20% by mole or more, still more preferably 25% by mole or more, and particularly preferably 40% by mole or more, with respect to all the repeating units of the resin (A).

The resin (A) may contain a repeating unit having a lactone structure or a sultone structure.

Specific examples of the repeating unit having a group having a lactone structure or a sultone structure are shown below, but the present invention is not limited thereto.

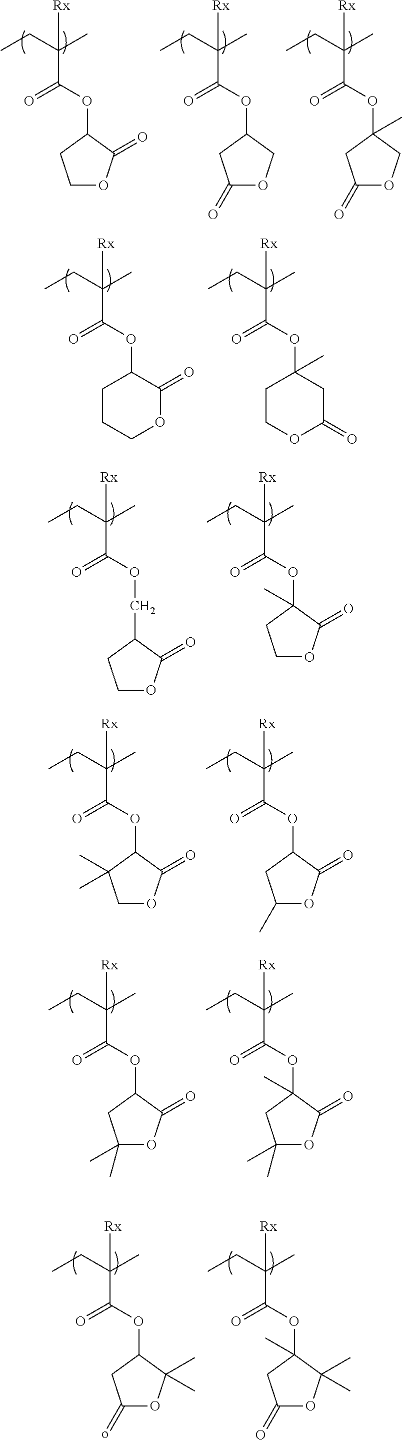

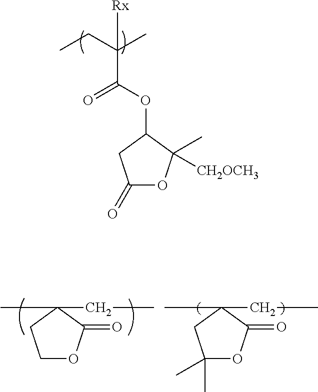

(in the formulae, Rx represents H, CH₃, CH₂OH, or CF₃)

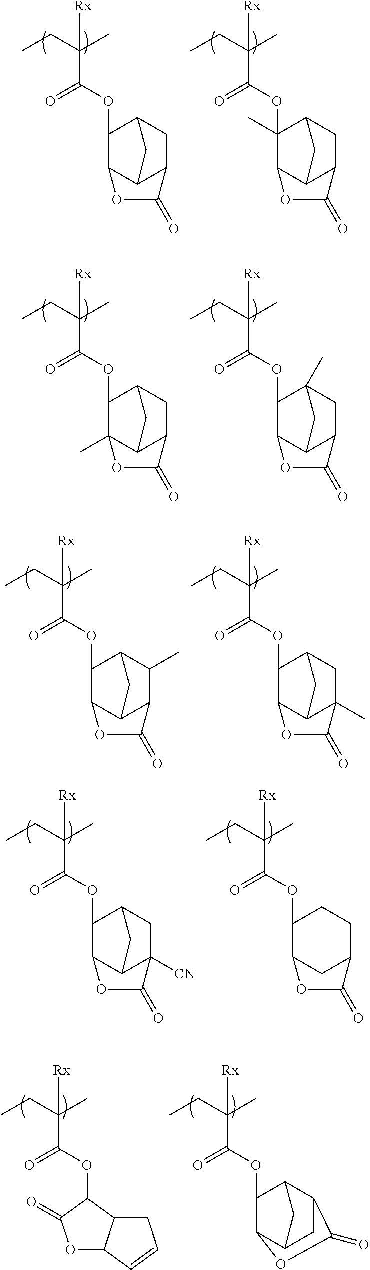

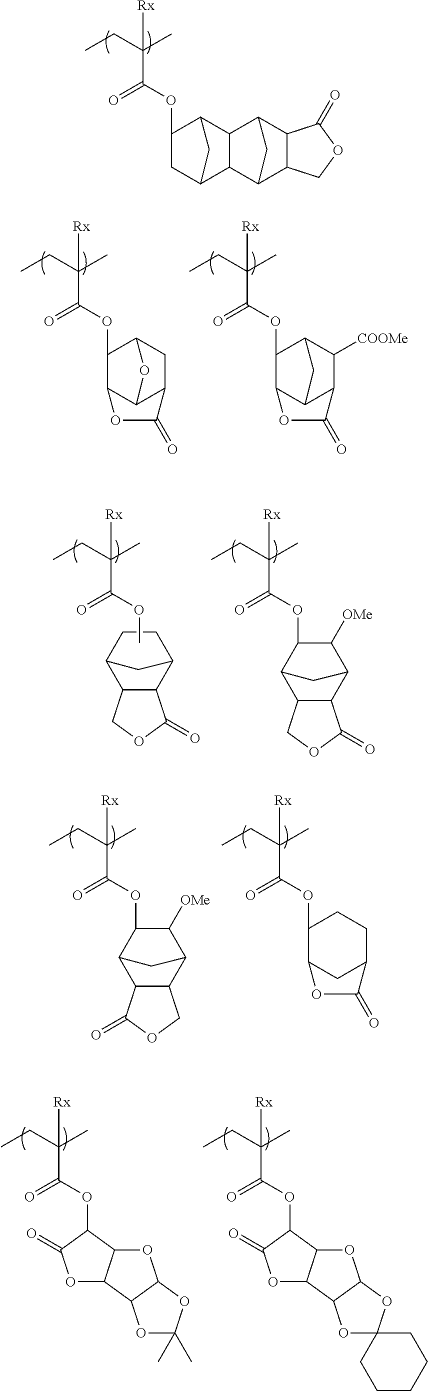

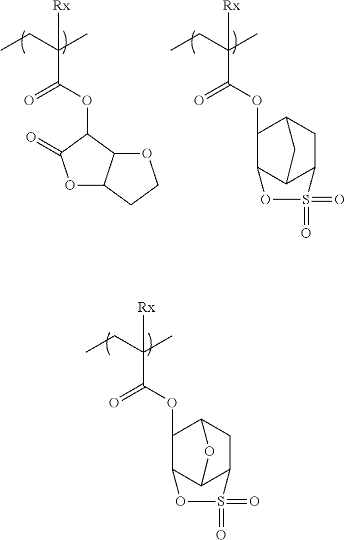

(in the formulae, Rx represents H, CH₃, CH₂OH, or CF₃)

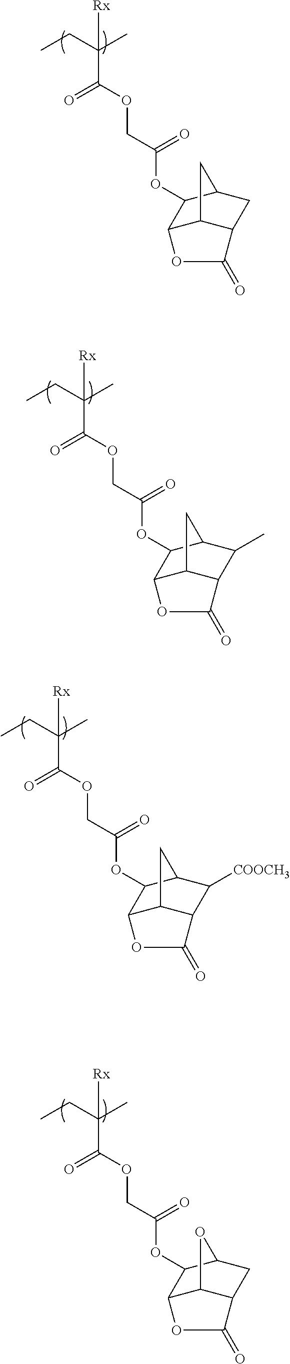

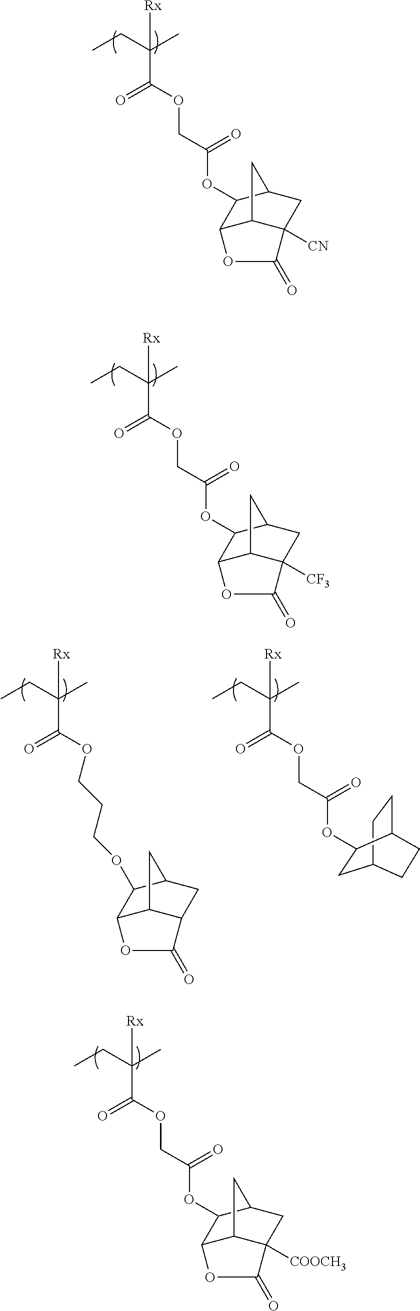

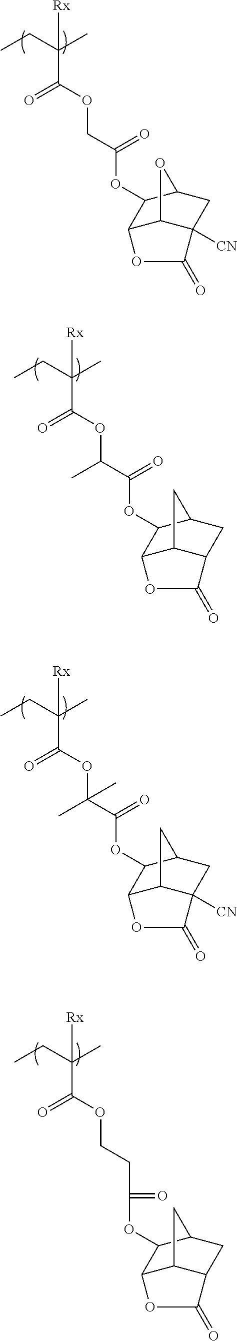

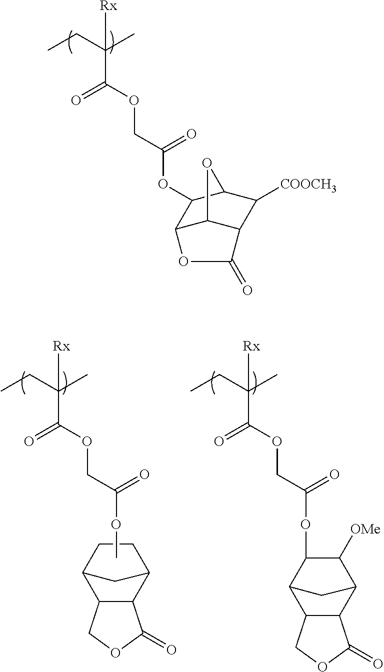

(in the formulae, Rx represents H, CH₃, CH₂OH, or CF₃)

It is also possible to use two or more kinds of repeating units having a lactone structure or a sultone structure in combination.

In the case where the resin (A) contains a repeating unit having a lactone structure or a sultone structure, the content of the repeating units having a lactone structure or a sultone structure is preferably from 5% by mole to 60% by mole, more preferably from 5% by mole to 55% by mole, and still more preferably from 10% by mole to 50% by mole, with respect to all the repeating units in the resin (A).

Furthermore, the resin (A) may contain a repeating unit having a cyclic carbonic ester structure. Specific examples thereof include the following ones, but the present invention is not limited thereto.

Incidentally, R_{A}¹ in the following specific examples represents a hydrogen atom or an alkyl group (preferably a methyl group).

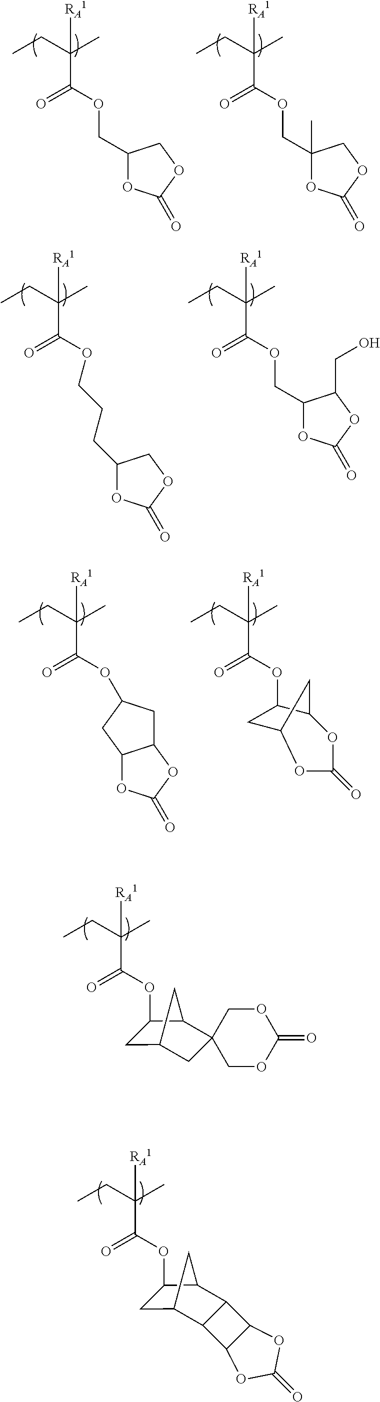

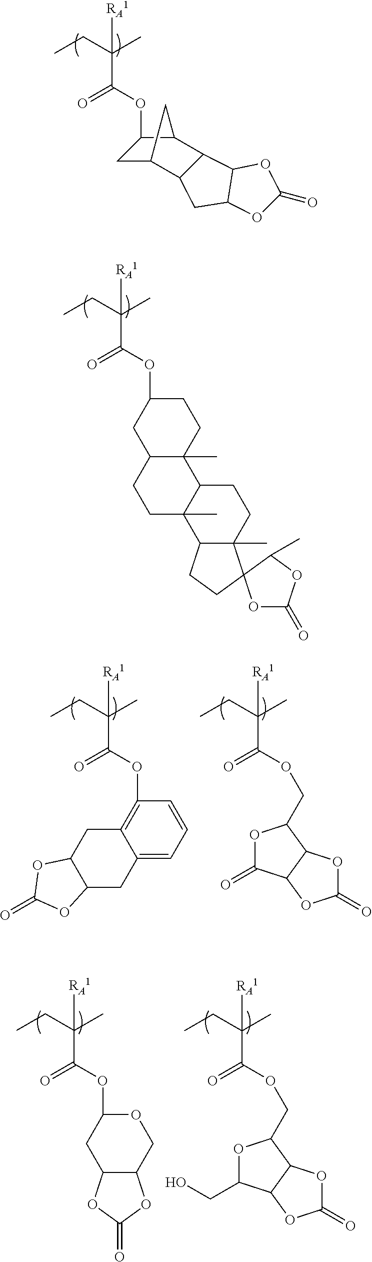

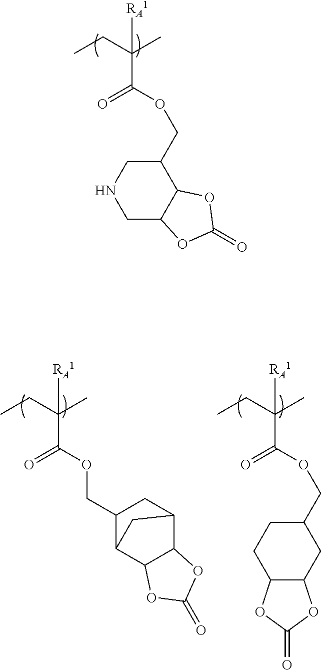

The resin (A) may contain a repeating unit having a hydroxyl group or a cyano group.

Specific examples of the repeating unit having a hydroxyl group or a cyano group are shown below, but the present invention is not limited thereto.

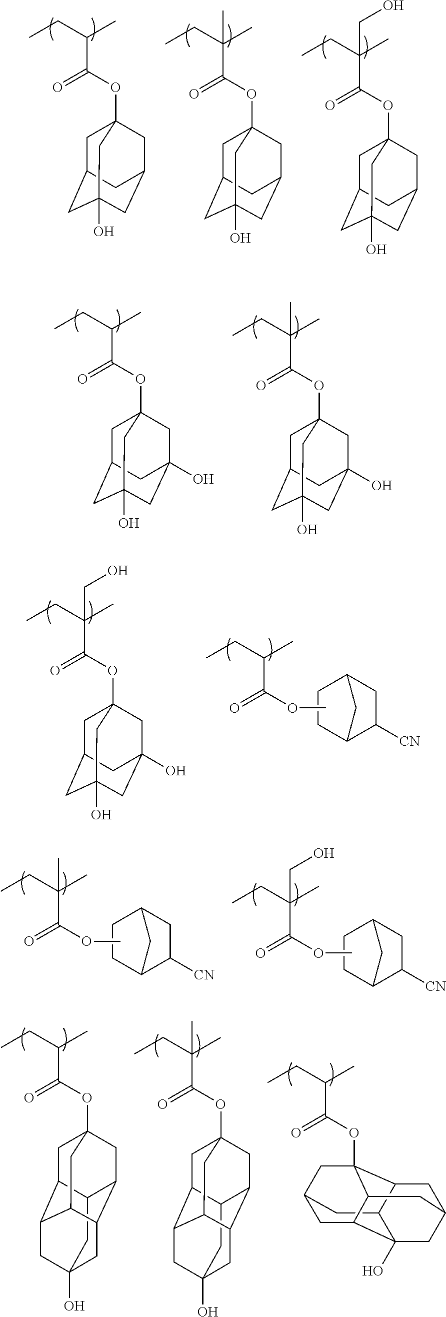

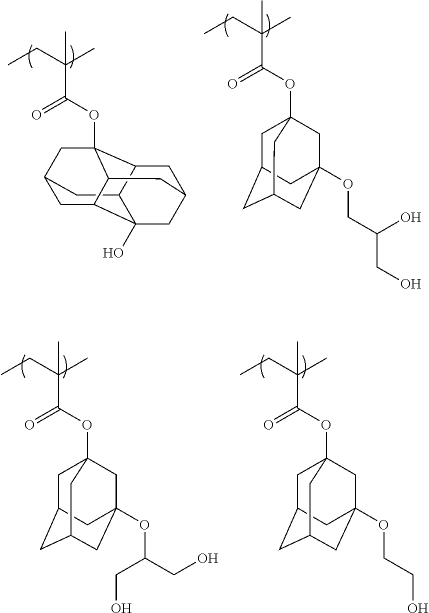

The resin (A) may not have a repeating unit having an acid group.

Although the resin (A) may or may not contain a repeating unit having an acid group, in the case where the repeating unit having an acid group is contained, the content thereof is preferably 25% by mole or less, and more preferably 20% by mole or less, with respect to all the repeating units in the resin (A). In the case where the resin (A) contains a repeating unit having an acid group, the content of the repeating units having an acid group in the resin (A) is usually 1% by mole or more.

Specific examples of the repeating unit having an acid group are shown below, but the present invention is not limited thereto.

In the specific examples, Rx represents H, CH₃, CH₂OH, or CF₃.

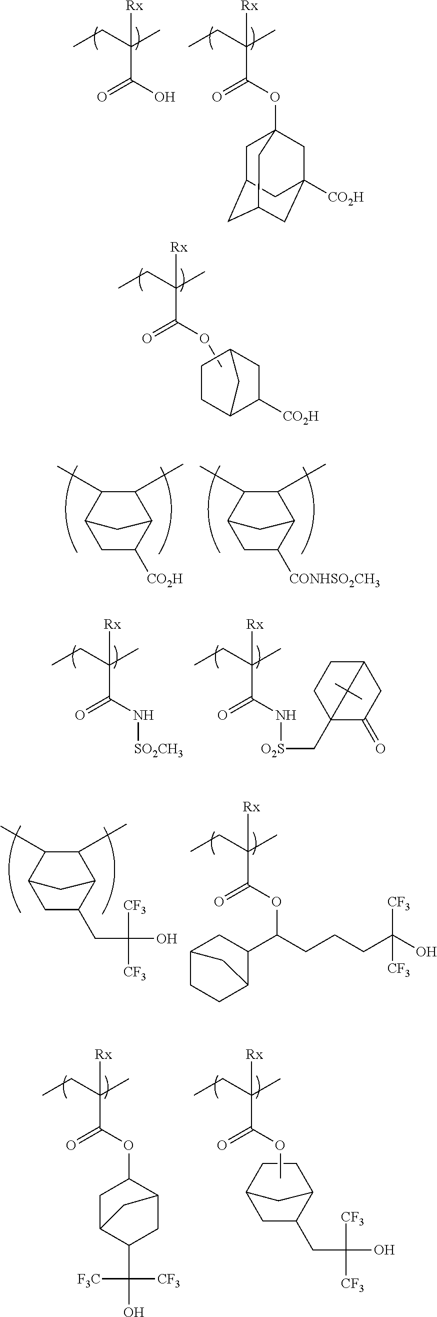

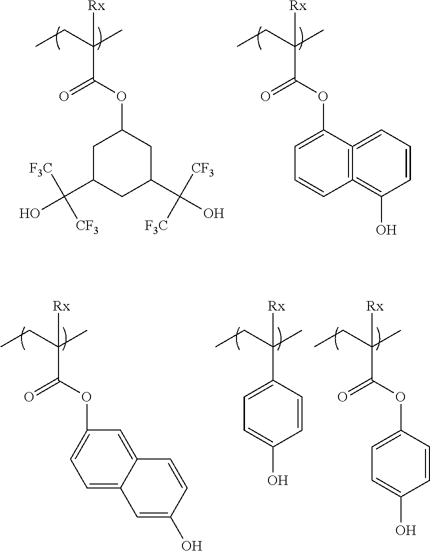

The resin (A) may further contain a repeating unit having an alicyclic hydrocarbon structure and/or aromatic ring structure having no polar group (for example, the acid groups, a hydroxyl group, and a cyano group) and not exhibiting acid-decomposability. In the case where the resin (A) contains this repeating unit, the content of the repeating units is preferably from 3% by mole to 30% by mole, and still more preferably from 5% by mole to 25% by mole, with respect to all the repeating units in the resin (A).

Specific examples of the repeating unit having an alicyclic hydrocarbon structure containing no polar group and not exhibiting acid-decomposability are shown below, but the present invention is not limited thereto. In the formulae, Ra represents H, CH₃, CH₂OH, or CF₃.

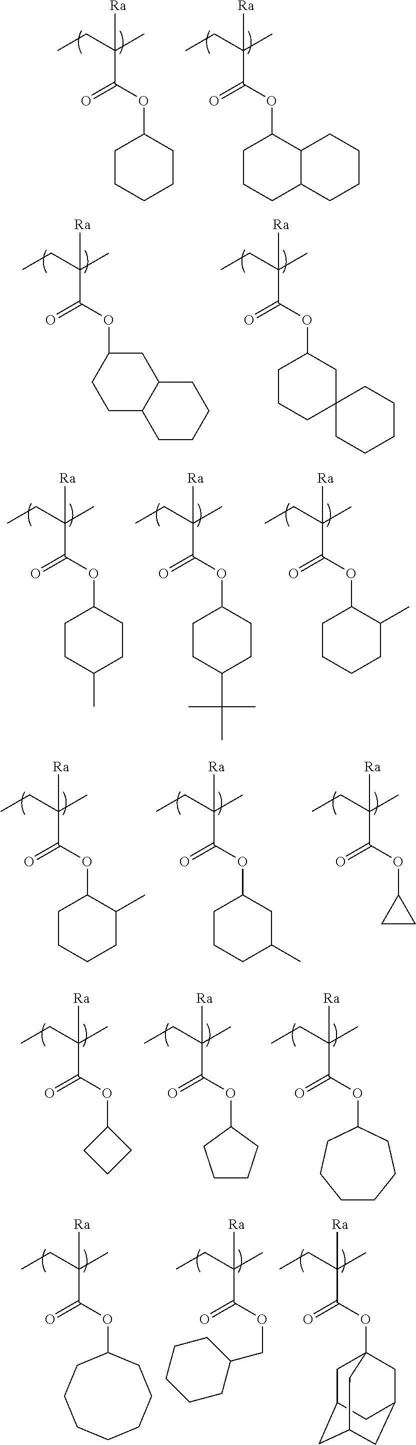

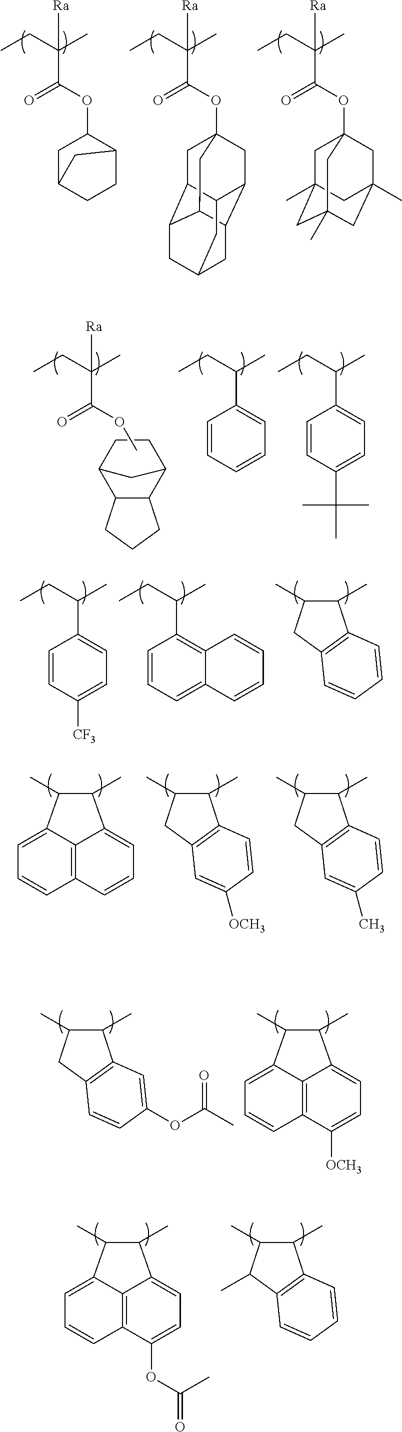

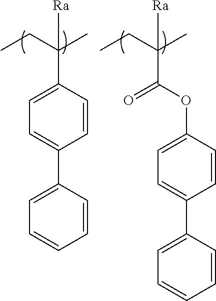

When the resist composition is for ArF exposure, it is preferable that the resin (A) used in the resist composition substantially does not have aromatic rings (specifically, the proportion of repeating units having an aromatic group in the resin is preferably 5% by mole or less, more preferably 3% by mole or less, and ideally 0% by mole, that is, the resin (A) does not have an aromatic group) in terms of transparency to ArF light. It is preferable that the resin (A) has a monocyclic or polycyclic alicyclic hydrocarbon structure.

The form of the resin (A) in the present invention may be any of random-type, block-type, comb-type, and star-type forms. The resin (A) can be synthesized by, for example, radical, cationic, or anionic polymerization of unsaturated monomers corresponding to respective structures. It is also possible to obtain a desired resin by polymerizing unsaturated monomers corresponding to precursors of respective structures, and then by carrying out a polymer reaction.

When the resist composition contains a resin (D) as described later, it is preferable that the resin (A) contains neither a fluorine atom nor a silicon atom, from the viewpoint of compatibility with the resin (D).

The resin (A) used in the resist composition is preferably a resin in which all the repeating units are composed of (meth)acrylate-based repeating units. In this case, all the repeating units may be methacrylate-based repeating units, all the repeating units may be acrylate-based repeating units, or all the repeating units may be composed anyone of methacrylate-based repeating units and acrylate-based repeating units, but the acrylate-based repeating units preferably accounts for 50% by mole or less with respect to all the repeating units.

In the case where the resist composition is irradiated with KrF excimer laser light, electron beams, X-rays, and high-energy light beams at a wavelength of 50 nm or less (EUV and the like), the resin (A) may further have a repeating unit having an aromatic ring. The repeating unit having an aromatic ring is not particularly limited, and examples thereof are shown in the description of the respective repeating units as described above, including a styrene unit, a hydroxystyrene unit, a phenyl (meth)acrylate unit, and a hydroxyphenyl (meth)acrylate unit. More specific examples of the resin (A) include a resin having a hydroxystyrene-based repeating unit and a hydroxystyrene-based repeating unit protected by an acid-decomposable group, a resin having the repeating unit having an aromatic ring and a resin having a repeating unit having a carboxylic acid moiety of a (meth)acrylic acid protected by an acid-decomposable group.

The resin (A) in the present invention can be synthesized in accordance with an ordinary method (for example, radical polymerization, living radical polymerization, and anionic polymerization). For example, reference can be made to the descriptions of paragraphs 0121 to 0128 of JP2012-073402A (paragraphs 0203 to 0211 of the corresponding US Patent App. No. 2012/077122), the contents of which are incorporated in the specification of the present application.

The weight-average molecular weight of the resin (A) in the present invention is preferably 7,000 or more as described above, preferably from 7,000 to 200,000, more preferably from 7,000 to 50,000, still more preferably from 7,000 to 40,000, and particularly preferably from 7,000 to 30,000, as measured by a GPC method, and calculated in terms of polystyrene. When the weight-average molecular weight is less than 7,000, the solubility in organic developing liquid becomes too high, and as a result, there is a concern that it may fail to form precise patterns.

The resin (A) having a dispersity (molecular-weight distribution) of generally from 1.0 to 3.0, preferably from 1.0 to 2.6, more preferably from 1.0 to 2.0, and particularly preferably from 1.4 to 2.0 is used. The narrower the molecular weight distribution, the more excellent resolution and resist profile are achieved, and in addition, the smoother side wall of a resist pattern and the more excellent roughness are obtained.

In the resist composition, the blending ratio of the resin (A) in the entire resist composition is preferably from 30% by mass to 99% by mass, and more preferably 60% by mass to 95% by mass, with respect to the total solid content.

Furthermore, in the present invention, the resins (A) may be used alone or in combination of a plurality of kinds thereof. In the case of using a plurality of the resins (A) in combination, the combination use ratio or the combination of the resins (A) is not particularly limited, but preferred examples thereof include a combination of two kinds of the resins (A) having repeating units having different acid-decomposable groups.

Specific examples (in which the compositional ratio of the repeating units is a molar ratio) of the resin (A) are shown below, but the present invention is not limited thereto. Incidentally, embodiments of the case where a structure corresponding to the acid generator (B) as described later is supported on the resin (A) are also exemplified.

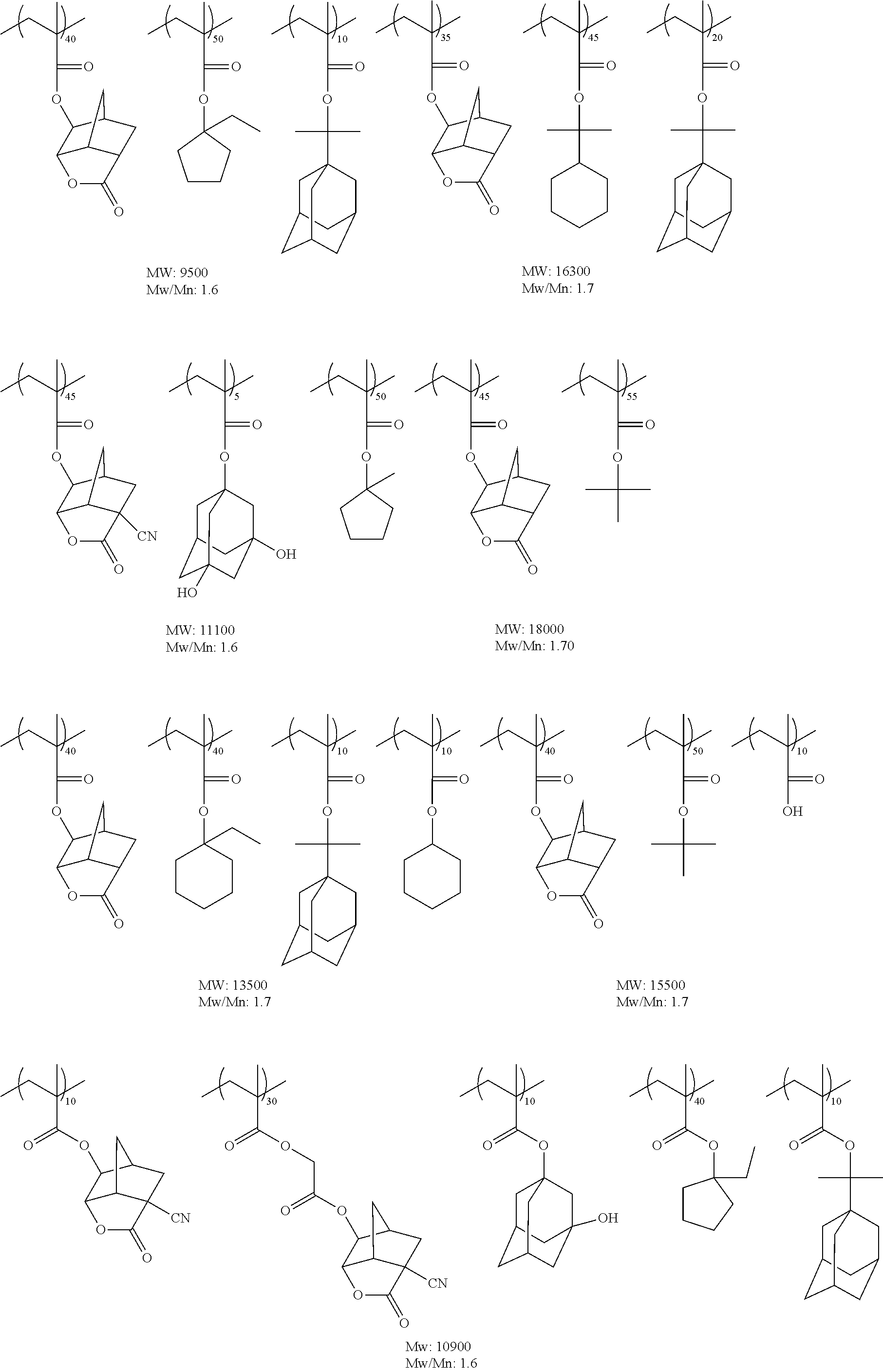

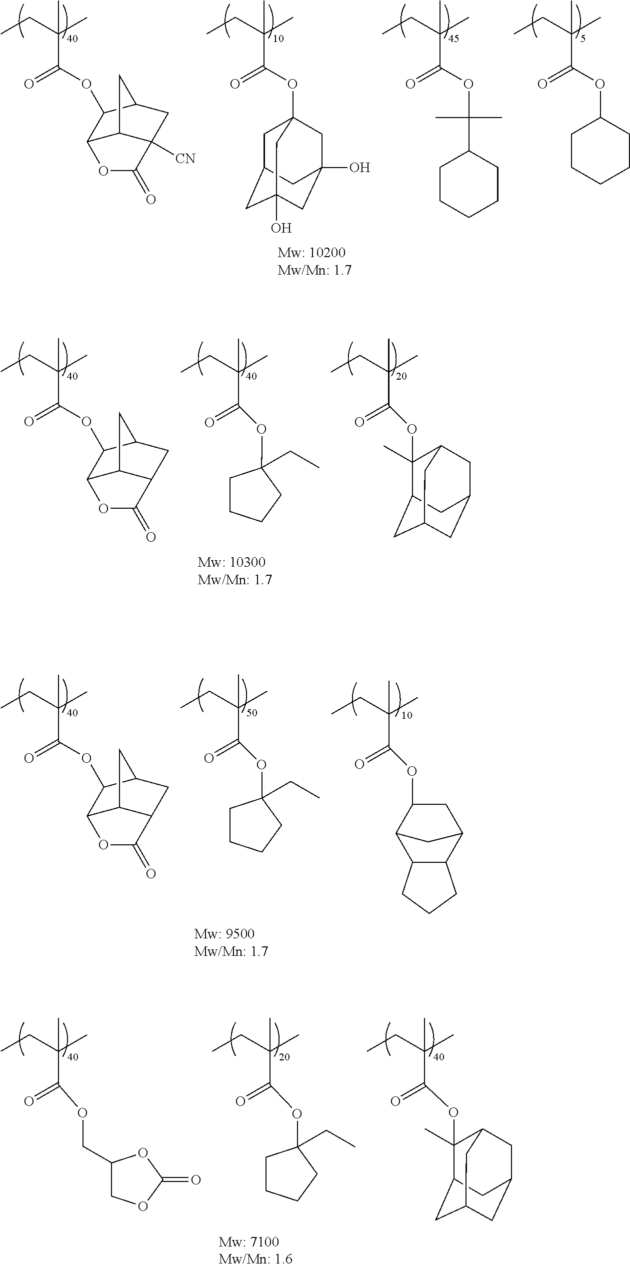

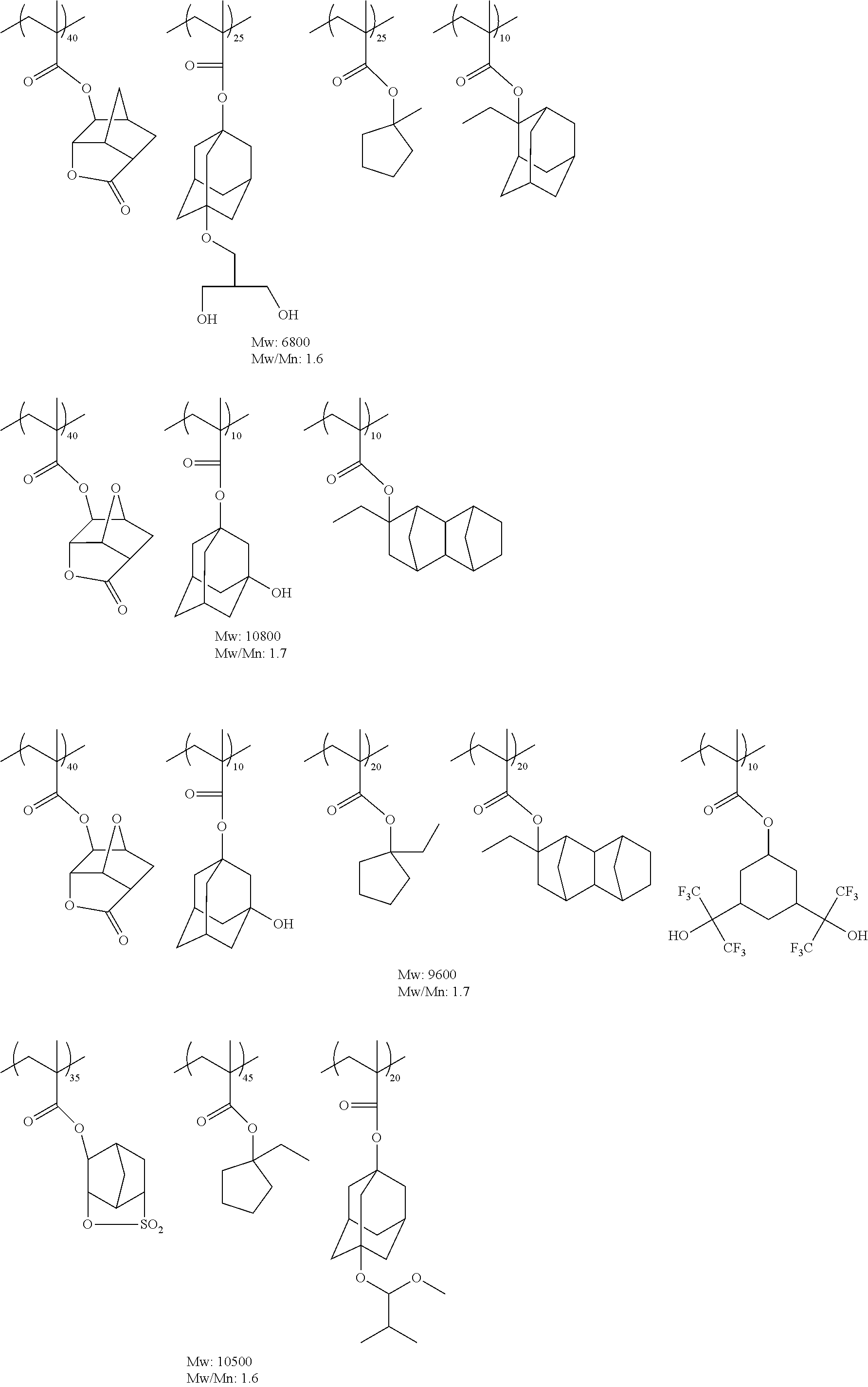

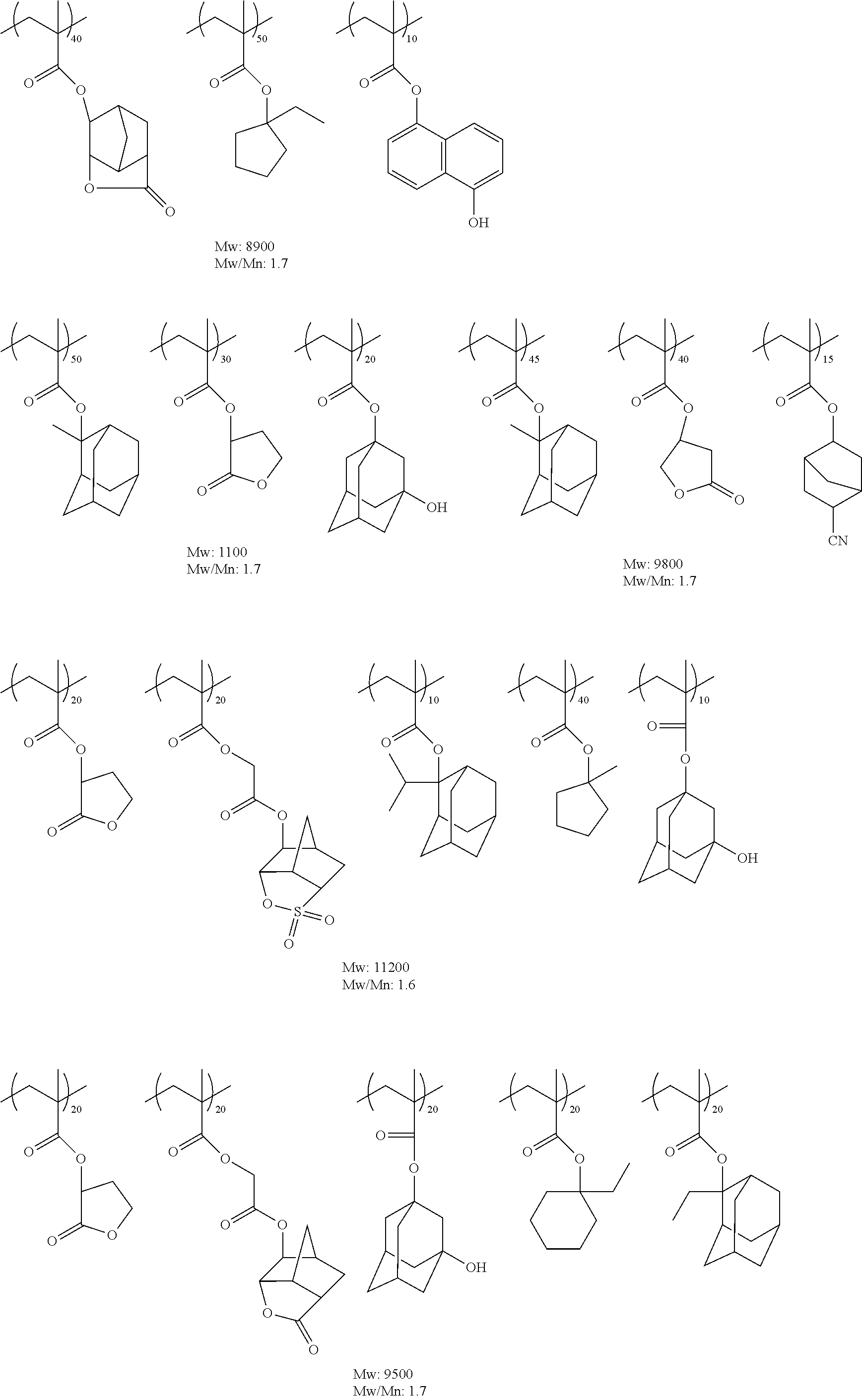

The resins exemplified below are the examples of the resins which can be suitably used, in particular, during EUV exposure or electron beams exposure.

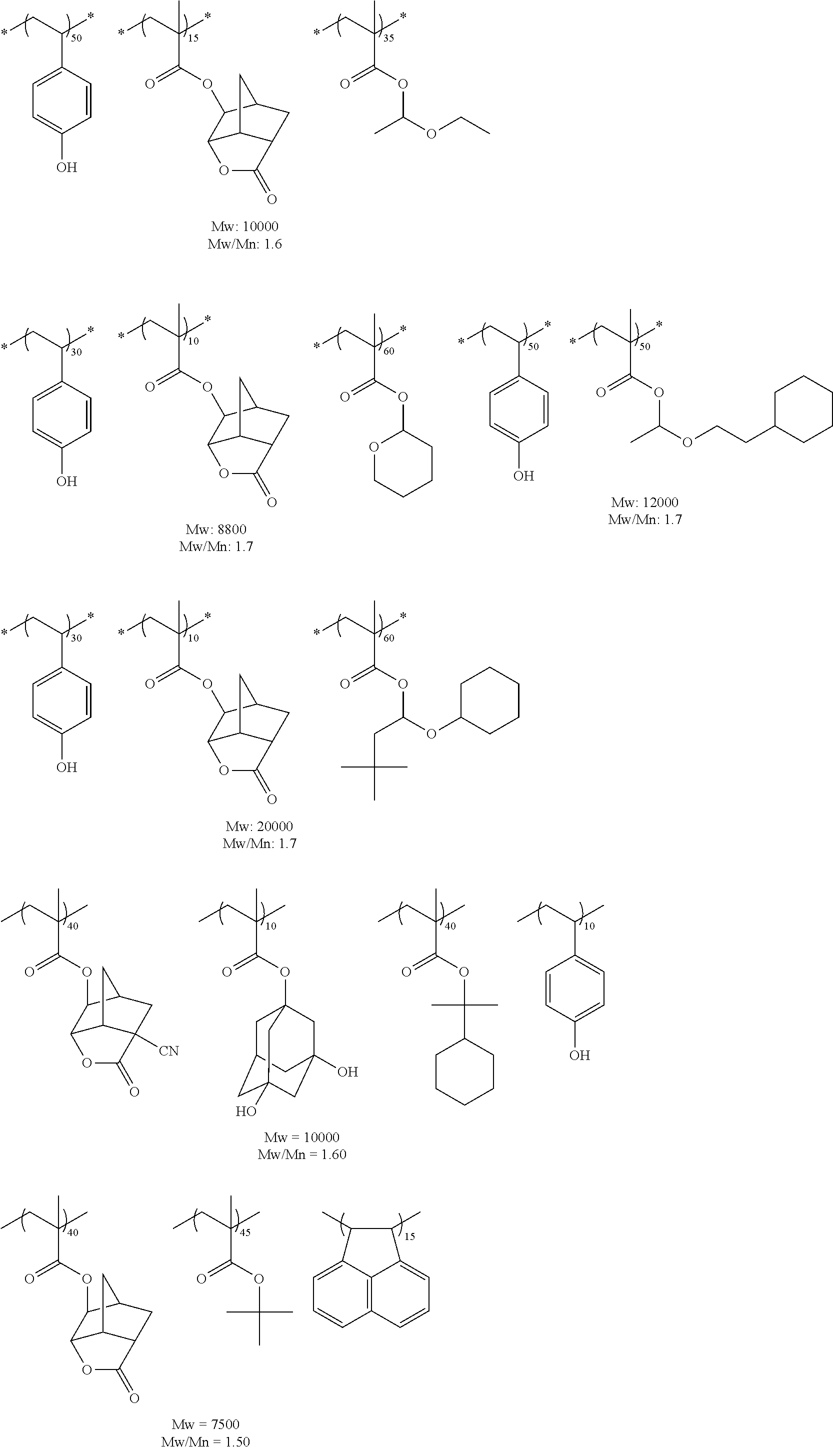

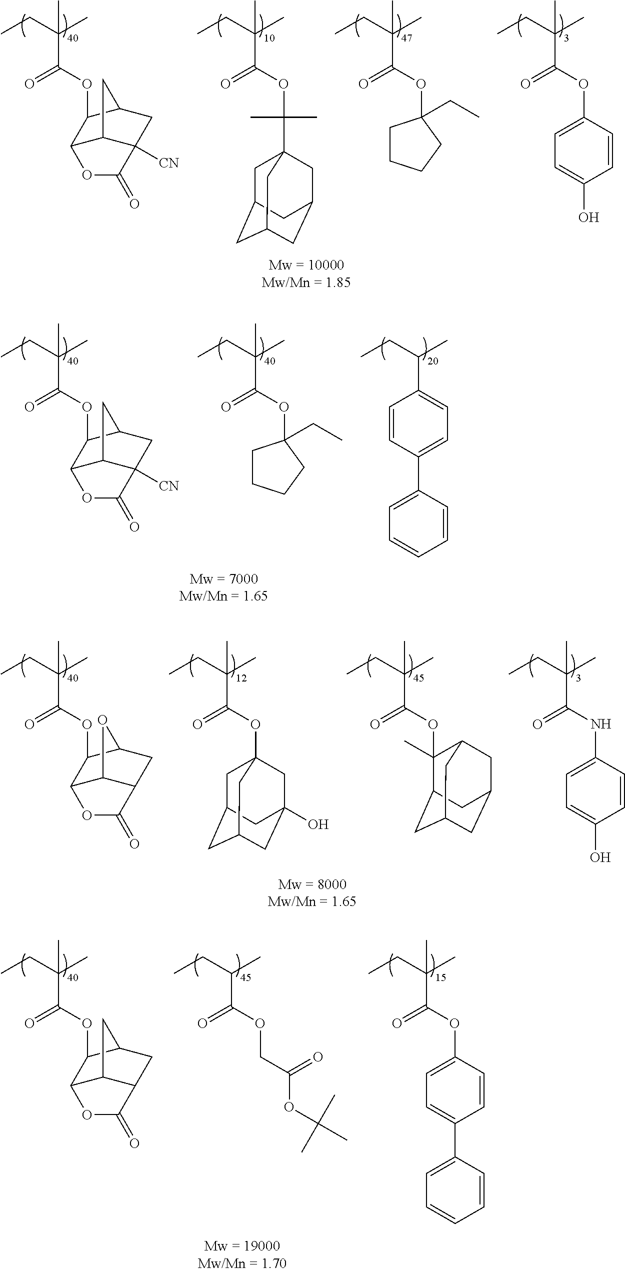

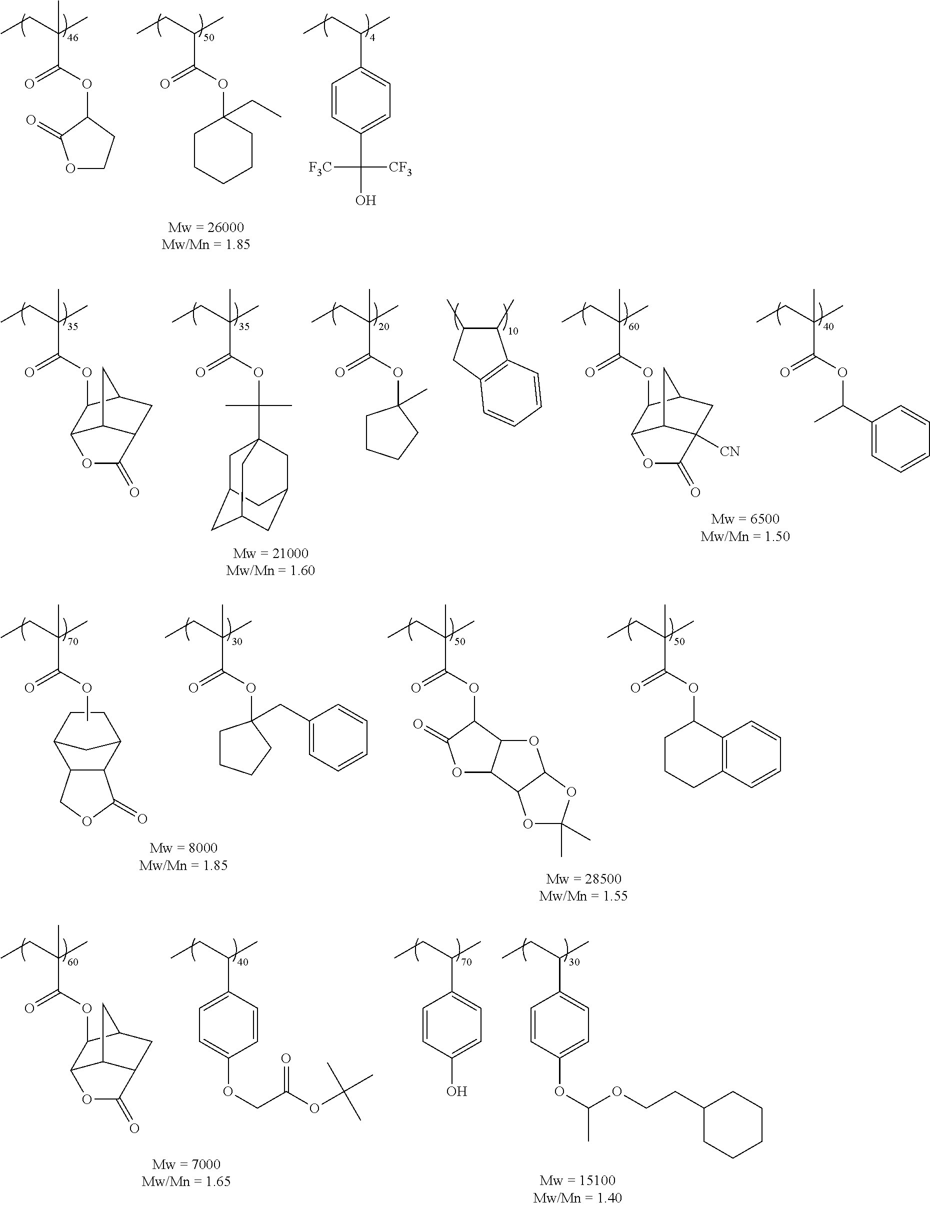

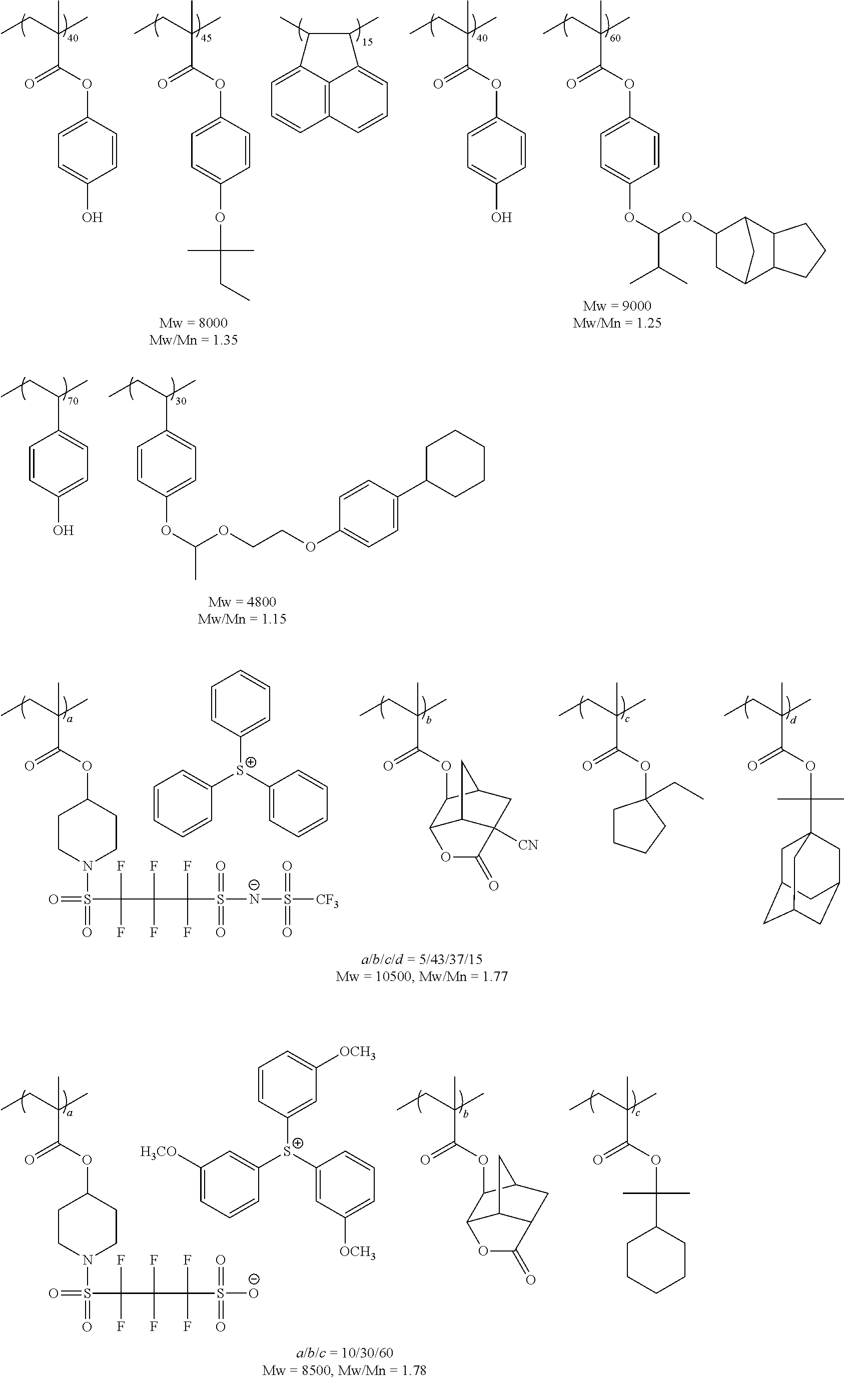

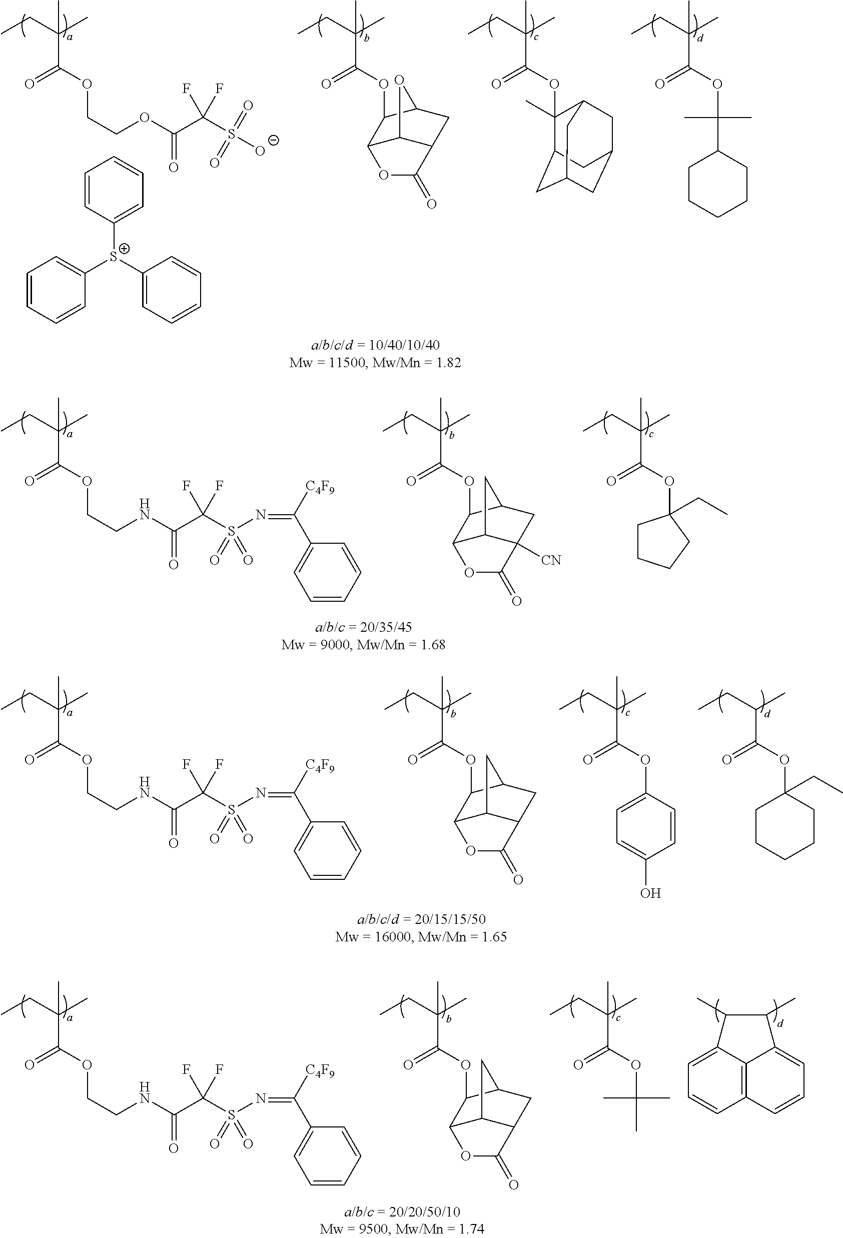

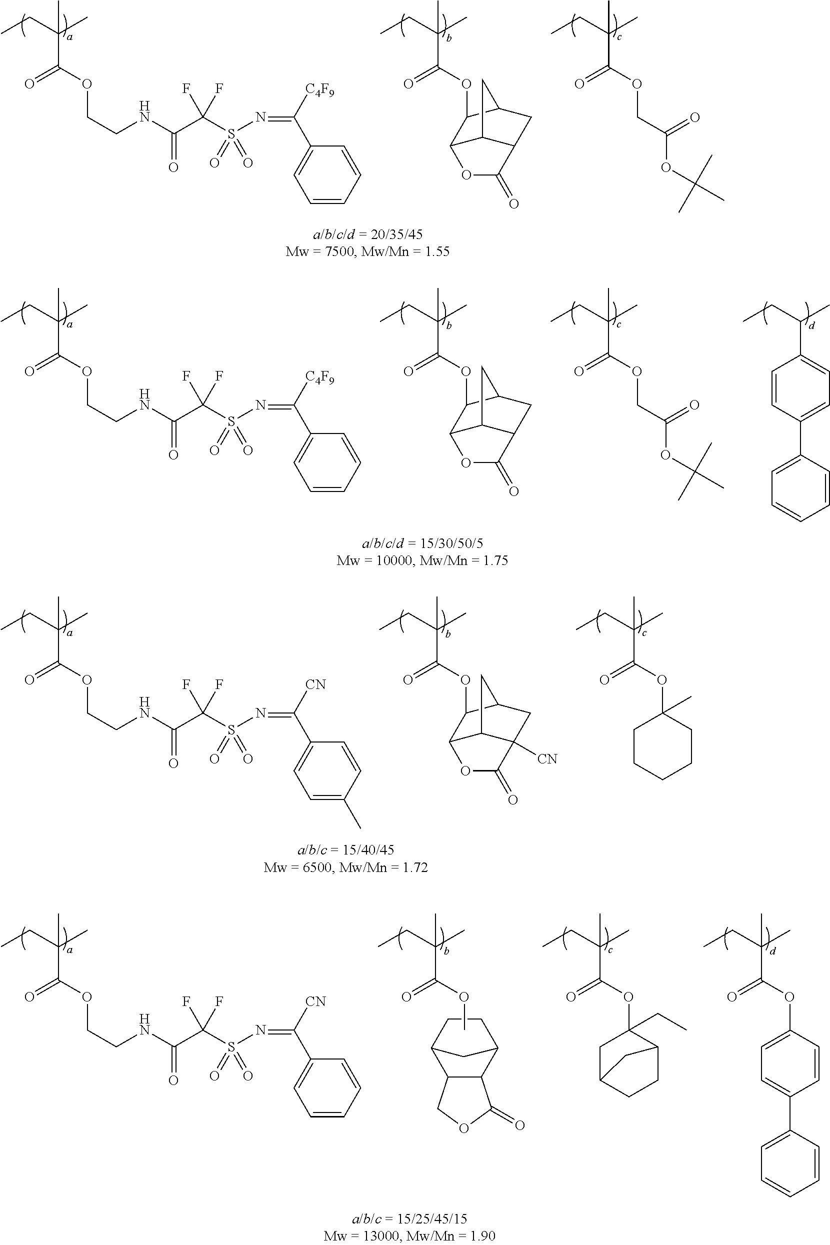

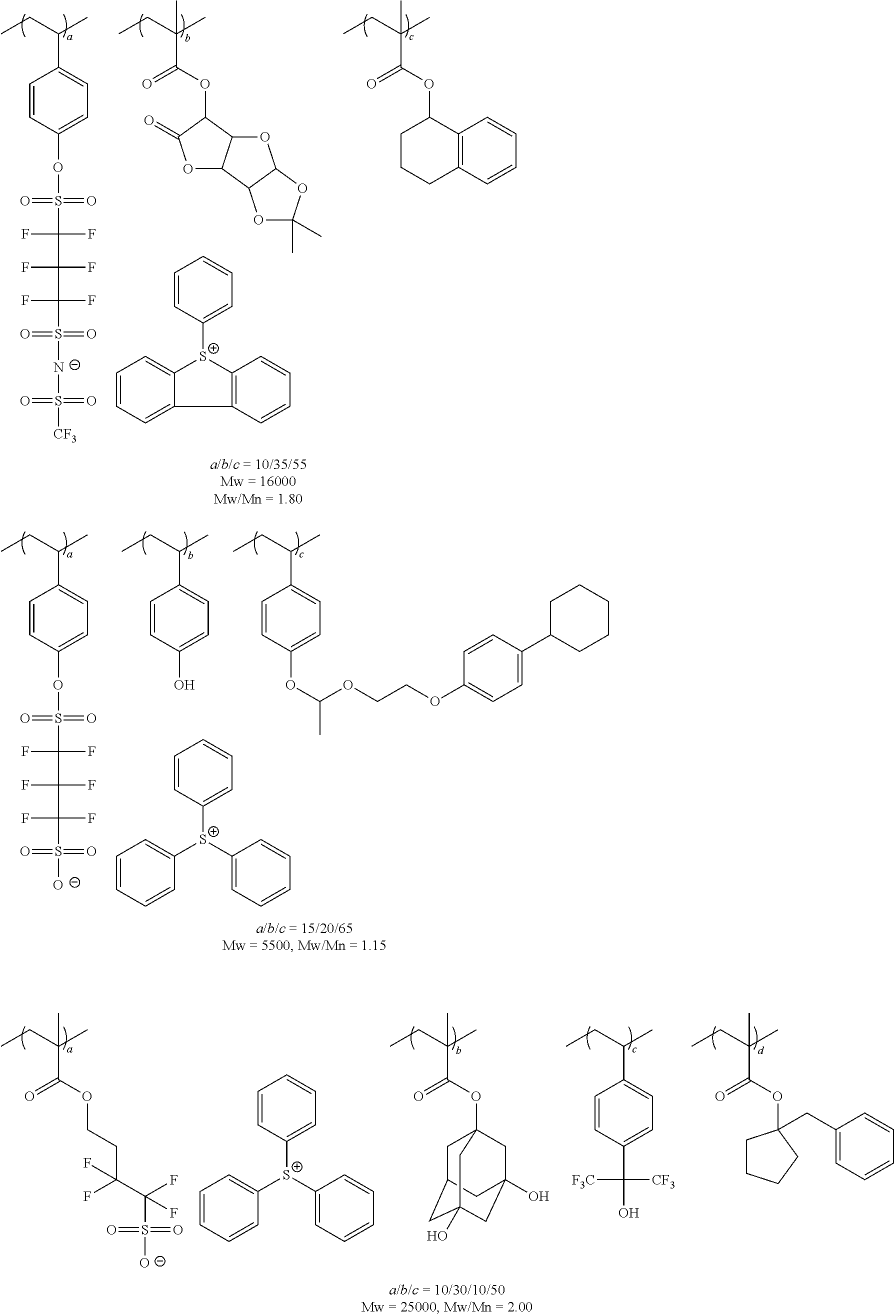

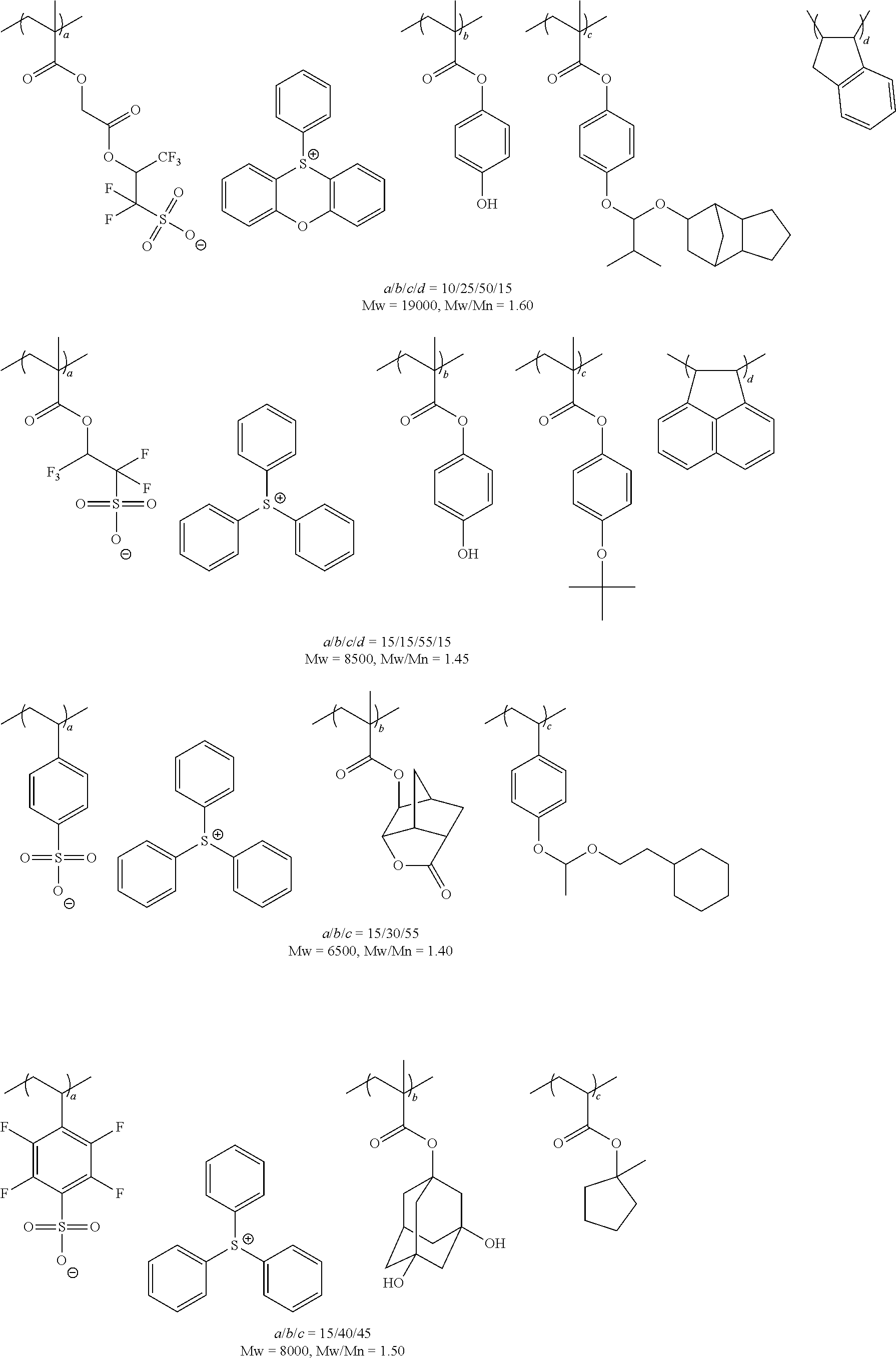

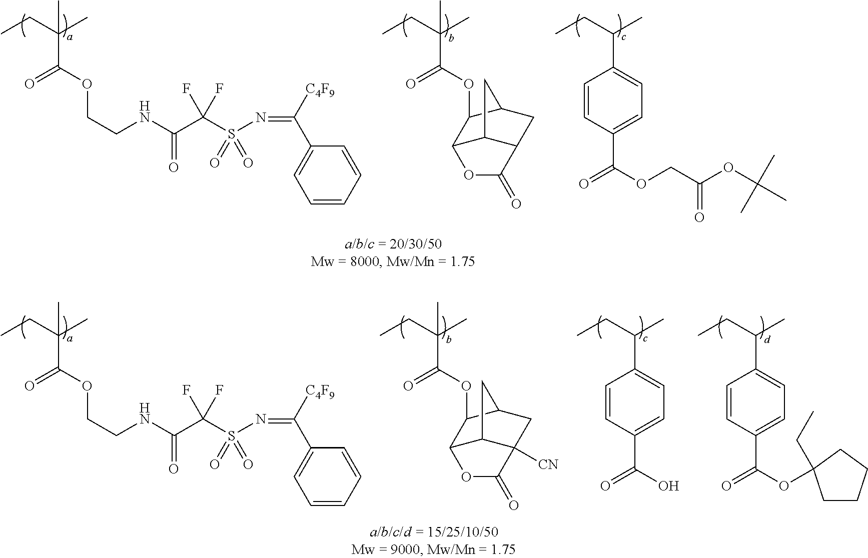

[2] Compound Capable of Generating Acid by Irradiation with Actinic Rays or Radiation

The resist composition preferably contains a compound capable of generating an acid by irradiation with actinic rays or radiation (hereinafter also referred to as a “compound (B)” or an “acid generator”). The compound (B) capable of generating an acid by irradiation with actinic rays or radiation is preferably a compound capable of generating an organic acid by irradiation with actinic rays or radiation.

The acid generator which is appropriately selected from a photoinitiator for cationic photopolymerization, a photoinitiator for radical photopolymerization, a photodecoloring agent for dyes, a photodiscoloring agent, a known compound capable of generating an acid by irradiation with actinic rays or radiation, which is used for a microresist or the like, and a mixture thereof can be used.

Examples thereof include a diazonium salt, a phosphonium salt, a sulfonium salt, an iodonium salt, imide sulfonate, oxime sulfonate, diazodisulfone, disulfone, and o-nitrobenzyl sulfonate.

Among the acid generators, particularly preferred examples are shown below.

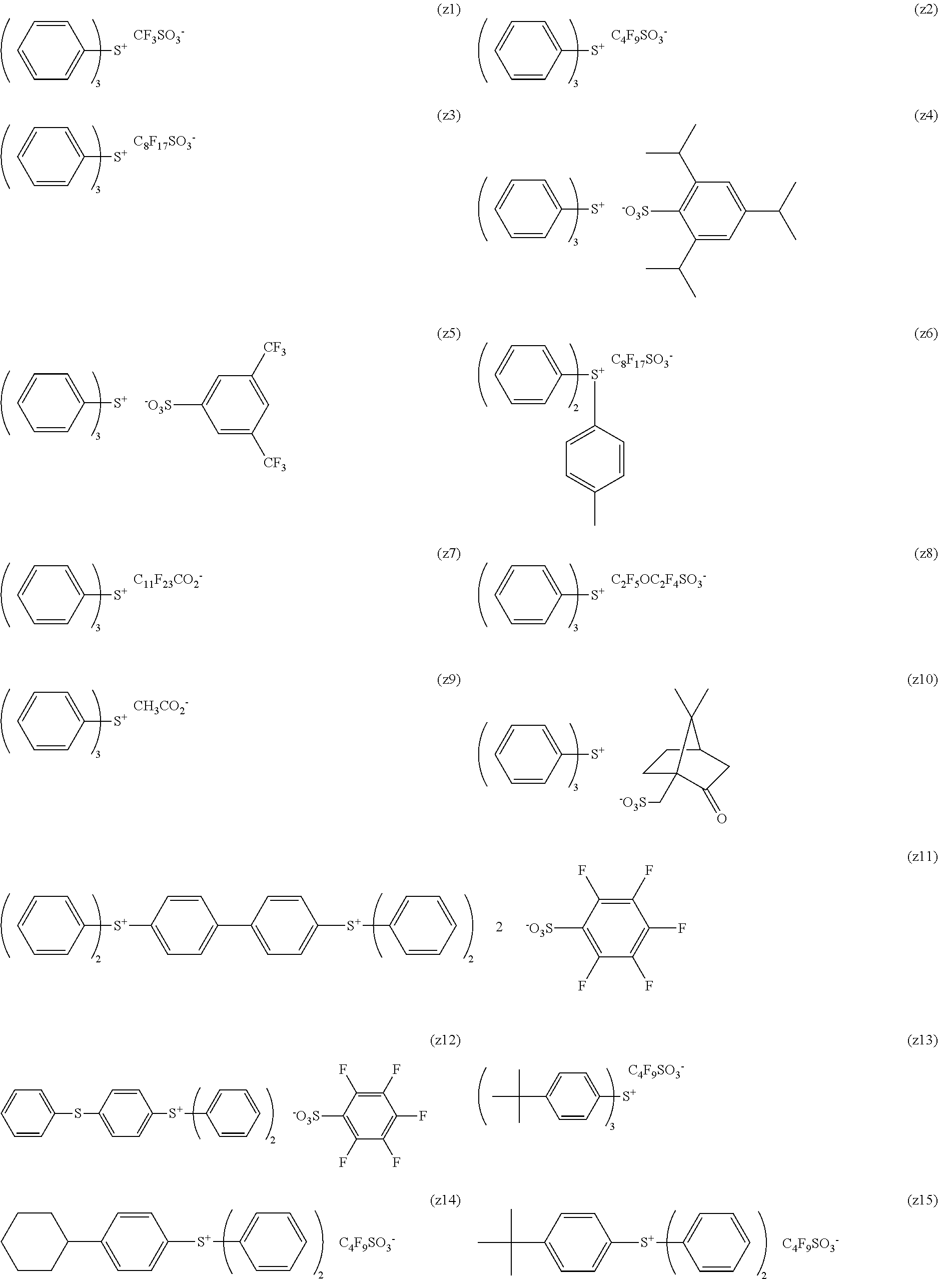

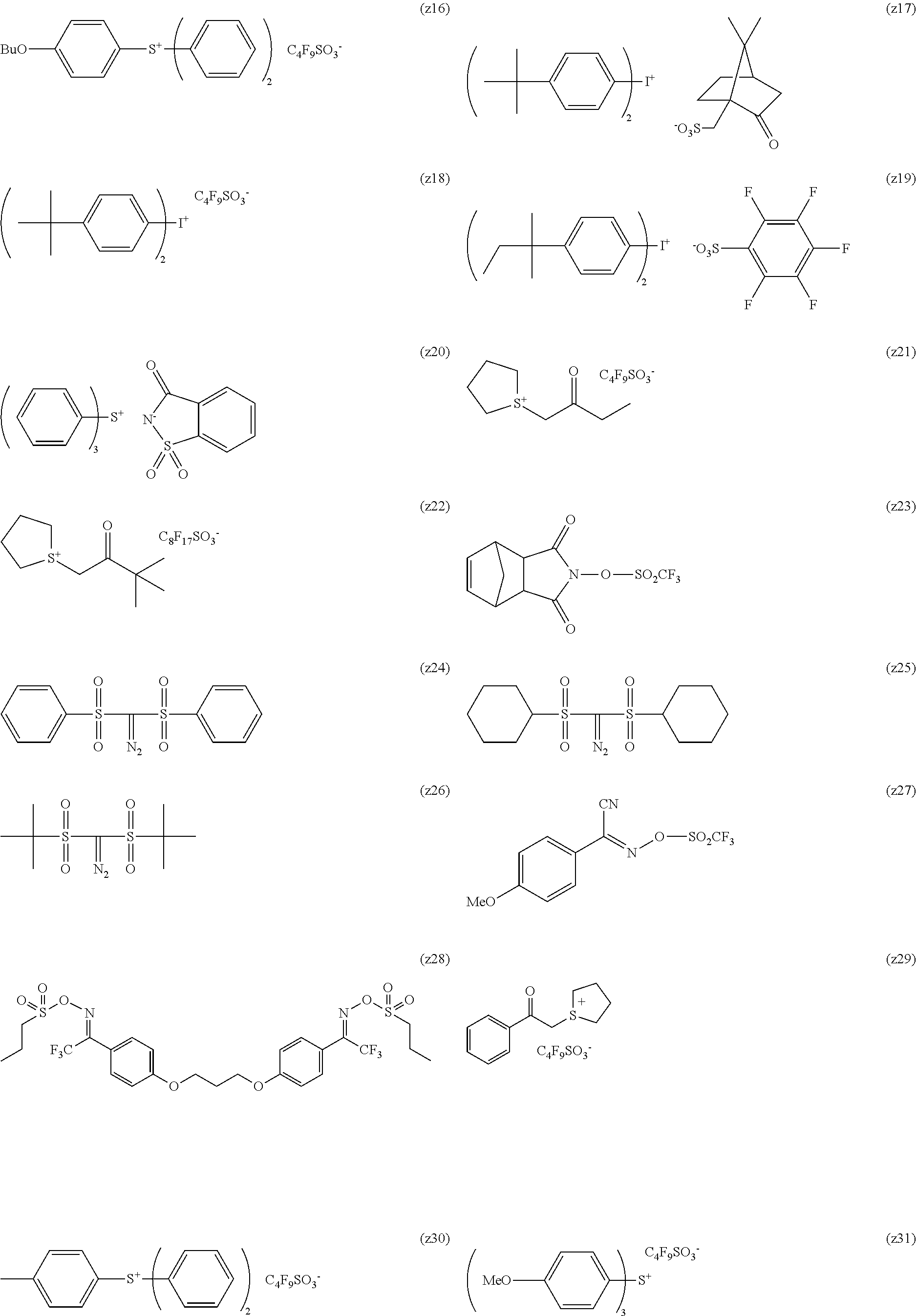

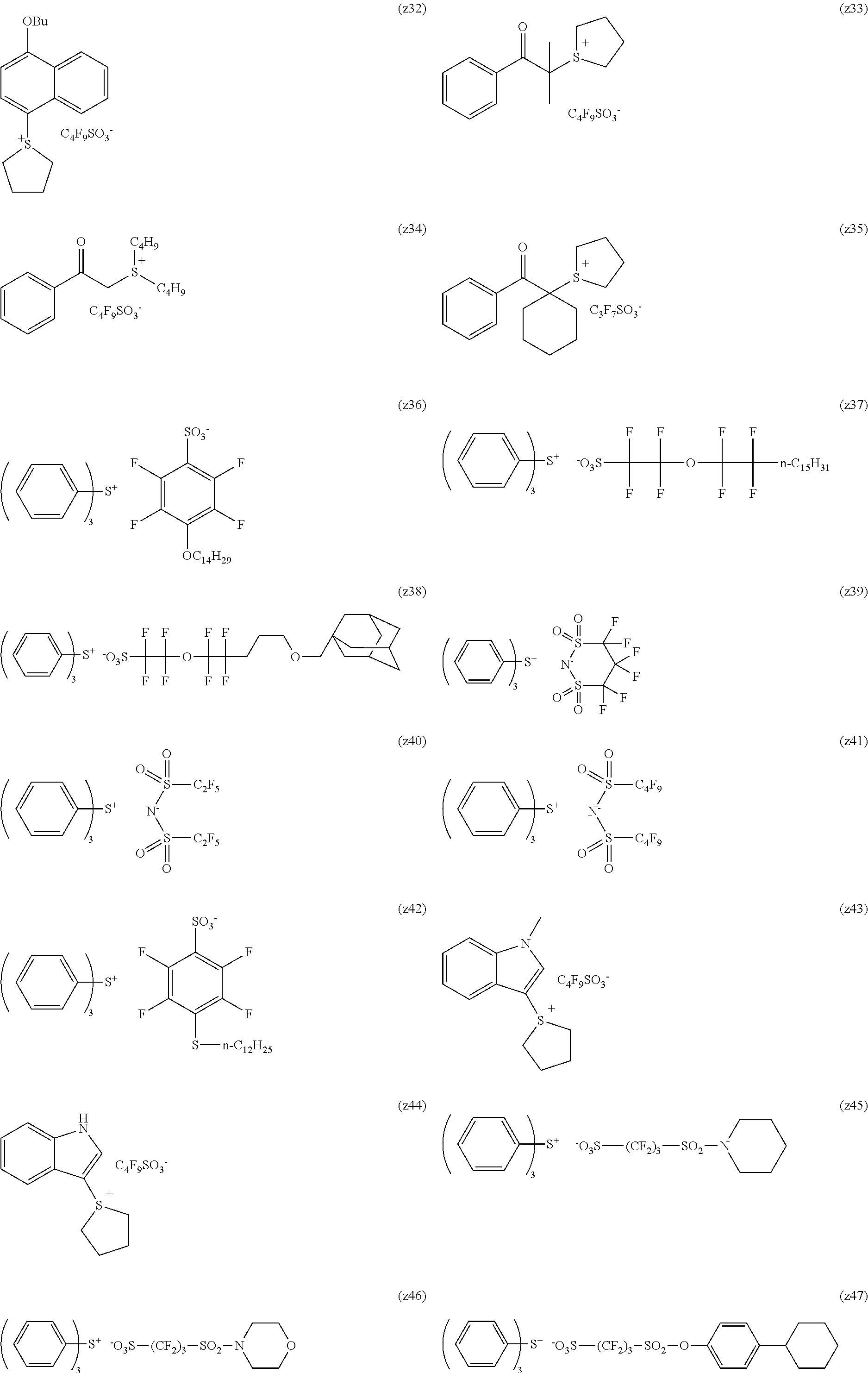

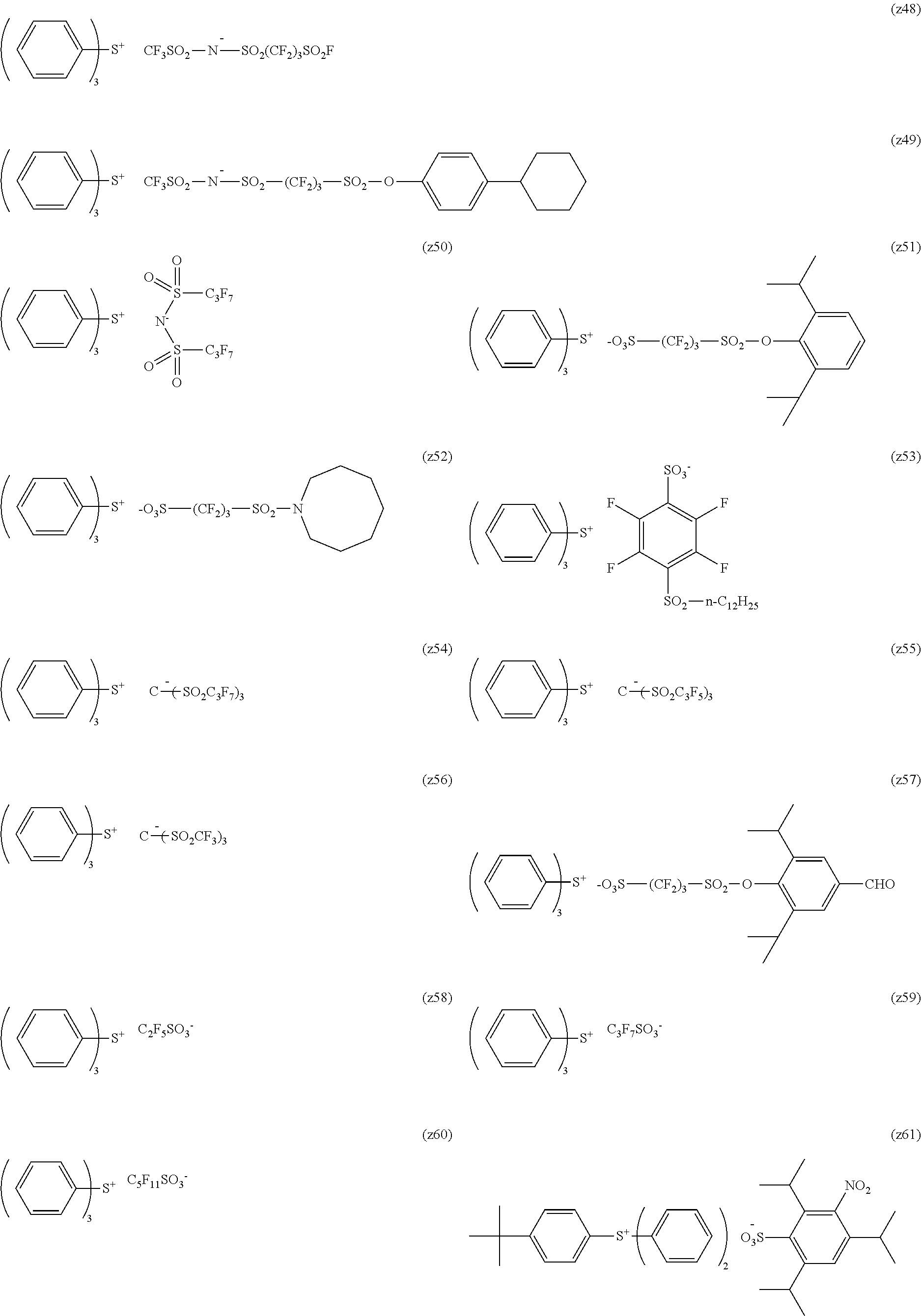

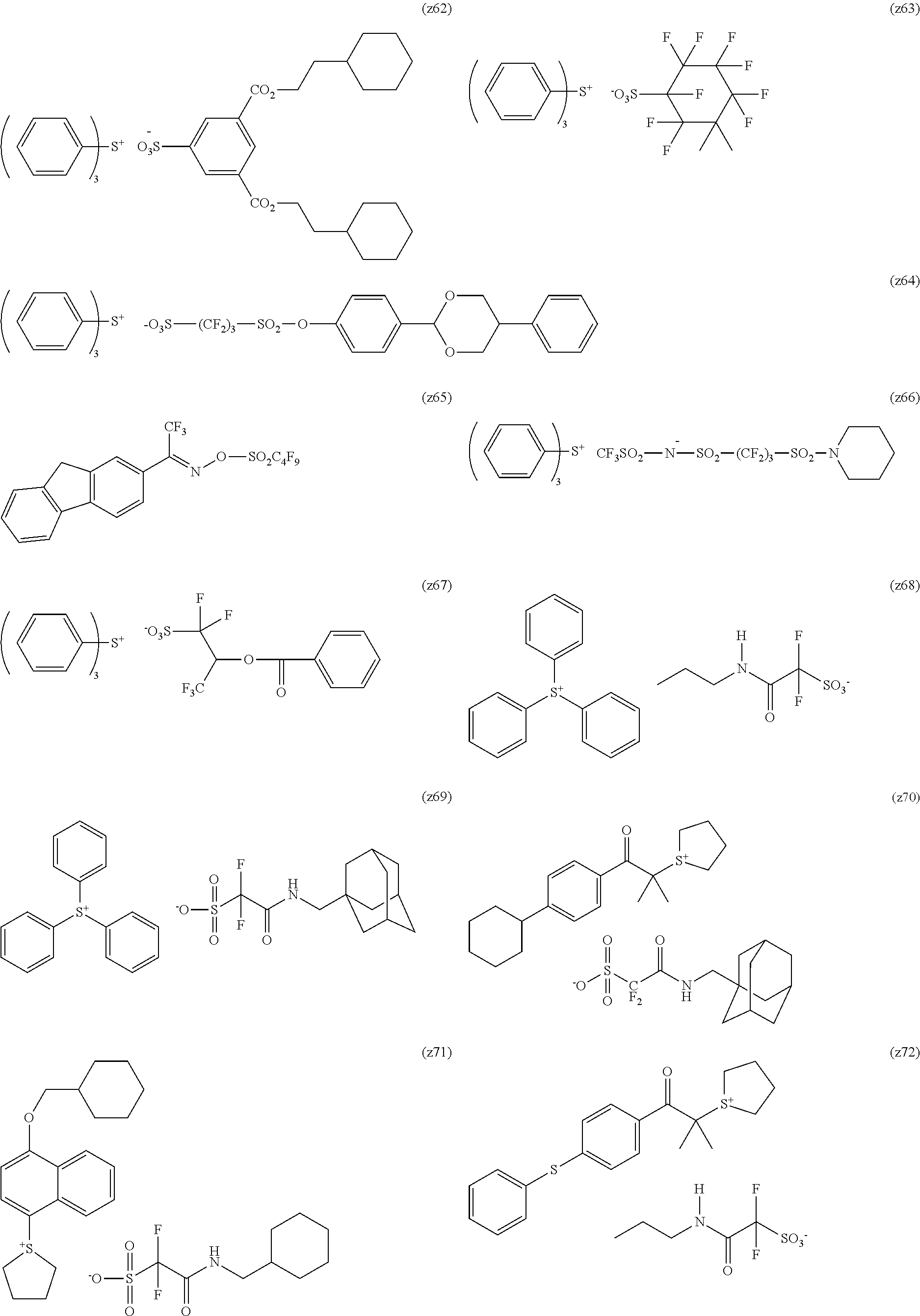

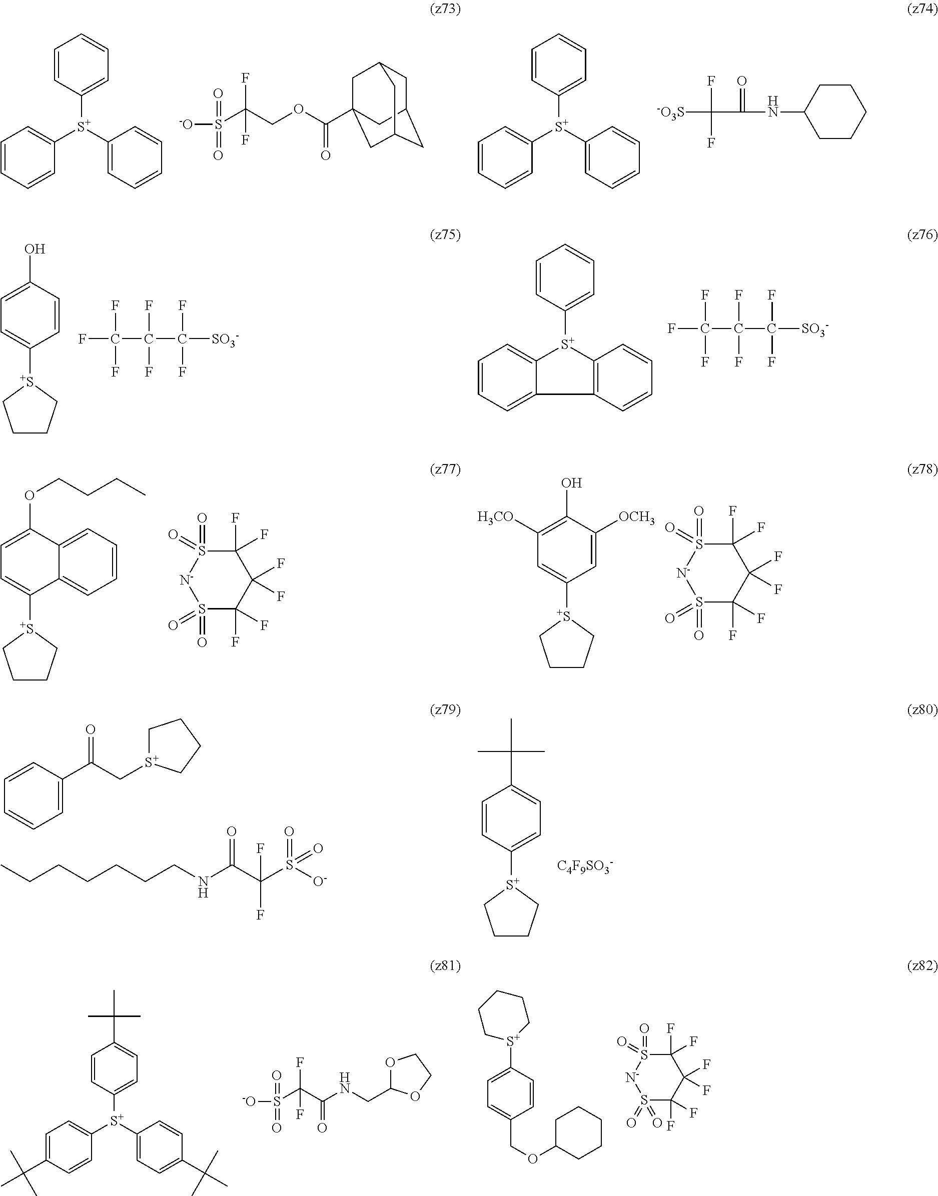

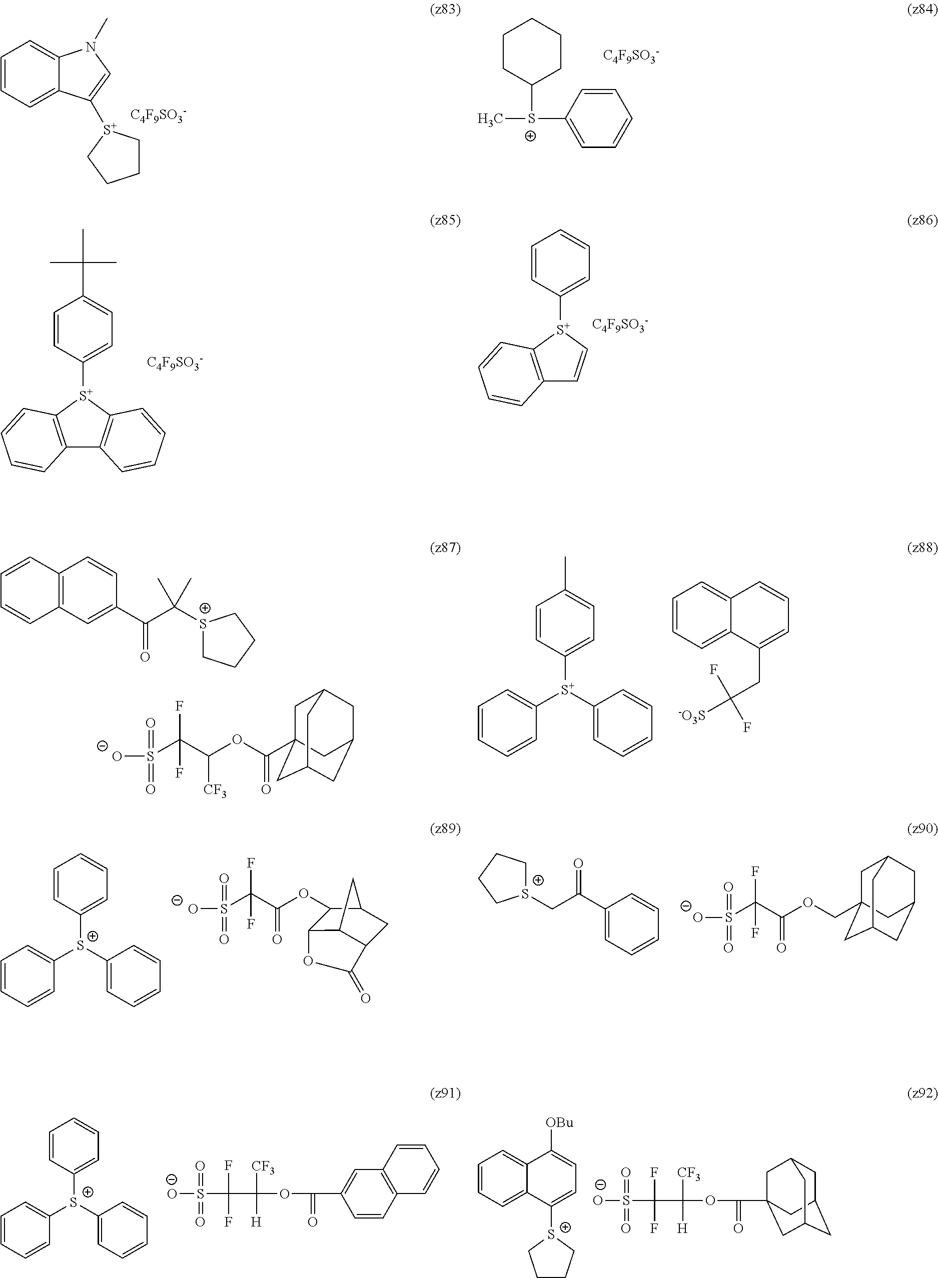

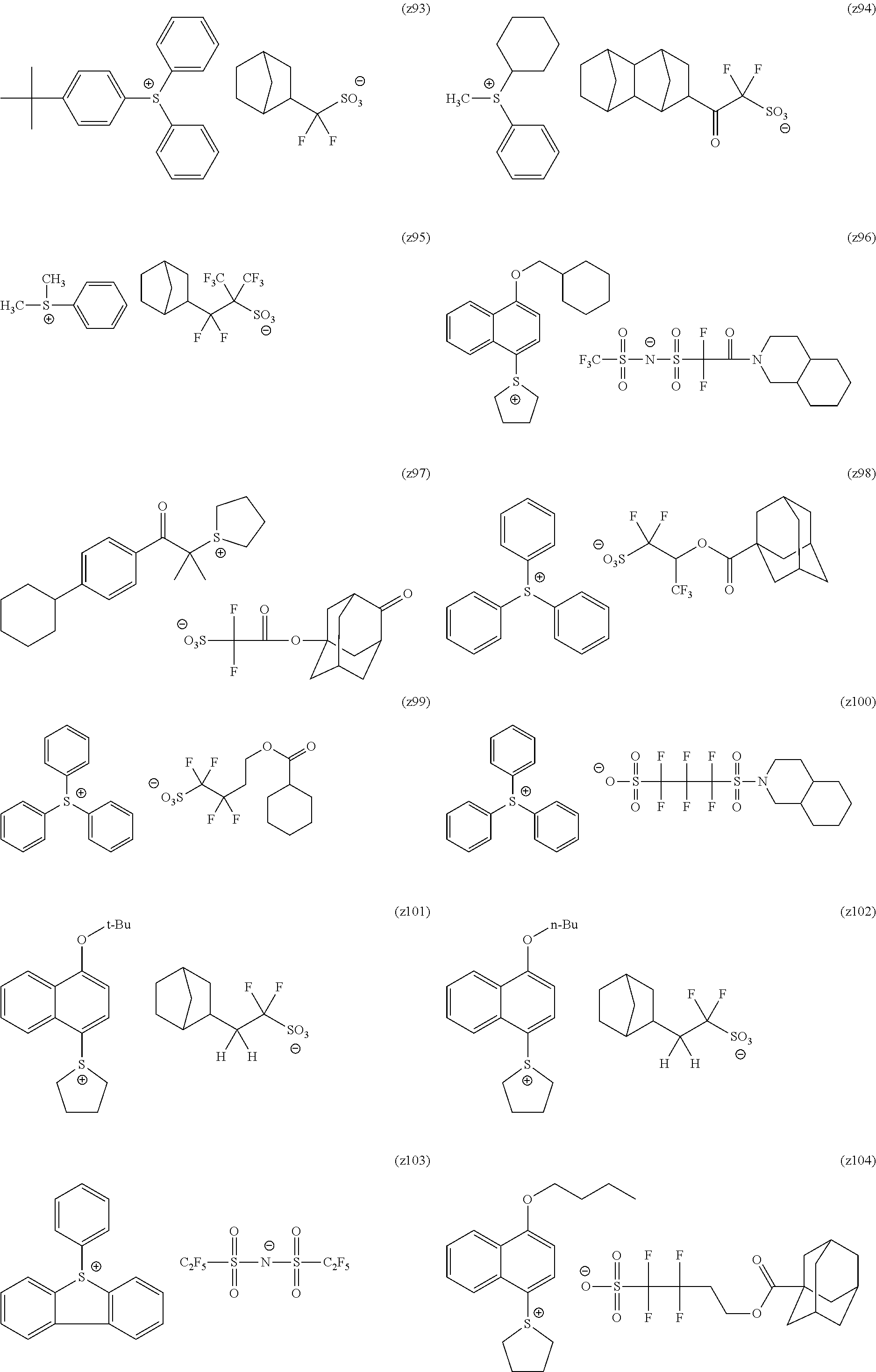

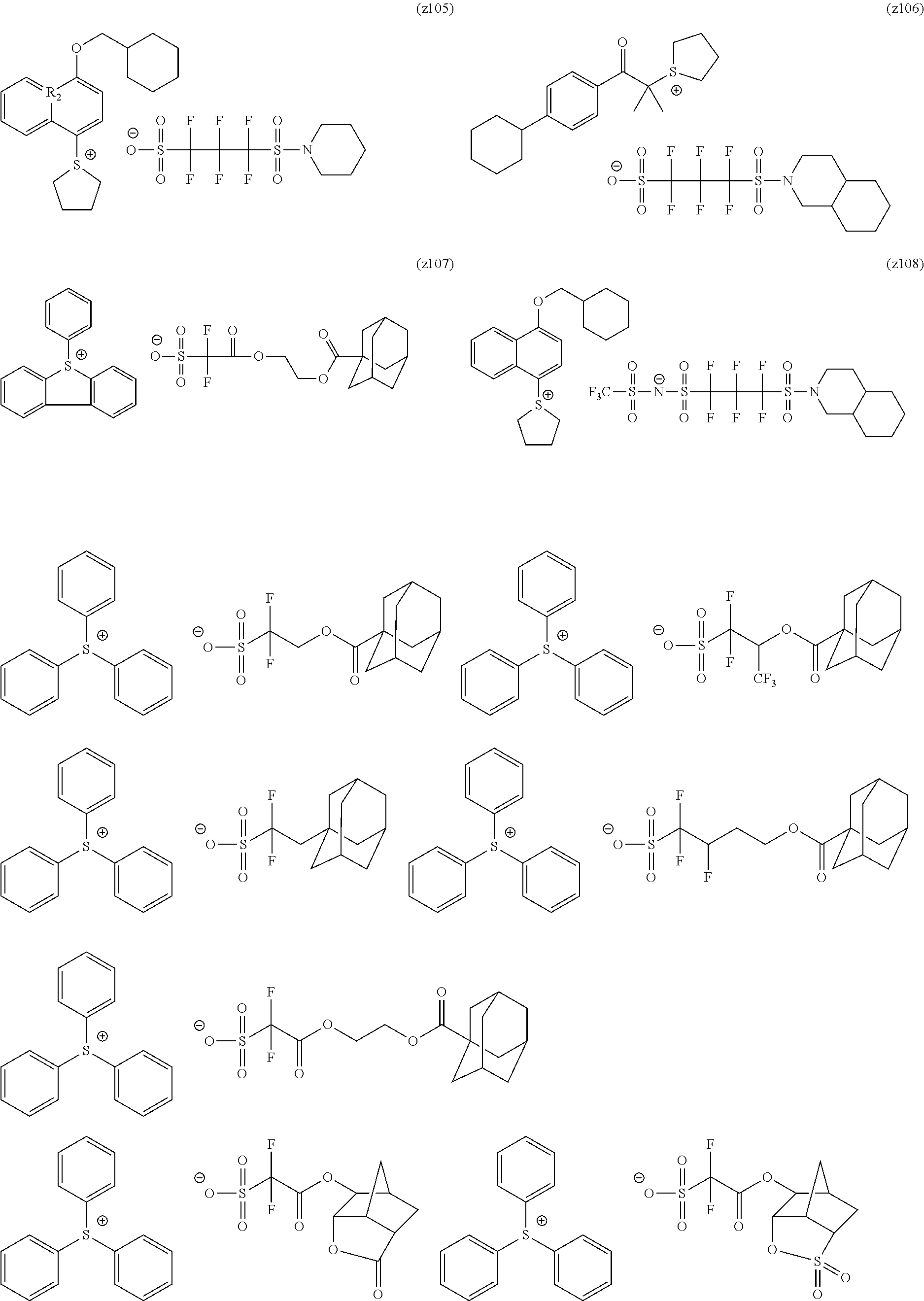

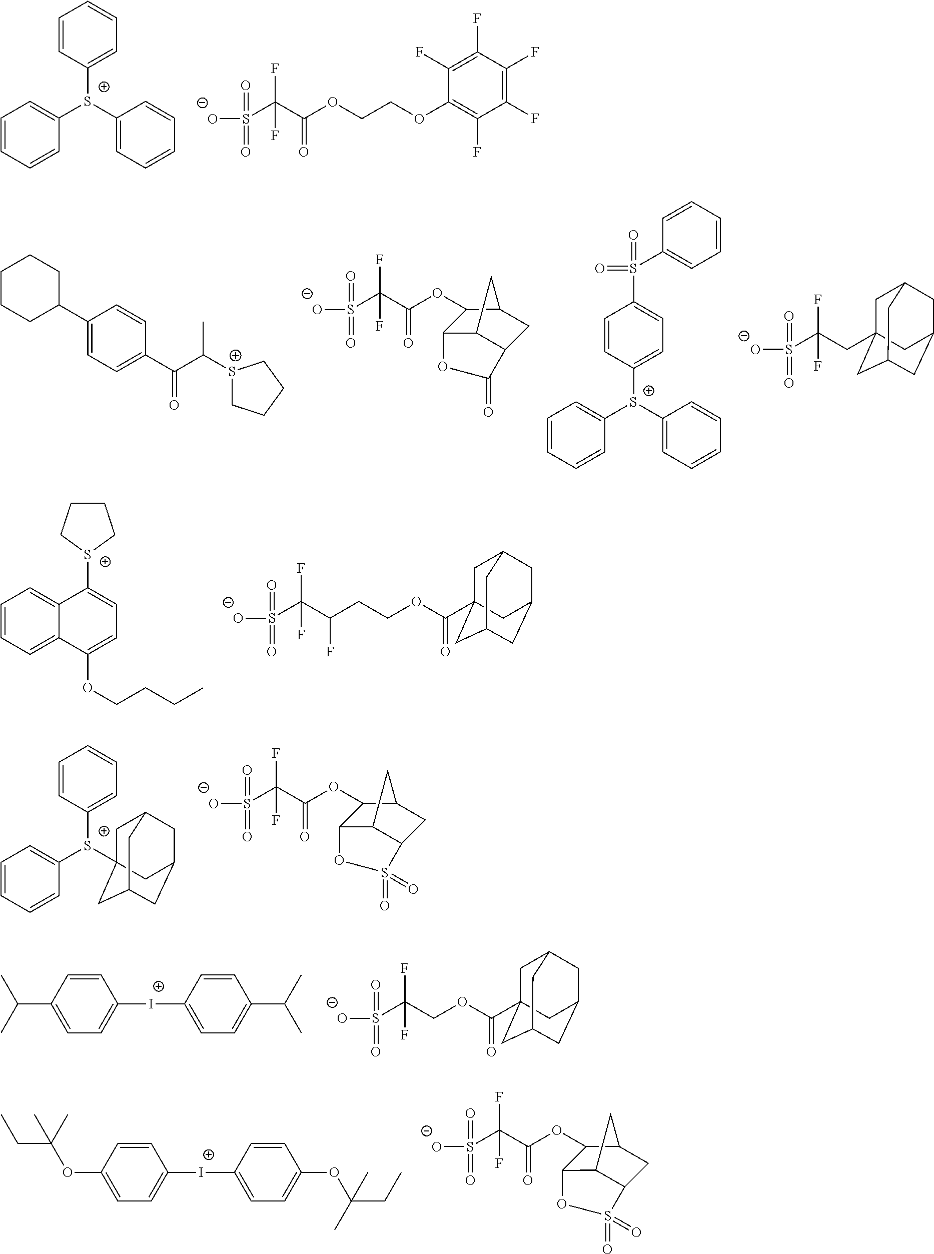

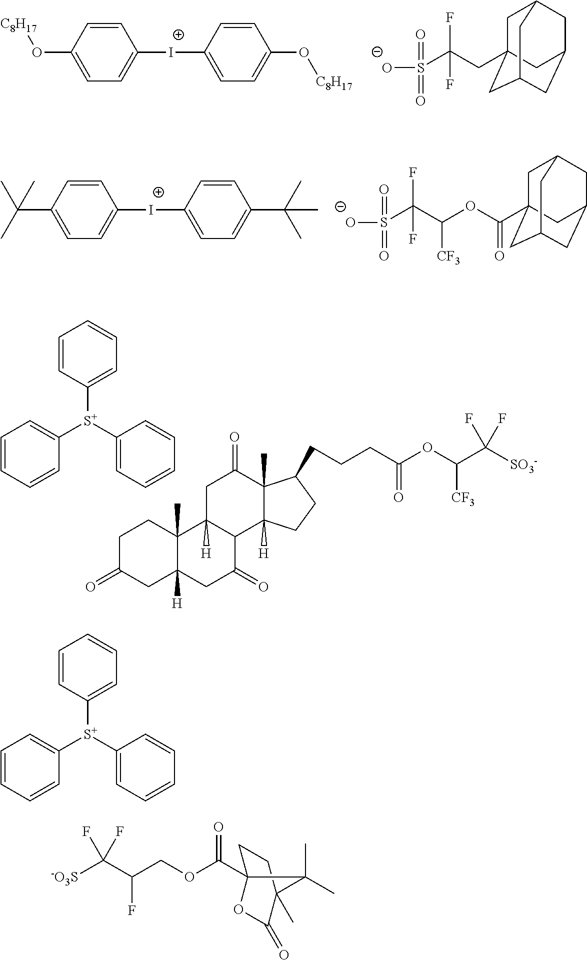

The acid generators can be synthesized by a known method, and can be synthesized in accordance with the method described in, for example, JP2007-161707A, [0200] to [0210] of JP2010-100595A, [0051] to [0058] of WO2011/093280A, [0382] to [0385] of WO2008/153110A, JP2007-161707A, or the like.

The acid generators can be used alone or in combination of two or more kinds thereof.

The content of the compound capable of generating an acid by irradiation with actinic rays or radiation in the resist composition is preferably from 0.1% by mass to 30% by mass, more preferably from 0.5% by mass to 25% by mass, still more preferably from 3% by mass to 20% by mass, and particularly preferably from 3% by mass to 15% by mass, with respect to the total solid content of the resist composition.

Incidentally, depending on the resist composition, there is an embodiment (B′) in which the structure corresponding to the acid generator is supported on the resin (A). Specific examples of such an embodiment include the structures described in JP2011-248019A (in particular, the structures described in paragraphs 0164 to 0191, and the structures included in the resin described in Examples of paragraph 0555). In addition, even in the embodiment in which the structure corresponding to the acid generator is supported on the resin (A), the resist composition may further contain an acid generator which is not supported on the resin (A).

Examples of the embodiment (B′) include, but are not limited to, the repeating units as described below.

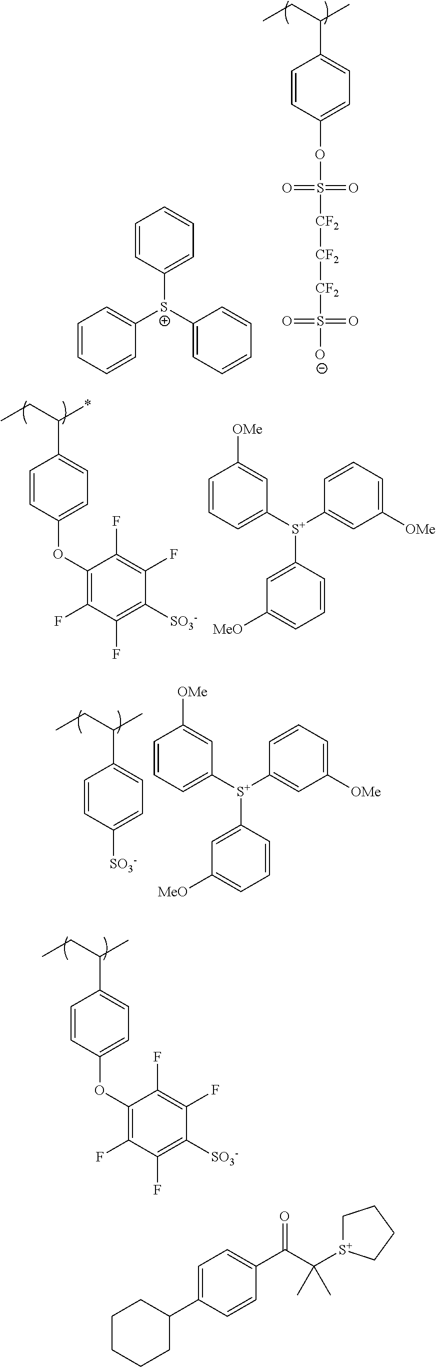

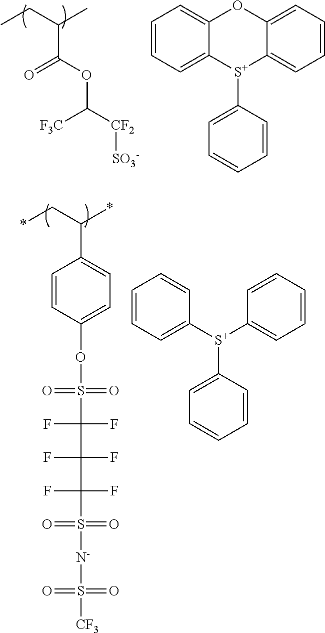

[3] Solvent

The resist composition preferably contains a solvent.

Examples of the solvent which can be used in the preparation of the resist composition include an organic solvent such as alkylene glycol monoalkyl ether carboxylate, alkylene glycol monoalkyl ether, alkyl lactate ester, alkyl alkoxypropionate, cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of these solvents include ones described in, for example, [0441] to [0455] of US 2008/0187860A.

In the present invention, a mixed solvent of a solvent containing a hydroxyl group in the structure and a solvent containing no hydroxyl group may be used as the organic solvent.

The solvent containing a hydroxyl group and the solvent containing no hydroxyl group can be suitably selected from the exemplary compounds as mentioned above. However, as the solvent containing a hydroxyl group, alkylene glycol monoalkyl ether, alkyl lactate ester, or the like is preferred, and propylene glycol monomethyl ether (PGME, alternative name: 1-methoxy-2-propanol) or ethyl lactate is more preferred. Further, as the solvent containing no hydroxyl group, alkylene glycol monoalkyl ether acetate, alkyl alkoxy propionate, a monoketone compound which may contain a ring, cyclic lactone, alkyl acetate, or the like is preferred. Among these, propylene glycol monomethyl ether acetate (PGMEA, alternative name: 1-methoxy-2-acetoxypropane), ethylethoxypropionate, 2-heptanone, α-butyrolactone, cyclohexanone, and butyl acetate are particularly preferred, and propylene glycol monomethyl ether acetate, ethylethoxypropionate, and 2-heptanone are most preferred.

The mixing ratio (mass) of the solvent containing a hydroxyl group to the solvent containing no hydroxyl group is from 1/99 to 99/1, preferably from 10/90 to 90/10, and more preferably from 20/80 to 60/40. A mixed solvent having 50% by mass or more of the solvent containing no hydroxyl group is particularly preferred in view of application.

The solvent preferably contains propylene glycol monomethyl ether acetate, and is preferably a solvent composed of propylene glycol monomethyl ether acetate alone or a mixed solvent of two or more kinds of solvents including propylene glycol monomethyl ether acetate.

[4] Hydrophobic Resin (D)

The resist composition preferably contains a hydrophobic resin (hereafter also referred to as a “hydrophobic resin (D)” or simply a “resin (D)”), particularly when the composition is applied to liquid immersion exposure. Incidentally, it is preferable that the hydrophobic resin (D) is different from the resin (A).

With this, the hydrophobic resin (D) is unevenly distributed to the film surface layer, and in the case where the liquid immersion medium is water, the static/dynamic contact angle of the resist film surface with respect to water is improved, which can enhance the followability of the immersion liquid. Further, in the case of EUV exposure, it can be expected that a so-called outgas can be inhibited.

It is preferable that the hydrophobic resin (D) is designed to be unevenly distributed to the interface as mentioned above, but in contrast to a surfactant, the resin (D) is not necessarily required to have a hydrophilic group in the molecule, and may not contribute to uniform mixing of polar/nonpolar materials.

The hydrophobic resin (D) is a material which is frequently used in the case of so-called liquid immersion exposure. However, it is literally hydrophobic, and therefore, hardly dissolved in an alkaline aqueous peeling solution, and there is a concern about causing adverse effects such as generation of residues of the resist. In this regard, when the peeling solution of the present application is used, there is little concern about such adverse effects.

From the viewpoint of unevenly distribution to the film surface layer, it is preferable that the hydrophobic resin (D) contains at least any one kind of a “fluorine atom”, a “silicon atom”, and a “CH₃ partial structure contained in the side chain portion of the resin”, and it is more preferable that the resin (D) contains two or more kinds thereof.

The weight-average molecular weight of the hydrophobic resin (D) in terms of standard polystyrene is preferably from 1,000 to 100,000, more preferably from 1,000 to 50,000, and still more preferably from 2,000 to 15,000.

Furthermore, the hydrophobic resins (D) may be used alone or in combination of two or more kinds thereof.

The content of the hydrophobic resin (D) in the resist composition is preferably from 0.01% by mass to 10% by mass, more preferably from 0.05% by mass to 8% by mass, and still more preferably from 0.1% by mass to 7% by mass, with respect to the total solid content of the resist composition.

In the hydrophobic resin (D), similarly to the resin (A), it is certain that the content of impurities such as metal is small, but the content of residual monomers or oligomer components is also preferably from 0.01% by mass to 5% by mass, more preferably from 0.01% by mass to 3% by mass, and still more preferably from 0.05% by mass to 1% by mass. Within these ranges, a resist composition free from in-liquid extraneous materials and a change in the sensitivity with aging or the like can be obtained. Further, in view of a resolution, a resist profile, the side wall of a resist pattern, a roughness, and the like, the molecular weight distribution (Mw/Mn, also referred to as a dispersity) is preferably in the range of 1 to 5, more preferably 1 to 3, and still more preferably 1 to 2.

As the hydrophobic resin (D), various commercial products may be used, or the resin may be synthesized by an ordinary method (for example, radical polymerization). Examples of the general synthesis method include a batch polymerization method of dissolving monomer species and an initiator in a solvent and heating the solution, thereby carrying out the polymerization, and a dropping polymerization method of adding dropwise a solution containing monomer species and an initiator to a heated solvent for 1 hour to 10 hours, among which the dropping polymerization method is preferred.

The reaction solvent, the polymerization initiator, the reaction conditions (a temperature, a concentration, and the like) and the method for purification after reaction are the same as ones described for the resin (A), but in the synthesis of the hydrophobic resin (D), the concentration at the reaction is preferably from 30% by mass to 50% by mass. More specifically, the method described in, for example, around the paragraphs 0320 to 0329 of JP2008-292975A, can be exemplified.

Specific examples of the hydrophobic resin (D) are shown below. Further, the molar ratio of the repeating units (the respective repeating units being shown in order starting from the left side), the weight-average molecular weight, and the dispersity of the respective resins are shown in the following tables.

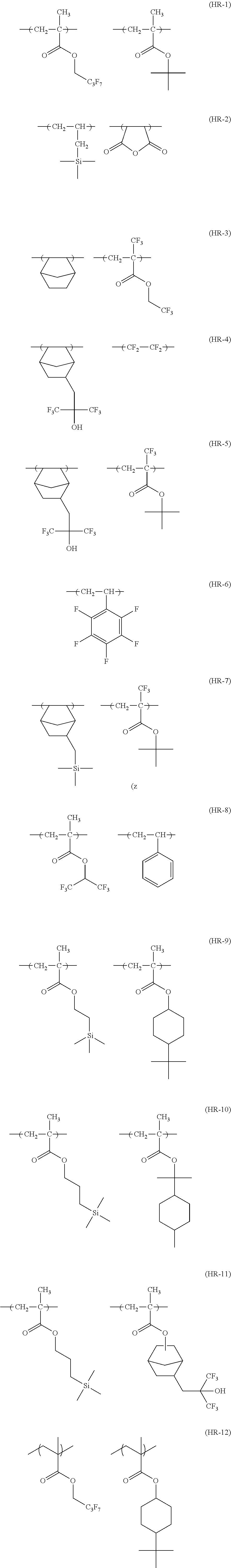

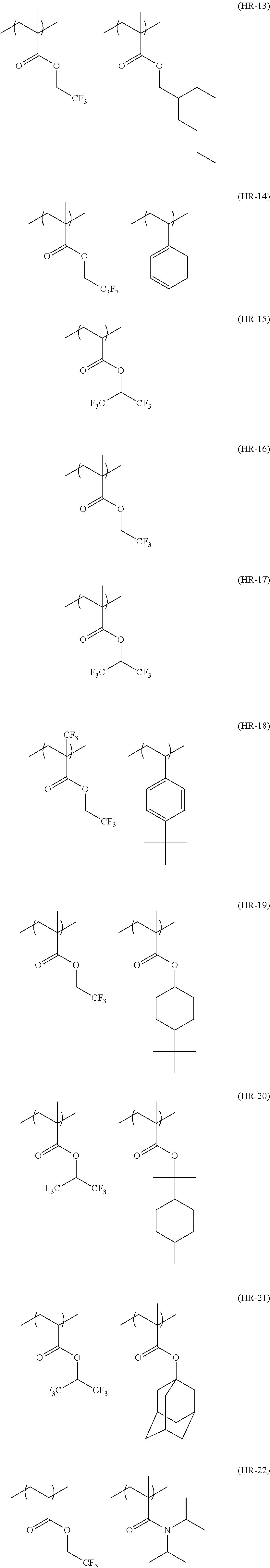

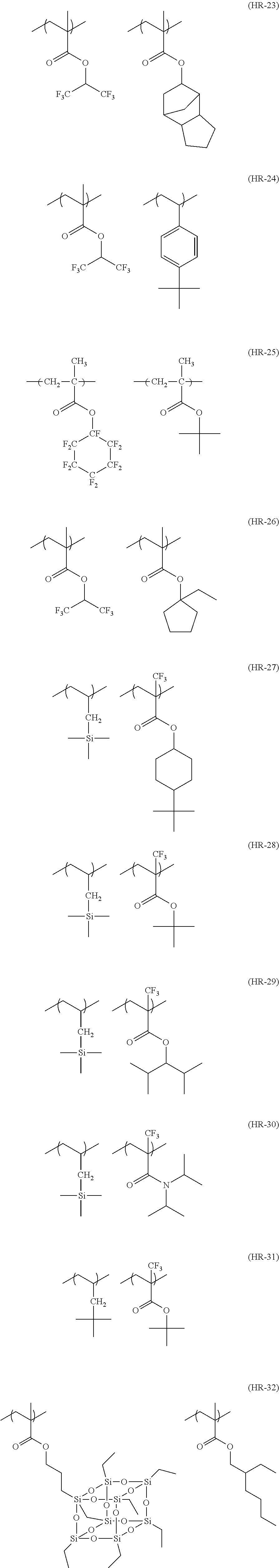

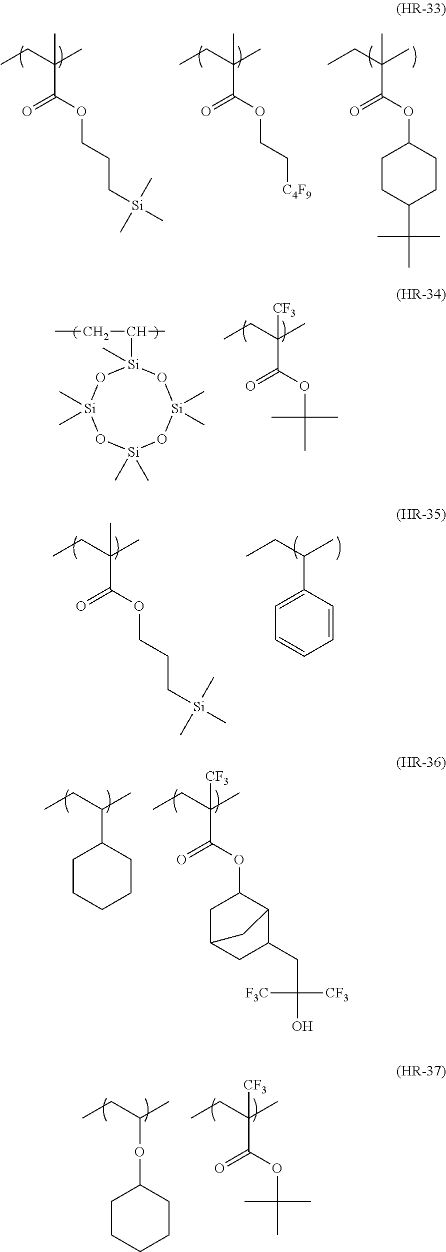

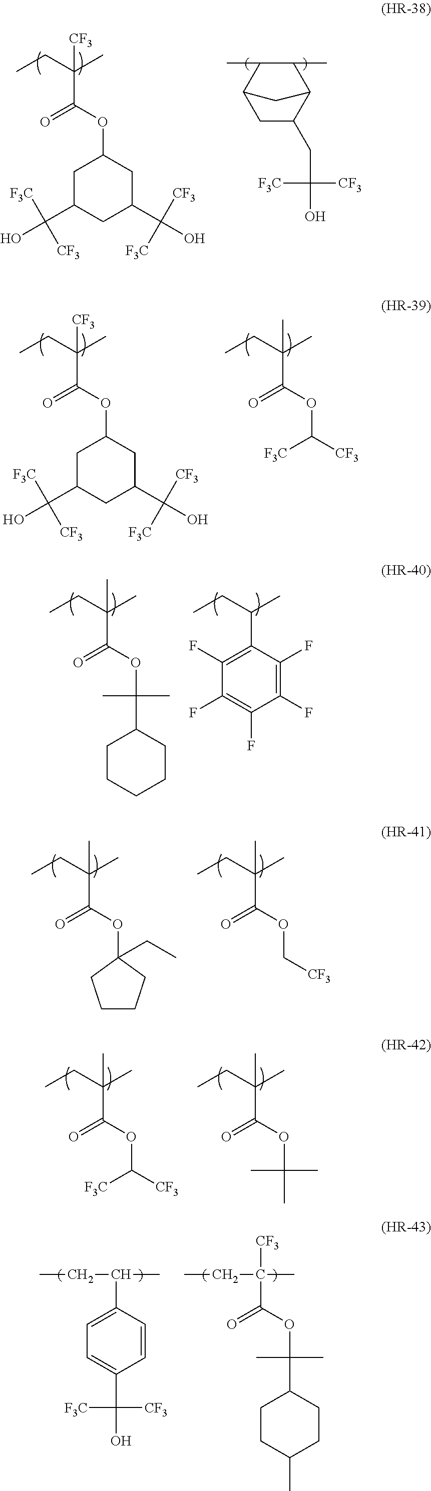

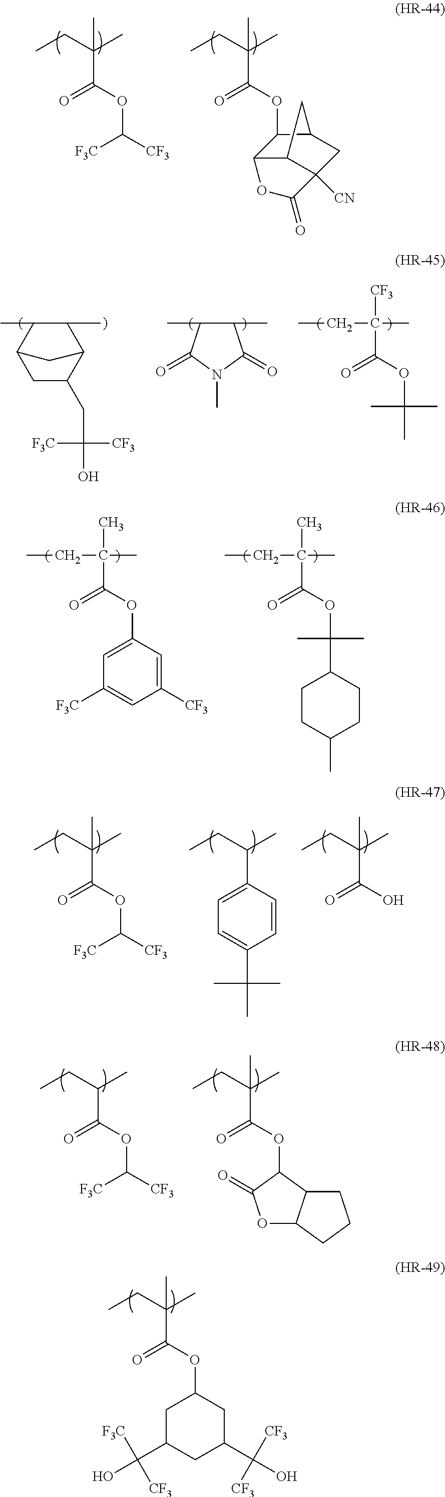

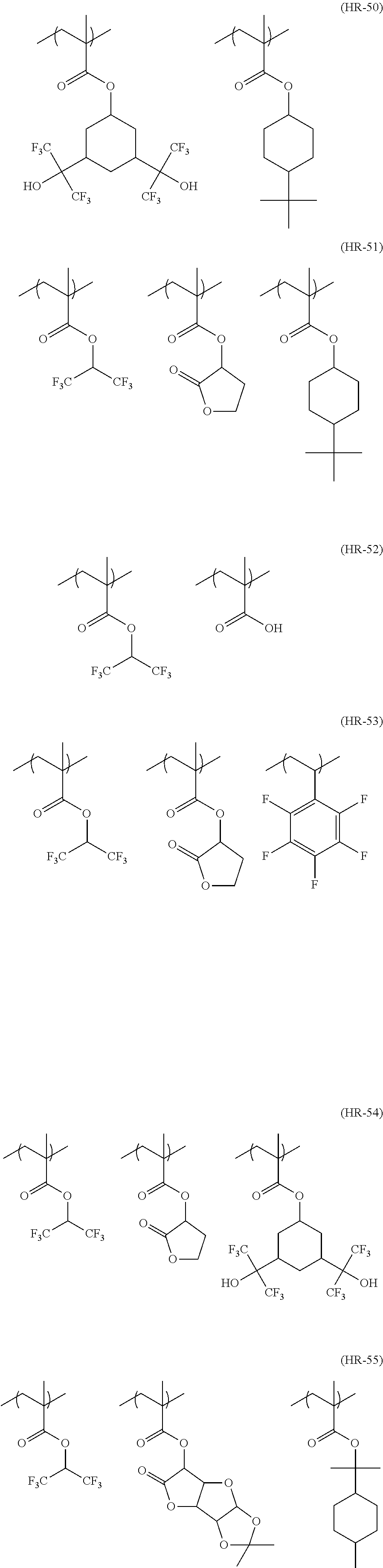

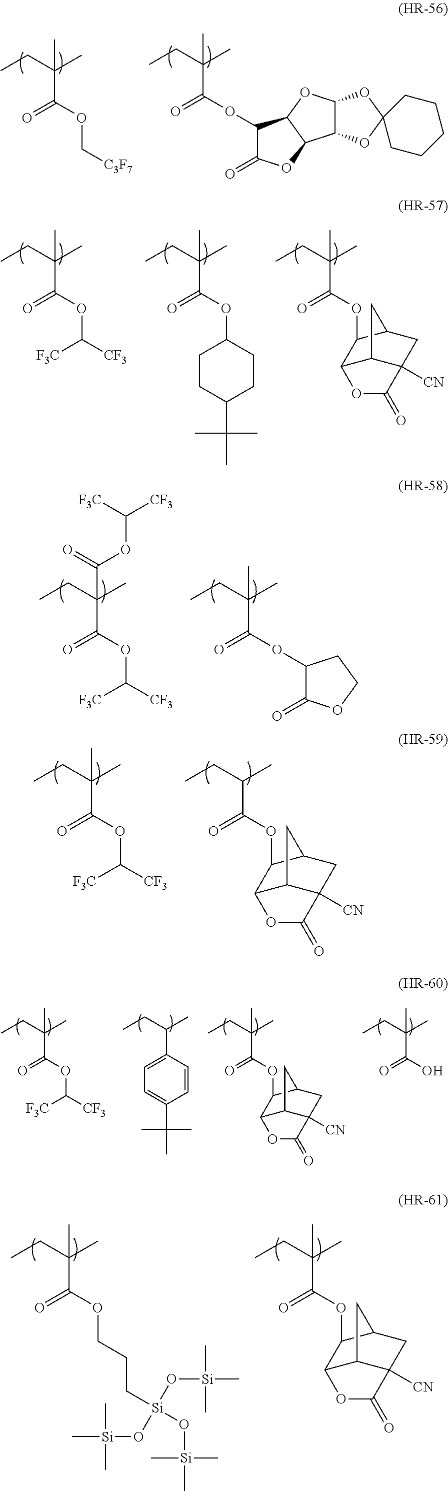

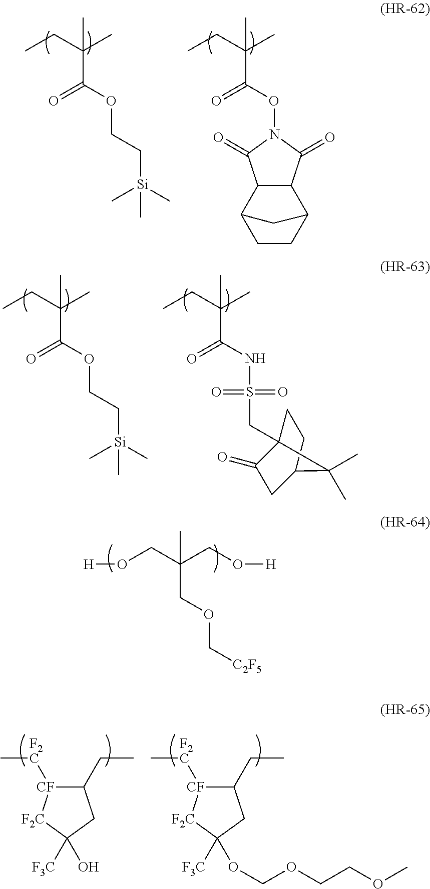

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

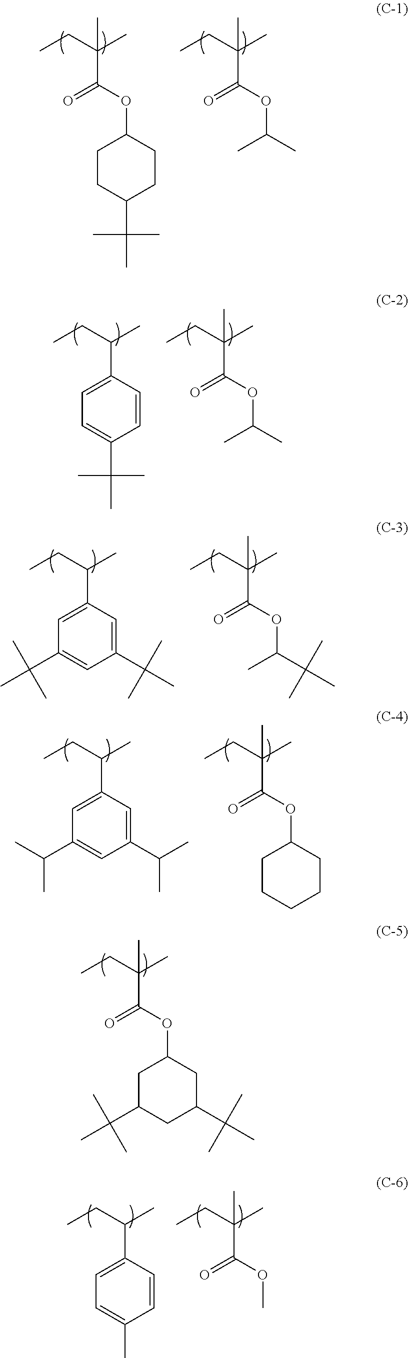

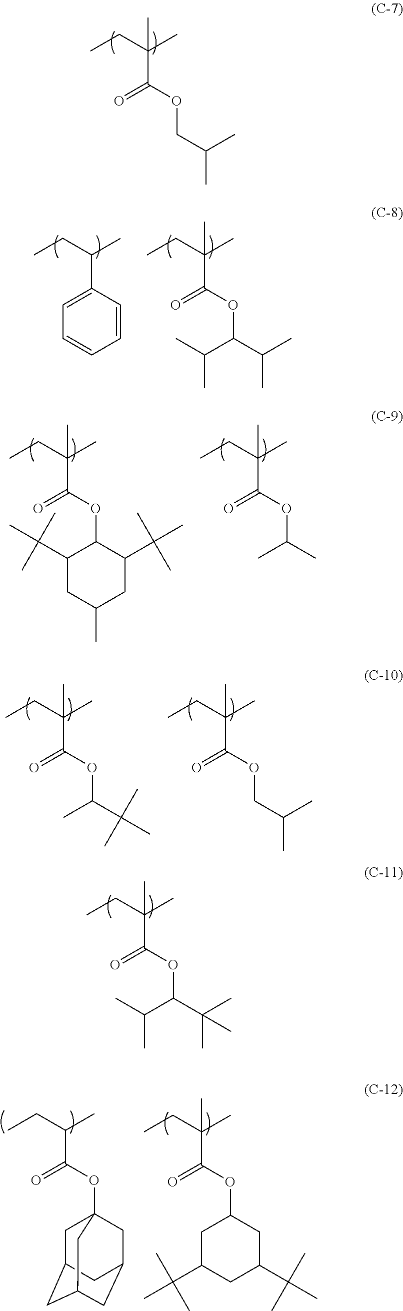

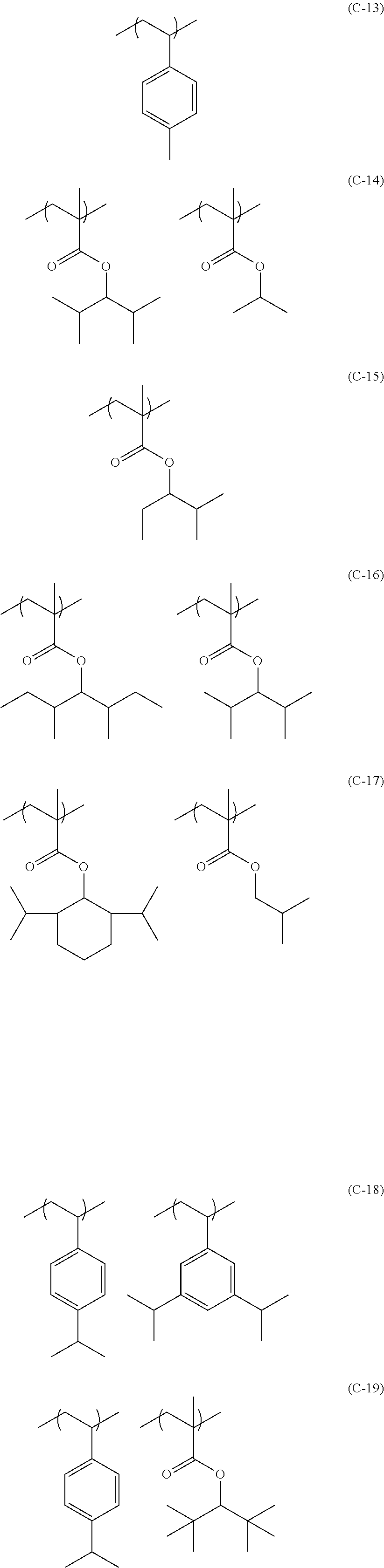

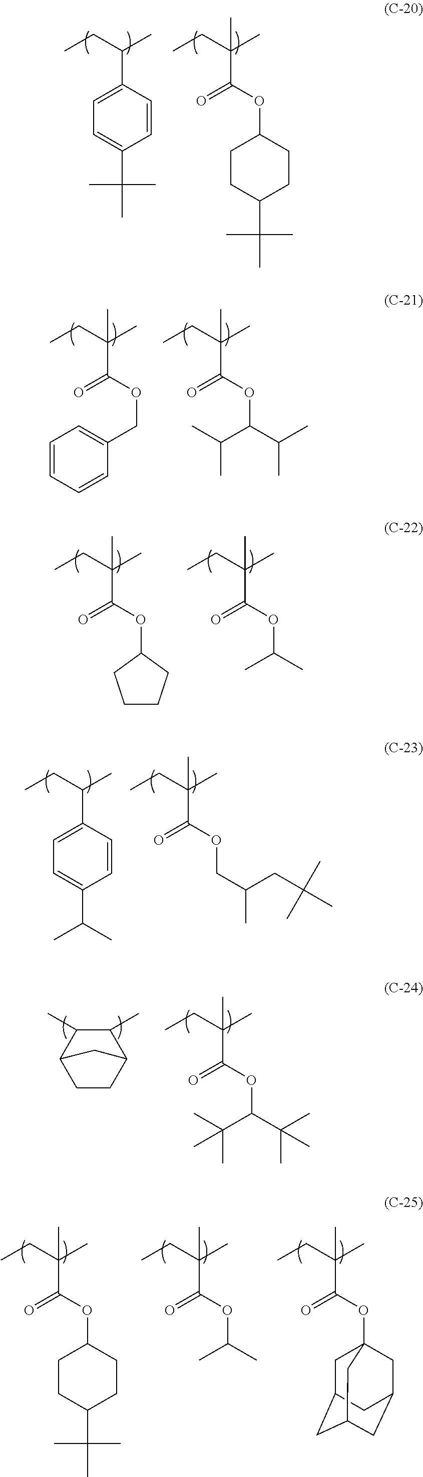

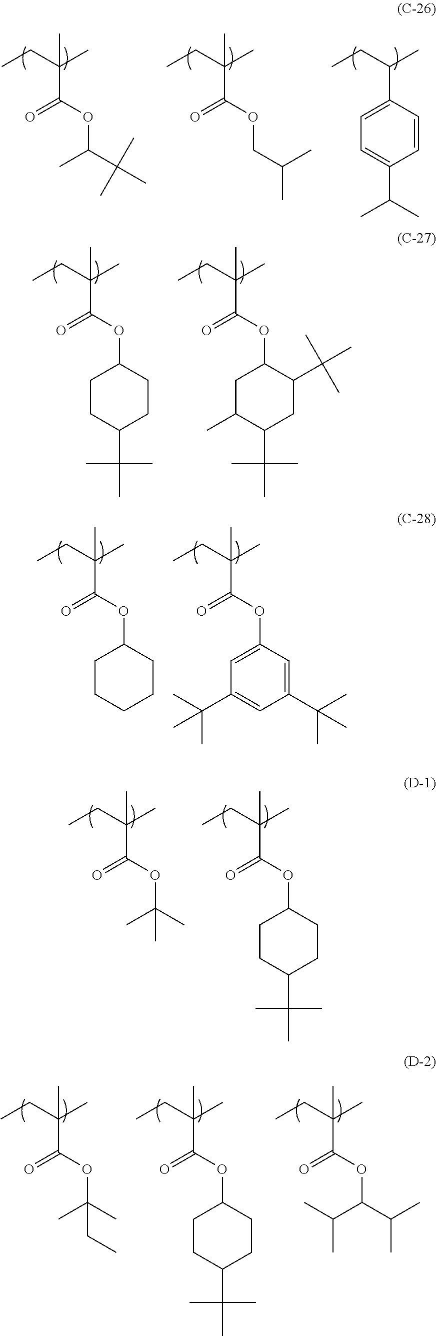

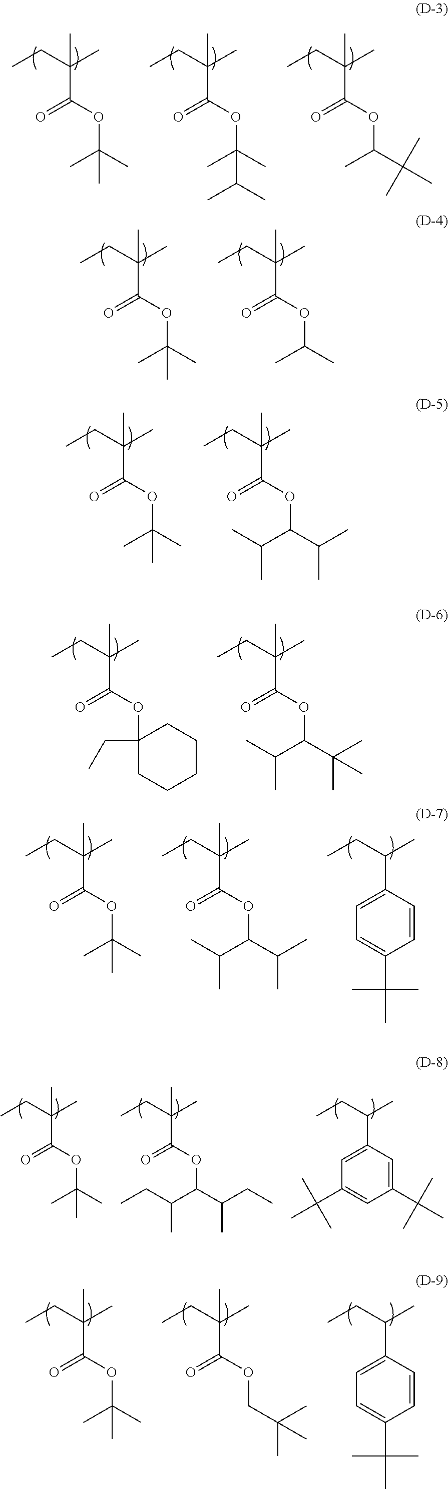

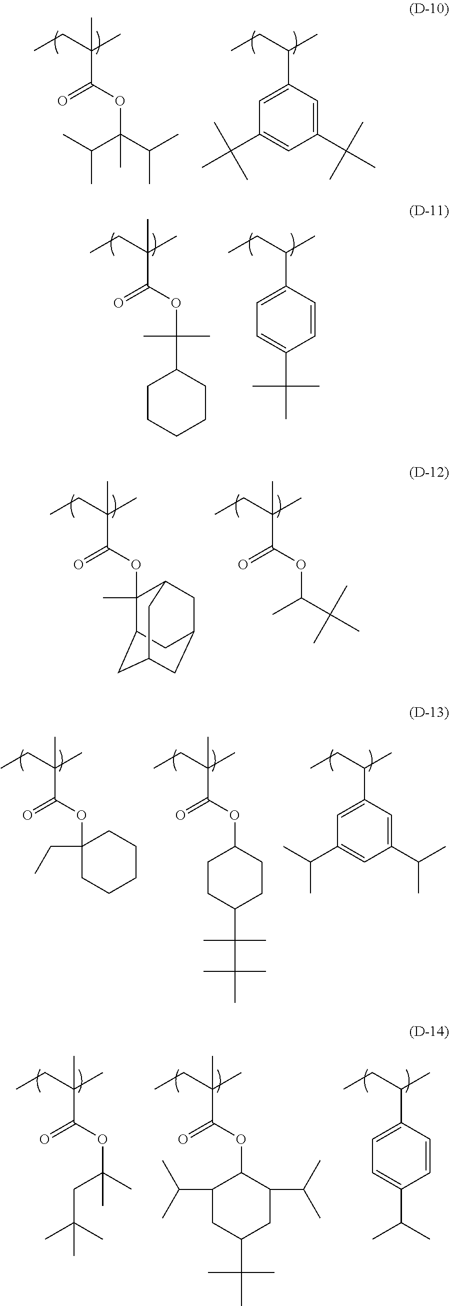

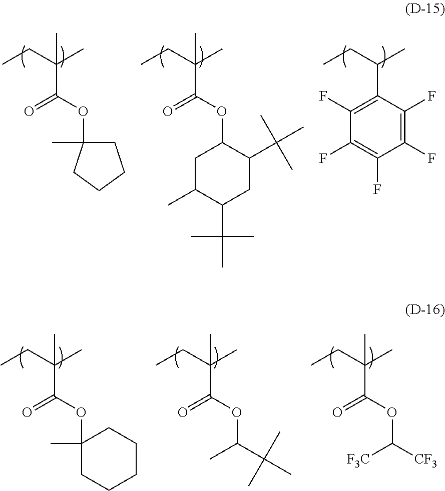

TABLE 2

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 3

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5] Basic Compound

The resist composition preferably contains a basic compound.

(1) In one embodiment, the resist composition preferably contains a basic compound or an ammonium salt compound (hereinafter, also referred to as a “compound (N)”) whose basicity is decreased by irradiation with actinic rays or radiation as the basic compound.

The compound (N) is preferably a compound (N-1) having a basic functional group or an ammonium group, and a group capable of generating an acidic functional group by irradiation with actinic rays or radiation. That is, the compound (N) is preferably a basic compound having a basic functional group, and a group capable of generating an acidic functional group by irradiation with actinic rays or radiation, or an ammonium salt compound having an ammonium group, and a group capable of generating an acidic functional group by irradiation with actinic rays or radiation.

Specific examples of the compound (N) include the following compounds. Further, in addition to the compounds mentioned above, as the compound (N), for example, the compounds of (A-1) to (A-44) described in US2010/0233629A and the compounds of (A-1) to (A-23) described in US2012/0156617A can also be preferably used in the present invention.

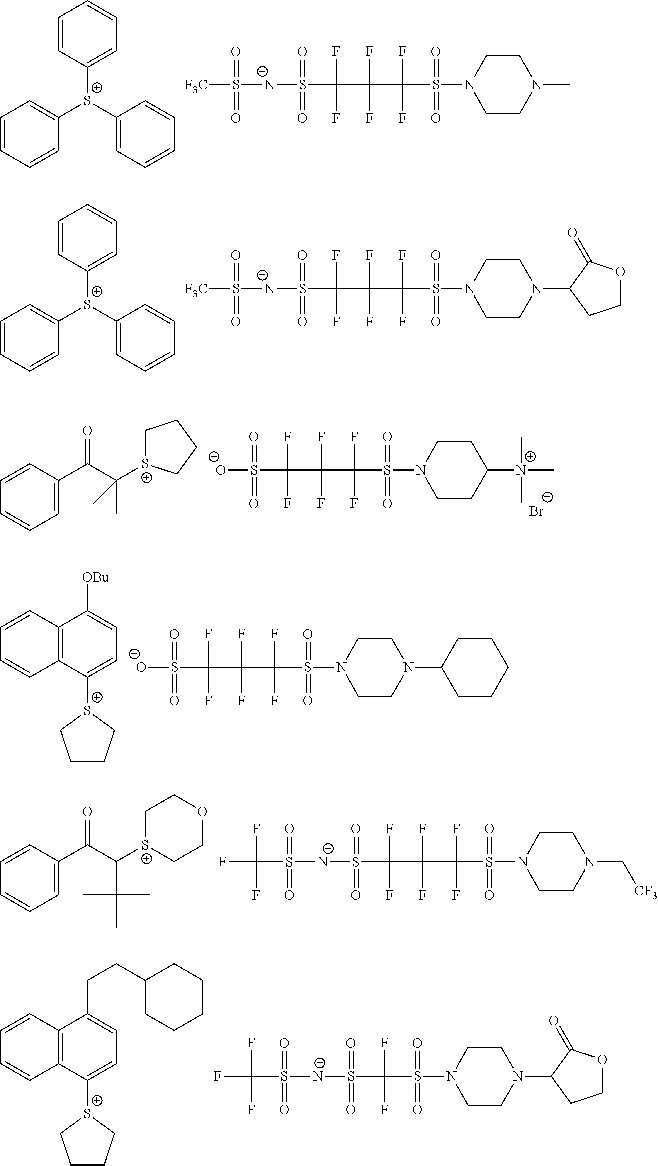

These compounds can be synthesized in accordance with Synthesis Examples described in JP2006-330098A, or the like.

The molecular weight of the compound (N) is preferably from 500 to 1,000.

The resist composition may or may not contain a compound (N), but in the case where the compound (N) is contained, the content of the compound (N) is preferably from 0.1% by mass to 20% by mass, and more preferably from 0.1% by mass to 10% by mass, with respect to the solid content of the composition.

(2) The resist composition may contain a basic compound (N′) other than the compound (N) as the basic compound in order to reduce a change in performance with aging from exposure to heating.

Preferred examples of the basic compound (N′) include compounds having structures represented by the following General Formulae (A′) to (E′).

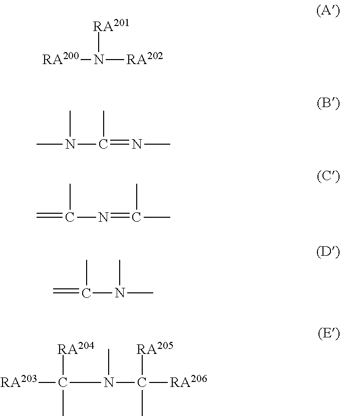

In General Formulae (A′) and (E′),

RA²⁰⁰, RA²⁰¹, and RA²⁰², which may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 RA²⁰³, carbon atoms), and RA²⁰¹ and RA²⁰² may be bonded to each other to form a ring. RA²⁰⁴, RA²⁰⁵ and RA²⁰⁶, which may be the same as or different from each other, each represent an alkyl group (preferably having 1 to 20 carbon atoms).

The alkyl group may have a substituent, and as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferred.

It is more preferable for the alkyl groups in General Formulae (A′) and (E′) to be unsubstituted.

Specific preferred examples of the basic compound (N′) include guanidine, aminopyrrolidine, pyrazole, pyrazoline, piperazine, aminomorpholine, aminoalkylmorpholine, and piperidine. More specific preferred examples thereof include compounds having an imidazole structure, a diazabicyclo structure, an onium hydroxide structure, an onium carboxylate structure, a trialkylamine structure, an aniline structure, or a pyridine structure; alkylamine derivatives having a hydroxyl group and/or an ether bond; and aniline derivatives having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]nona-5-ene, and 1,8-diazabicyclo[5,4,0]undeca-7-ene. Examples of the compound having an onium hydroxide structure include triarylsulfonium hydroxide, phenacylsulfonium hydroxide, sulfonium hydroxide having 2-oxoalkyl group, specifically triphenylsulfonium hydroxide, tris(t-butyl phenyl)sulfonium hydroxide, bis(t-butyl phenyl)iodonium hydroxide, phenacylthiophenium hydroxide, and 2-oxopropylthiophenium hydroxide. The compound having an onium carboxylate structure is a compound in which the anion moiety of the compound having an onium hydroxide structure becomes a carboxylate, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, -, and tris(methoxyethoxyethyl)amine. Examples of the aniline derivative having a hydroxyl group and/or an ether bond include N,N-bis(hydroxyethyl)aniline.

Preferred examples of the basic compound include an amine compound having a phenoxy group, an ammonium salt compound having a phenoxy group, an amine compound having a sulfonic ester group, and an ammonium salt compound having a sulfonic ester group. Specific examples thereof include the compounds (C1-1) to (C3-3) exemplified in paragraph [0066] of US2007/0224539A, but are not limited thereto.

(3) In another embodiment, the resist composition may contain a nitrogen-containing organic compound having a group capable of leaving by the action of an acid as one of the basic compound. As the examples of this compound, specific examples of the compound are shown below.

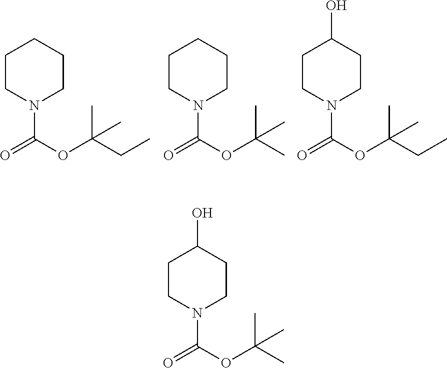

The compounds can be synthesized in accordance with the method described in, for example, JP2009-199021A.

Furthermore, as the basic compound (N′), a compound having an amine oxide structure can also be used. As the specific examples of this compound, triethylaminepyridine N-oxide, tributyl amine N-oxide, triethanolamine N-oxide, tris(methoxyethyl)amine N-oxide, tris(2-(methoxymethoxy)ethyl)amine=oxide, 2,2′,2″-nitrilotriethylpropionate N-oxide, N-2-(2-methoxyethoxy)methoxyethylmorpholine N-oxide, and the amine oxide compounds exemplified in JP2008-102383A in addition to these can also be used.

The molecular weight of the basic compound (N′) is preferably from 250 to 2,000, and more preferably from 400 to 1,000. From the viewpoints of further reduction in LWR (Line Width Roughness) and local pattern dimensional uniformity, the molecular weight of the basic compound is preferably 400 or more, more preferably 500 or more, and still more preferably 600 or more.

This basic compound (N′) may be used in combination with the compound (N), or may be used alone or in combination of two or more kinds thereof.

The resist composition may or may not contain the basic compound (N′), but in the case where the basic compound (N′) is contained, the amount of the basic compound (N′) used is usually from 0.001% by mass to 10% by mass, and preferably from 0.01% by mass to 5% by mass, with respect to the solid content of the resist composition.

(4) In another embodiment, the resist composition may include an onium salt represented by the following General Formula (6A) or (6B) as the basic compound. It is expected that this onium salt regulates the diffusion of generated acids in a resist system in relation to the acid strength of a photoacid generator which is usually used as a resist composition.

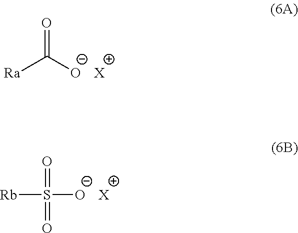

In General Formula (6A),

Ra represents an organic group, provided that any one in which the carbon atom directly bonded to the carboxylic group in the formula is substituted with a fluorine atom is excluded; and

X⁺ represents an onium cation.

In General Formula (6B),

Rb represents an organic group, provided that any one in which the carbon atom directly bonded to the sulfonic acid group in the formula is substituted with a fluorine atom is excluded; and

X⁺ represents an onium cation.

For organic groups represented by Ra and Rb, the atom directly bonded to the carboxylic group, or sulfonic acid group in the formula is preferably a carbon atom. However, in this case, for the realization of a relatively weak acid as compared to the acids generated from the above photoacid generators, the carbon atom directly bonded to the sulfonic acid group or carboxylic group is not substituted with a fluorine atom in any case.

Examples of the organic groups represented by Ra and Rb include an alkyl group having 1 to 20 carbon atoms, a cycloalkyl group having 3 to 20 carbon atoms, an aryl group having 6 to 30 carbon atoms, an aralkyl group having 7 to 30 carbon atoms, and a heterocyclic group having 3 to 30 carbon atoms. In these groups, the hydrogen atoms may be partially or entirely replaced.

Examples of the substituents that can be contained in the alkyl group, the cycloalkyl group, the aryl group, the aralkyl group, and the heterocyclic group include a hydroxyl group, a halogen atom, an alkoxy group, a lactone group, and an alkylcarbonyl group.

Examples of the onium cations represented by X⁺ in General Formulae (6A) and (6B) include a sulfonium cation, an ammonium cation, an iodonium cation, a phosphonium cation, and a diazonium cation, among which the sulfonium cation is more preferred.

As the sulfonium cation, for example, an arylsulfonium cation having at least one aryl group is preferred, and a triarylsulfonium cation is more preferred. The aryl group may have a substituent, and as the aryl group, a phenyl group is preferred.

Preferred examples of the sulfonium cations and the iodonium cations include the structures as described in the compound (B).

Specific structures of the onium salt represented by General Formula (6A) or (6B) are shown below.

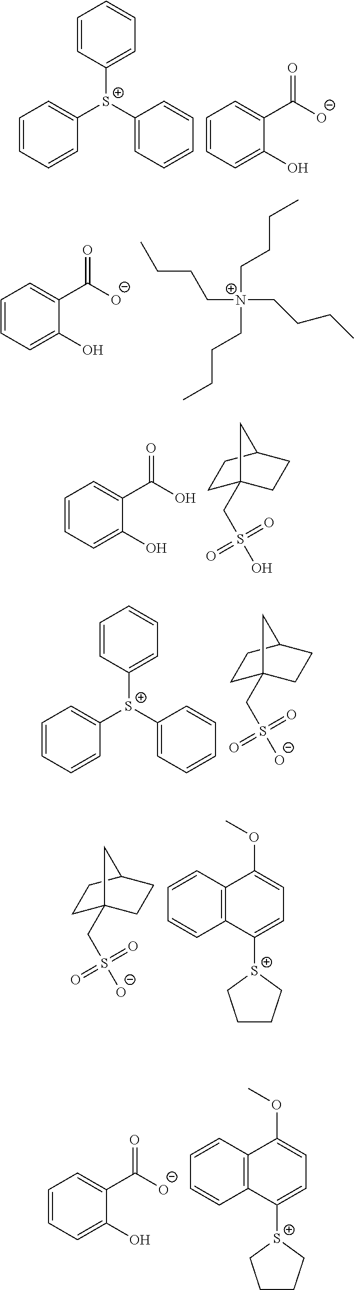

(5) In another embodiment, as the basic compound, the resist composition may contain a compound (hereinafter also referred to as a “betaine compound”) containing both an onium salt structure and an acid anion structure in one molecule, such as the compound represented by Formula (I) in JP2012-189977A, the compound represented by Formula (I) in JP2013-6827A, the compound represented by Formula (I) in JP2013-8020A, and the compound represented by Formula (I) in JP2012-252124A. Examples of the onium salt structure include sulfonium, iodonium, and ammonium structures, among which the sulfonium or iodonium salt structure is preferred. Further, the acid anion structure is preferably a sulfonic acid anion or a carboxylic acid anion. Examples of these compounds are shown below.

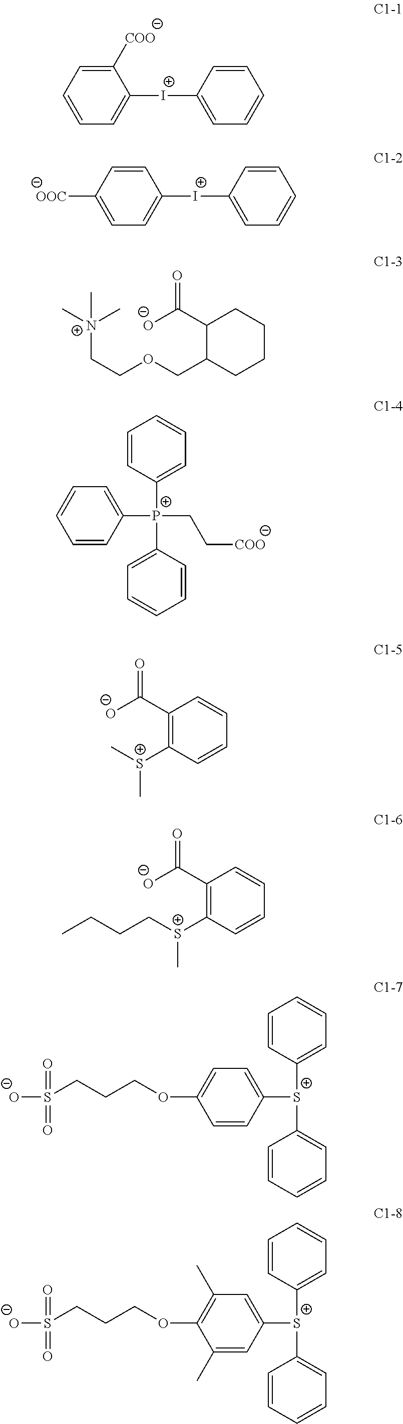

[6] Surfactant

The resist composition may further contain a surfactant. In the case where the resist composition contains a surfactant, it is preferable that it contains any one of fluorine- and/or silicon-based surfactants (a fluorine-based surfactant, a silicon-based surfactant, and a surfactant containing both a fluorine atom and a silicon atom), or two or more kinds thereof.

By incorporating the surfactant into the resist composition, it becomes possible to provide a resist pattern which is improved in sensitivity, resolution, and adhesion, and reduced in development defects when an exposure light source of 250 nm or less, and particularly 220 nm or less, is used.

Examples of the fluorine- and/or silicon-based surfactants include the surfactants described in [0276] of US2008/0248425A, and examples thereof include EFtop EF301 and EF303 (manufactured by Shin-Akita Kasei K.K.); Florad FC430, 431, and 4430 (manufactured by Sumitomo 3M Inc.); Megaface F171, F173, F176, F189, F113, F110, F177, F120, and R08 (manufactured by DIC Corp.); Surflon S-382, SC101, 102, 103, 104, 105, and 106, and KH-20 (manufactured by Asahi Glass Co., Ltd.); Troysol S-366 (manufactured by Troy Chemical); GF-300 and GF-150 (manufactured by Toagosei Chemical Industry Co., Ltd.); Surflon S-393 (manufactured by Seimi Chemical Co., Ltd.); EFtop EF121, EF122A, EF122B, RF122C, EF125M, EF135M, EF351, EF352, EF801, EF802, and EF601 (manufactured by JEMCO Inc.); PF636, PF656, PF6320, and PF6520 (manufactured by OMNOVA); and FTX-204G, 208G, 218G, 230G, 204D, 208D, 212D, 218D, and 222D (manufactured by NEOS Co., Ltd.). In addition, Polysiloxane Polymer KP-341 (manufactured by Shin-Etsu Chemical Co., Ltd.) may also be used as the silicon-based surfactant.

In addition to the known surfactants as shown above, a surfactant using a polymer having a fluoro-aliphatic group derived from a fluoro-aliphatic compound which is produced by a telomerization method (also referred to as a telomer method) or an oligomerization method (also referred to as an oligomer method), may be used as the surfactant. The fluoro-aliphatic compound can be synthesized by the method described in JP2002-90991A.

Examples of the surfactant corresponding to the above include Megaface F178, F-470, F-473, F-475, F-476, and F-472 (manufactured by DIC Corp.); a copolymer of an acrylate (or methacrylate) having a C₆F₁₃ group with a (poly(oxyalkylene)) acrylate (or methacrylate); and a copolymer of an acrylate (or methacrylate) having a C₃F7 group with a (poly(oxyethylene)) acrylate (or methacrylate) and a (poly(oxypropylene)) acrylate (or methacrylate).

In addition, in the present invention, a surfactant other than the fluorine- and/or silicon-based surfactants described in [0280] of US2008/0248425A can also be used.

These surfactants may be used alone or in combination of a few surfactants.

In the case where the resist composition contains the surfactant, the amount of the surfactant used is preferably from 0.0001% by mass to 2% by mass, and more preferably from 0.0005% by mass to 1% by mass, with respect to the total amount of the composition (excluding the solvent).

On the other hand, by setting the amount of the surfactant added to 10 ppm or less with respect to the total amount (excluding the solvent) of the resist composition, the hydrophobic resin is more unevenly distributed to the surface, so that the resist film surface can be made more hydrophobic, which can enhance the followability of water during the liquid immersion exposure.

[7] Other Additives (G)

The resist composition may contain an onium carboxylate salt. Examples of such an onium carboxylate salt include ones described in [0605] to [0606] of US2008/0187860A.

In the case where the resist composition contains an onium carboxylate salt, the content of the salt is generally from 0.1% by mass to 20% by mass, preferably from 0.5 to 10% by mass, and still more preferably from 1% by mass to 7% by mass, with respect to the total solid content of the composition.

Furthermore, the resist composition may contain a so-called acid-increasing agent, if desired. It is preferable that the acid-increasing agent is used, particularly when pattern formation is carried out by EUV exposure or irradiation with electron beams. Specific examples of the acid-increasing agent are not particularly limited, and examples thereof are shown below.

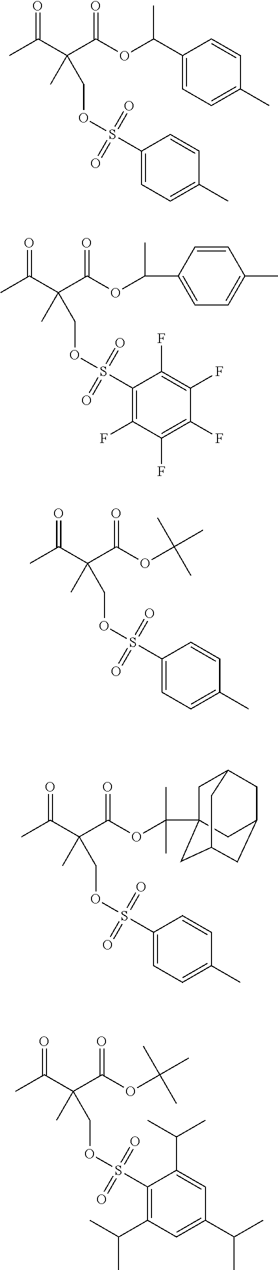

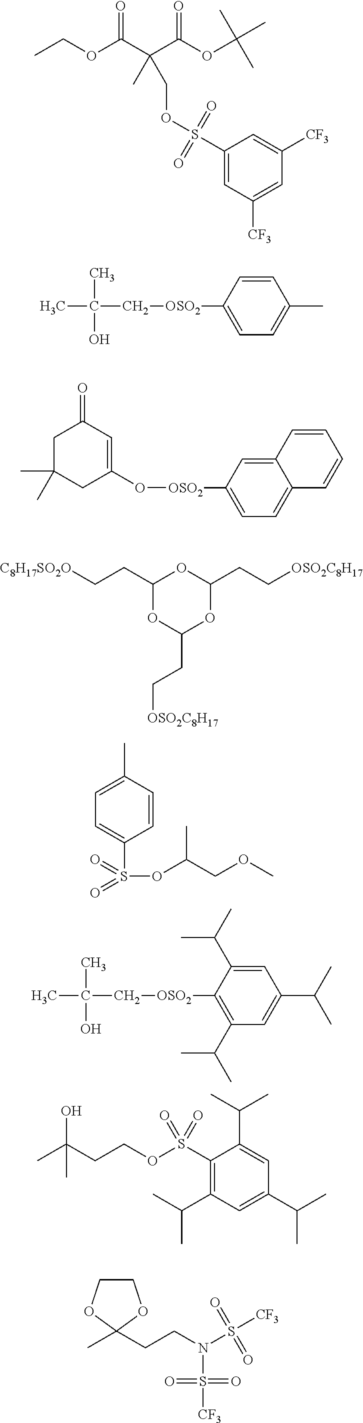

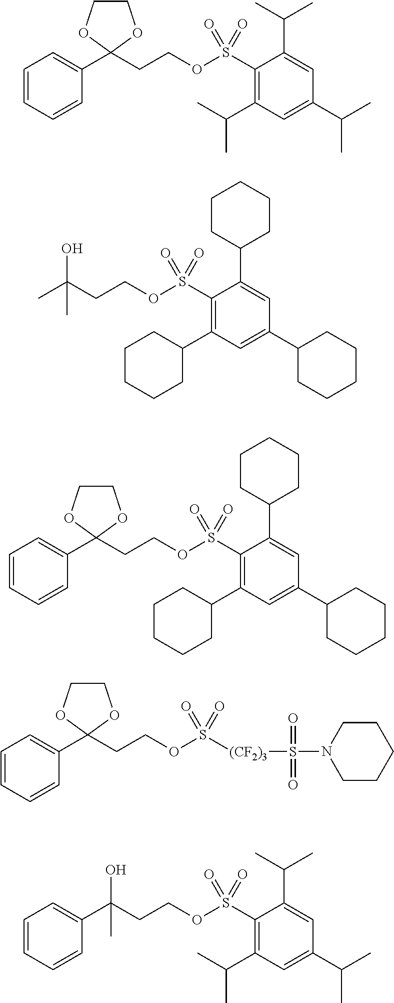

The resist composition can contain a dye, a plasticizer, a photosensitizer, a light absorber, an alkali-soluble resin, a dissolution inhibitor, a compound for accelerating solubility in a developing liquid (for example, a phenol compound having a molecular weight of 1000 or less, or a carboxyl group-containing alicyclic or aliphatic compound), or the like, if desired.

From the viewpoint of resolving power, the resist composition is preferably used in a film thickness of 30 nm to 250 nm, and more preferably from 30 nm to 200 nm.

The solid content concentration of the resist composition is usually from 1.0% by mass to 10% by mass, preferably from 2.0% by mass to 5.7% by mass, and more preferably from 2.0% by mass to 5.3% by mass. By setting the solid content concentration to the range above, the resist solution can be uniformly coated on a substrate.

The solid content concentration refers to a mass percentage of the weight of the other resist components excluding the solvent, with respect to the total weight of the resist composition.

The resist composition is used by dissolving the components in a predetermined organic solvent, and preferably the mixed solvent, filtered through a filter, and then applied onto a predetermined support (substrate). A filter used in the filtration through the filter is preferably a polytetrafluoroethylene-, polyethylene-, or nylon-made filter having a pore size of 0.1 μm or less, more preferably 0.05 μm or less, and still more preferably 0.03 μm or less. In the filtration through a filter, cyclic filtration is carried out as in, for example, JP2002-62667A, or filtration may be carried out by connecting multiple types of filters in series or in parallel. Further, the resist composition may be carried out multiple times. In addition, before and after the filtration through the filter, the resist composition may be subjected to a deaeration treatment or the like.

<Procedure of Step (1)>

A method for applying the resist composition onto a substrate is not particularly limited, and a known method may be used. However, spin coating is preferably used in a field of manufacturing semiconductors.

The substrate on which the resist composition is applied is not particularly limited, and a substrate generally used in a process for manufacturing an inorganic substrate such as silicon, SiO₂, and SiN, an application-based inorganic substrate such as SOG, or a semiconductor such as an IC, or a process for manufacturing a circuit board such as a liquid crystal and a thermal head, and further, a lithography process for photofabrication in addition to these can be used. Further, if desired, an antireflection film may be formed between the resist film and the substrate. As the antireflection film, a known organic or inorganic antireflection film may be used as appropriate.

Furthermore, a drying treatment for removing the solvent may be carried out, if desired, after applying the resist composition on a substrate. A method for the drying treatment is not particularly limited, and examples thereof include a heating treatment and an air drying treatment

[Step (2): Exposing Step]

The step (2) is a step of exposing (irradiating with actinic rays or radiation) the resist film formed in the step (1) as described above. More specifically, it is a step of selectively exposing the resist film so as to form a desired negative-type pattern. With this step, the resist film is patternwise exposed and only the exposed area has a change in the solubility of the resist film.

The light source wavelength used in the exposure is not particularly limited, and examples thereof include infrared rays, visible light, ultraviolet rays, far ultraviolet rays, extreme ultraviolet rays, X-rays, and electron beams. Examples thereof include, far ultraviolet rays at a wavelength of preferably 250 nm or less, more preferably 220 nm or less, and particularly preferably 1 nm to 200 nm, more specifically, a KrF excimer laser (248 nm), an ArF excimer laser (193 nm), an F₂ excimer laser (157 nm), X-rays, EUV (13 nm), and electron beams, among which the KrF excimer laser, the ArF excimer laser, EUV, or the electron beams are preferred, and the ArF excimer laser is more preferred.

Furthermore, in the exposing step of the present invention, a liquid immersion exposure method can be applied. The liquid immersion exposure method can be combined with super-resolution technology such as a phase shift method and a modified illumination method.

In the case of carrying out liquid immersion exposure, a step of washing the surface of the resist film with an aqueous chemical liquid may be carried out (1) after a step of forming a resist film on a substrate and then exposing the resist film, and/or (2) after a step of exposing the resist film through an immersion liquid and before a step of heating the resist film.

The immersion liquid is preferably a liquid which is transparent to exposure wavelength and has a minimum temperature coefficient of a refractive index so as to minimize the distortion of an optical image projected on the resist film. In particular, in the case where the exposure light source is an ArF excimer laser (wavelength: 193 nm), water is preferably used in terms of easy availability and easiness of handling, in addition to the above-described viewpoints.

In the case of using water, an additive (liquid) that decreases the surface tension of water while increasing the interfacial activity may be added at a slight proportion. It is preferable that this additive does not dissolve the resist film on the wafer, and gives a negligible effect on the optical coat at the undersurface of a lens element.

Such an additive is preferably, for example, an aliphatic alcohol having a refractive index substantially equal to that of water, and specific examples thereof include methyl alcohol, ethyl alcohol, and isopropyl alcohol. By adding an alcohol having a refractive index substantially equal to that of water, even when the alcohol component in water is evaporated and its content concentration is changed, an advantage in that the change in the refractive index of the liquid as a whole can be advantageously made very small is obtained.

On the other hand, if materials opaque to light at 193 nm or impurities having a great difference in the refractive index from water are incorporated, the distortion of the optical image projected on the resist film is caused. Therefore, the water to be used is preferably distilled water. Further, pure water after filtration through an ion exchange filter or the like may also be used.

The electrical resistance of water used as the immersion liquid is preferably 18.3 MQcm or more, and Total Organic Concentration (TOC) is preferably 20 ppb or less. The water is preferably one which has been subjected to a deaeration treatment.

In addition, the lithography performance can be enhanced by increasing the refractive index of the immersion liquid. From such a viewpoint, an additive for increasing the refractive index, for example, may be added to water, or heavy water (D₂O) may be used in place of water.

The receding contact angle of the film (resist film) formed using the resist composition is preferably 70° or more at 23±3° C. at a humidity of 45±5%, which is appropriate in the case of the exposure through a-liquid immersion medium. The receding contact angle is more preferably 75° or more, and still more preferably from 75° to 85°.

When the receding contact angle is extremely small, the resist film cannot be appropriately used the case of the exposure through the liquid immersion medium, and the effect of suppressing any residual water (watermark) defect cannot be sufficiently exerted. For the realization of a desirable receding contact angle, it is preferable to incorporate the hydrophobic resin (D) in the resist composition. Alternatively, the receding contact angle may be increased by forming a coating layer (known as a “top coat”) of the hydrophobic resin composition on the resist film.

In the immersion exposing step, the exposure head scans a wafer at a high speed, and follows the movement due to formation of the exposure pattern, and it is necessary for the immersion liquid to move on the wafer. Thus, the contact angle of the immersion liquid with respect to the resist film in the dynamic state becomes important, liquid droplets do not remain, and thus, the resist film is required to have performance that follows the high-speed scan of the exposure head.

<Heating Treatment>

The resist film may be subjected to a heating treatment (PB: Prebake) prior to the present step. The heating treatment (PB) may also be carried out multiple times.

In addition, the resist film after the present step may be subjected to a heating treatment (PEB: Post Exposure Bake). The heating treatment (PEB) may also be carried out multiple times.

By the heating treatment, the reaction in the exposed area is promoted, and thus, the sensitivity or the pattern profile is further improved.

For both PB and PEB, the temperature for the heating treatment is preferably from 70° C. to 130° C., and more preferably from 80° C. to 120° C.

For both PB and PEB, the time for the heating treatment is preferably from 30 seconds to 300 seconds, more preferably from 30 seconds to 180 seconds, and still more preferably from 30 seconds to 90 seconds.

For both PB and PEB, the heating treatment can be carried out using a device installed in an ordinary exposure-and-development machine, or may also be carried out using a hot plate or the like.

[Step (3): Developing Step]

The step (3) is a step of developing the resist film exposed in the step (2) using a developing liquid containing an organic solvent. With this step, a desired negative-type pattern is formed.

The developing liquid containing an organic solvent (hereinafter also referred to as an organic developing liquid) is not particularly limited, and for example, polar solvents such as a ketone-based solvent, an ester-based solvent, an alcohol-based solvent, an amide-based solvent, an ether-based solvent, and hydrocarbon-based solvents can be used.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, and propyl lactate.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, n-decanol, and 4-methyl-2-pentanol (MIBC: methyl isobutyl carbinol); glycol-based solvents such as ethylene glycol, diethylene glycol, and triethylene glycol; and glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether-based solvent include, in addition to the glycol ether-based solvents, dioxane and tetrahydrofuran.

Examples of the amide-based solvent include N-methyl-2-pyrrolidone, N,N-dimethylacetamid, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene, and aliphatic hydrocarbon-based solvents such as pentane, hexane, octane, and decane.

A plurality of these solvents may be mixed, or the solvent may be used by mixing it with a solvent other than ones described above or with water. However, in order to exhibit the effects of the present invention sufficiently, the moisture content ratio of the entire developing liquid is preferably less than 10% by mass, and it is more preferable to contain substantially no moisture content.

That is, the amount of the organic solvent used with respect to the organic developing liquid is preferably from 90% by mass to 100% by mass, and more preferably from 95% by mass to 100% by mass, with respect to the entire amount of the developing liquid.

In particular, the organic developing liquid is preferably a developing liquid containing at least one organic solvent selected from the group consisting of a ketone-based solvent, an ester-based solvent, an alcohol-based solvent, an amide-based solvent, and an ether-based solvent, and more preferably a developing liquid containing an ester-based solvent (particularly butyl acetate).

The vapor pressure at 20° C. of the organic developing liquid is preferably 5 kPa or less, more preferably 3 kPa or less, and particularly preferably 2 kPa or less. By setting the vapor pressure of the organic developing liquid to 5 kPa or less, the evaporation of the developing liquid on a substrate or in a development cup is inhibited, and the temperature uniformity within a wafer plane is improved, whereby the dimensional uniformity within a wafer plane is enhanced.

An appropriate amount of a surfactant may be added to the organic developing liquid, if desired.

The surfactant is not particularly limited, and for example, an ionic or nonionic fluorine- and/or silicon-based surfactant can be used. Examples of such a fluorine- and/or silicon-based surfactant include surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540), JP1995-230165A (JP-H07-230165A), JP1996-62834A (JP-H08-62834A), JP1997-54432A (JP-H09-54432A), JP1997-5988A (JP-H09-5988A), and U.S. Pat. No. 5,405,720, U.S. Pat. No. 5,360,692, U.S. Pat. No. 5,529,881, U.S. Pat. No. 5,296,330, U.S. Pat. No. 5,436,098, U.S. Pat. No. 5,576,143, U.S. Pat. No. 5,294,511, and U.S. Pat. No. 5,824,451, among which the nonionic surfactant is preferred. The nonionic surfactant is not particularly limited, but a fluorine-based surfactant or a silicon-based surfactant is more preferably used.

The amount of the surfactant used is usually from 0.001% by mass to 5% by mass, preferably from 0.005% by mass to 2% by mass, and more preferably from 0.01% by mass to 0.5% by mass, with respect to the entire amount of the developing liquid.

In addition, the developing liquid containing an organic solvent may contain a basic compound. Specific preferred examples of the basic compound which may be contained in the developing liquid used in the present invention are the same as for the aforementioned basic compounds which may be contained in the resist composition, as mentioned above. For these descriptions, reference may be made to JP2013-11833A or the like.

As the developing method, for example, a method in which a substrate is immersed in a tank filled with a developing liquid for a certain period of time (a dip method), a method in which a developing liquid is heaped up to the surface of a substrate by surface tension and developed by resting for a certain period of time (a paddle method), a method in which a developing liquid is sprayed on the surface of a substrate (a spray method), a method in which a developing liquid is continuously discharged on a substrate rotated at a constant rate while scanning a developing liquid discharging nozzle at a constant rate (a dynamic dispense method), or the like, can be applied.

If a variety of developing methods as described above include a step in which a developing liquid is discharged from a development nozzle of a development apparatus toward a resist film, the discharge pressure of the developing liquid discharged (a flow rate per unit area of the developing liquid discharged) is preferably 2 mL/sec/mm² or less, more preferably 1.5 mL/sec/mm² or less, and still more preferably 1 mL/sec/mm² or less. The lower limit of the flow rate is not particularly limited, but is preferably 0.2 mL/sec/mm² or more, taking consideration of throughput.

By setting the discharge pressure of the developing liquid to the above range, the defects of a pattern derived from a resist residue after the development can be remarkably reduced.

Details of this mechanism are not clearly known, but it is considered that by setting the discharge pressure to the above range, the pressure imposed on the resist film by the developing liquid becomes small and the resist film or the resist pattern is inhibited from inadvertent chipping or collapse.

Incidentally, the discharge pressure (mL/sec/mm²) of the developing liquid is a value at the outlet of a development nozzle in a developing device.

Examples of the method for adjusting the discharge pressure of the developing liquid include a method for adjusting the discharge pressure using a pump and the like, and a method for adjusting the pressure by supplying the pressure from the pressure tank.

In addition, after the step of carrying out development using a developing liquid containing an organic solvent, a step of stopping the development while replacing the solvent with another solvent may be carried out.

[Arbitrary Step: Rinsing Step]

It is preferable to wash the negative-type pattern formed by the developing step using a rinsing liquid or the like at a time between the developing step as described above and the peeling step as described later.

The rinsing liquid used in the rinsing step is not particularly limited as long as it does not dissolve the pattern, and a solution containing common organic solvents can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent are the same as those for the developing liquid containing an organic solvent as described above.

A rinsing liquid containing an alcohol-based solvent or an ester-based solvent is preferred; a rinsing liquid containing a monohydric alcohol is more preferred; and a rinsing liquid containing a monohydric alcohol having 5 or more carbon atoms is still more preferred.

Here, examples of the monohydric alcohol used in the rinsing step include linear, branched, or cyclic monohydric alcohols, and specifically, 1-butanol, 2-butanol, 3-methyl-1-butanol, tert-butyl alcohol, 1-pentanol, 2-pentanol, 1-hexanol, 4-methyl-2-pentanol (MIBC: methyl isobutyl carbinol), 1-heptanol, 1-octanol, 2-hexanol, cyclopentanol, 2-heptanol, 2-octanol, 3-hexanol, 3-heptanol, 3-octanol, 4-octanol, or the like can be used. As the particularly preferred monohydric alcohol having 5 or more carbon atoms, 1-hexanol, 2-hexanol, 4-methyl-2-pentanol, 1-pentanol, 3-methyl-1-butanol, or the like can be used.

Suitable embodiments of a combination of the organic solvent contained in the developing liquid and the rinsing liquids used in the rinsing step include ester-based solvents (particularly, butyl acetate).

The respective components may be mixed, or the solvent may be used by mixing it with an organic solvent other than those described above.

The moisture content percentage in the rinsing liquid is preferably 10% by mass or less, more preferably 5% by mass or less, and still more preferably 3% by mass or less. By setting the moisture content percentage to 10% by mass or less, good development characteristics can be obtained.

The vapor pressure of the rinsing liquid is preferably from 0.05 kPa to 5 kPa, more preferably from 0.1 kPa to 5 kPa, and most preferably from 0.12 kPa to 3 kPa at 20° C. By setting the vapor pressure of the rinsing liquid from 0.05 kPa to 5 kPa, the temperature uniformity within a wafer plane is improved, whereby the dimensional uniformity within a wafer plane is enhanced by inhibition of swelling due to the penetration of the rinsing liquid.

An appropriate amount of a surfactant can also be added to the rinsing liquid, and used.

A method for carrying out rinsing with the rinsing liquid is not particularly limited, and for example, a method in which a rinsing liquid is continuously discharged on a substrate rotated at a constant rate (a rotation application method), a method in which a substrate is immersed in a bath filled with a rinsing liquid for a certain period of time (a dip method), a method in which a rinsing liquid is sprayed on a substrate surface (a spray method), or the like, can be applied. Among these, a method in which a washing treatment is carried out using the rotation application method, a substrate is rotated at a rotational speed of 2,000 rpm to 4,000 rpm after washing, thereby removing the rinsing liquid from the substrate, is preferred.

[Arbitrary Step: Heating Step]

It is preferable to include a heating step of heating the negative-type pattern formed by the developing step at a time between the developing step as described above and the peeling step as described later. Further, in the case of including the above-described rinsing step, it is preferable to include the heating step at a time between the rinsing step and the peeling step as described later.

The developing liquid and the rinsing liquid remaining between the patterns and in the inside of the pattern are removed by the heating step and the durability of the pattern is improved.

The heating step can be carried out in accordance with a known method.

The heating temperature is not particularly limited, but is preferably from 100° C. to 160° C. The heating time is not particularly limited, but is preferably from 10 seconds to 3 minutes, and preferably from 30 seconds to 90 seconds.

[Arbitrary Step: Etching Step]

An etching step is usually provided between the developing step as described above and the peeling step as described later. More specifically, the negative-type pattern (resist pattern) formed in the step (3) is used as a mask, and the non-mask area is etched. A subject to be etched is not particularly limited, and varies depending on the type of the substrate.

Examples of the etching step include a dry etching step and a wet etching step, and it is preferably to include a dry etching step. The dry etching step is not particularly limited, and may be carried out using a known method. With respect to the dry etching step, reference may be made to, for example, Chapter 4 of Semiconductor Process Textbook (4^{th} Edition, 2^{nd} Impression) (SEMI FORUM JAPAN Program Committee, reviewed by Demizu, Kiyoshi, published on Dec. 5, 2007).

[Step (4): Peeling Step]

The step (4) is a step of peeling the formed negative-type pattern as described above using the following liquid (A) or (B) (peeling solution) (hereinafter, the following liquid (A) and the following liquid (B) are also referred to as a “peeling solution (A)” and a “peeling solution (B)”, respectively):

(A) a liquid containing a sulfoxide compound and/or an amide compound; and

(B) a liquid containing sulfuric acid and hydrogen peroxide.

First, the peeling solution used in the present step will be described in detail, and then, the procedures of the step will be described in detail.

<Peeling Solution (A): Liquid Containing Sulfoxide Compound and/or Amide Compound>

(Sulfoxide Compound)

The sulfoxide compound contained in the peeling solution (A) is not particularly limited as long as it is a compound having an “—S(═O)—” group. Among these, in view of superior peelability, a compound represented by the following General Formula (I-1) is preferred.

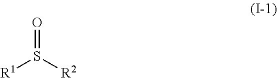

In General Formula (I-1), R¹ and R² each represent a hydrogen atom or an alkyl group. As the alkyl group, an alkyl group having 1 to 8 carbon atoms is preferred, and an alkyl group having 1 to 4 carbon atoms is more preferred. The alkyl group may be chained (branched or linear) or cyclic, but is preferably chained. The alkyl group may have a substituent, and examples of the substituent include a methyl group, an ethyl group, a propyl group, a butyl group, and a tert-butyl group. R¹ and R² may be bonded to each other to form a ring.

Examples of the sulfoxide compound include dimethylsulfoxide, methylethylsulfoxide, diethylsulfoxide, methylpropylsulfoxide, and dipropylsulfoxide.

(Amide Compound)

The amide compound contained in the peeling solution (A) is not particularly limited as long as it is a compound having an “>N—C(═O)—” group. Among these, for a reason of superior peelability, a compound represented by the following General Formula (I-2) is preferred.

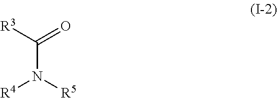

In General Formula (I-2), the definitions, the specific examples, and the suitable examples of R³ to R⁵ are the same as for R′ and R² in General Formula (I-1) as described above. Further, two members out of R³ to R⁵ may be bonded to each other to form a ring.

Examples of the amide compound include N,N-dimethylformamide, N-methylformamide, N,N-dimethylacetamide, N-methylacetamide, N,N-diethylacetamide, and N-methylpyrrolidone.

The “—S(═O)—” group and the “>N—C(═O)—” group are neutral polar groups which have affinity for organic materials as well as low substrate corrosiveness, and therefore, it is considered that the peeling using the peeling solution (A) causes excellent peelability and reduced damage to a substrate. Incidentally, it is considered that since the electron density of nitrogen atoms is decreased by electron absorption of a carbonyl group, and thus, the basicity of the nitrogen atom is decreased, the “>N—C(═O)—” group is a neutral polar group having low substrate corrosiveness.

(Other Components)

The peeling solution (A) may contain other components such as an amine compound and an organic solvent other than the sulfoxide compound and the amide compound above, within a range not interfering with the effect of the present invention.

The amine compound is not particularly limited, and examples thereof include hydroxylamine, ethylamine, diethylamine, triethylamine, ethylenediamine, monoethanolamine, diethanolamine, triethanolamine, propanolamine, dipropanolamine, tripropanolamine, isopropanolamine, diisopropanolamine, triisopropanolamine, butanolamine, N-methyl ethanolamine, N-methyldiethanolamine, N,N-dimethylaminoethanol, N-ethylethanolamine, N-ethyldiethanolamine, N,N-diethylethanolamine, N-n-butylethanolamine, di-n-butylethanolamine, tetramethylammonium hydroxide, tetraethylammonium hydroxide, tetrapropylammonium hydroxide, tetrabutylammonium hydroxide, and salts thereof.

As the amine compound, organic amine compounds are preferred, and diethylamine, ethylaminoethanol, butyl aminoethanol, and tetramethylammonium hydroxide are particularly preferably exemplified.

The organic solvent other than sulfoxide compound and the amide compound is not particularly limited, and examples thereof include alcohols such as methanol, ethanol, and butanol; lactams such as N-methyl-2-pyrrolidone, N-ethyl-2-pyrrolidone, and N-propyl-2-pyrrolidone; imidazolidinones such as 1,3-dimethyl-2-imidazolidinone, 1,3-diethyl-2-imidazolidinone, and 1,3-diisopropyl-2-imidazolidinone; and alkylene glycols. Examples of the alkylene glycols include glycol compounds such as ethylene glycol, propylene glycol, hexylene glycol, and neopentyl glycol, and monoether or diether compounds thereof, and salts thereof. Other examples include compounds having 2 to 4 alkylene glycols, such as dialkylene glycol, trialkylene glycol, and tetraalkylene glycol, and monoether or diether compounds thereof, and salts thereof. In the present invention, a preferred alkylene group is an ethylene group. That is, in the present invention, ethylene glycols are preferably used as the alkylene glycols. Specific examples thereof include ethylene glycol, ethylene glycol monomethyl ether, ethylene glycol monoethyl ether, ethylene glycol monopropyl ether, ethylene glycol monobutyl ether, ethylene glycol dimethyl ether, ethylene glycol diethyl ether, ethylene glycol monomethyl ether acetate, ethylene glycol monoethyl ether acetate, ethylene glycol diacetate, and compounds having 2 to 4 ethylene glycols thereof (diethylene glycols, triethylene glycols, and tetraethylene glycols), and preferably diethylene glycol dimethyl ether, diethylene glycol diethyl ether, triethylene glycol dimethyl ether, diethylene glycol monobutyl ether, triethylene glycol dimethyl ether, triethylene glycol monobutyl ether, diethylene glycol diacetate, and triethylene glycol diacetate.

The total content of the sulfoxide compound and the amide compound in the peeling solution (A) is not particularly limited, but is preferably 50% by mass or more, and more preferably from 70% by mass to 100% by mass.

Furthermore, in the case where the peeling solution (A) contains both of the sulfoxide compound and the amide compound, the mass ratio of the sulfoxide compound and the amide compound in the peeling solution (A) is not particularly limited, but is preferably from 5/95 to 95/5, and more preferably from 80/20 to 20/80.

In the case where the peeling solution (A) contains the amine compound as described above, the content thereof is preferably 20% by mass or less, more preferably 10% by mass or less, and particularly preferably 8% by mass or less.

In the case where the peeling solution (A) contains an organic solvent other than the sulfoxide compound and the amide compound as described above, the content thereof is preferably less than 50% by mass, more preferably 40% by mass or less, and particularly preferably 30% by mass or less.

<Peeling Solution (B): Liquid Containing Sulfuric Acid and Hydrogen Peroxide>

The peeling solution (B) is not particularly limited as long as it is a liquid containing sulfuric acid and hydrogen peroxide, but is preferably an aqueous solution containing sulfuric acid and hydrogen peroxide. The peeling solution (B) may contain other components within a range not interfering with the effect of the present invention. Examples of other such components include other components which may be contained in the peeling solution (A), as described above, and inorganic acids such as hydrochloric acid and nitric acid.

The content of the sulfuric acid in the peeling solution (B) is not particularly limited, but is preferably from 30% by volume to 70% by volume, and more preferably from 40% by volume to 60% by volume, when converted into the amount of concentrated sulfuric acid (96%-by-mass aqueous sulfuric acid solution).

The content of the hydrogen peroxide in the peeling solution (B) is not particularly limited, but is preferably from 30% by mass to 70% by mass, and more preferably from 40% by mass to 60% by mass, when converted into the amount of 30%-by-mass aqueous hydrogen peroxide.

The total content of sulfuric acid, hydrogen peroxide, and water in the peeling solution (B) is not particularly limited, but is preferably 80% by mass or more, and more preferably 90% by mass or more.

The ratio of sulfuric acid to hydrogen peroxide in the peeling solution (B) is not particularly limited, but the mixing ratio (volume ratio) of concentrated sulfuric acid is preferably from 30/70 to 70/30, and more preferably from 40/60 to 60/40, in terms of a 96%-by-mass aqueous sulfuric acid solution/30%-by-mass aqueous hydrogen peroxide (volume ratio).

<Procedure of Step (4)>

A method for peeling a negative-type pattern using the peeling solution (A) or (B) is not particularly limited, but may be carried out in a single wafer mode or a batch mode. The single wafer mode is a type of treating wafers one at a time. One embodiment of the single wafer mode is a treatment method involving spreading a peeling solution widely across the surface of a wafer with a spin coater.

Suitable values of the liquid temperature, the discharge amount of the peeling solution, the rotational speed of wafer in a spin coater of the peeling solution are selected, depending on the selection of a substrate to be targeted, and used.

The conditions for carrying out the peeling step are not particularly limited, but the peeling step in a single wafer mode is preferred. In the peeling step in the single wafer mode, a semiconductor substrate is transported or rotated in a predetermined direction, and the peeling solution is discharged into the space so as to bring the peeling solution into contact with the semiconductor substrate. If desired, the peeling solution may be sprayed while rotating the semiconductor substrate using a spin coater. On the other hand, in the peeling in the batch mode, a semiconductor substrate is immersed in a liquid bath including a peeling solution to bring the semiconductor substrate into contact with the peeling solution in the liquid bath. Any of these peeling modes can be used as long as they can appropriately distinguish the structures or materials of the element.

The temperature for carrying out the peeling is not particularly limited, but is preferably 100° C. or lower, and more preferably 80° C. or lower. The lower limits of the temperature for carrying out the peeling with respect to the peeling solutions (A) and (B) are not particularly limited as long as the peeling solutions are present as a liquid even at a low temperature, but it is preferable to carry out the peeling at a temperature of 15° C. or higher in terms of throughput at a time of production. In the case of the treatment in a single wafer mode, the supply rate of the peeling solution is not particularly limited and varies depending on the size of a substrate, but is preferably set to 0.3 L/min to 3 L/min, and more preferably set to 0.5 L/min to 2 L/min. It is preferable to set the supply rate to the lower limit or more since the uniformity within a plane can be ensured. It is also preferable to set the supply rate to the upper limit or less since stable performance at a time of continuous treatment can be ensured. When the substrate is spun, it is preferable to rotate the substrate at 100 rpm to 1000 rpm from the same viewpoint as described above, even though the rate may depend on the size or the like of the substrate.

Incidentally, the “temperature” as mentioned herein is a temperature of the surface of a substrate to be treated in the case of a treatment in a single wafer mode, or a liquid temperature of a peeling solution in a batch in the case of a treatment in a batch mode.

(Chemical Liquid Supply System and Temperature Regulation)

In the present invention, the temperature-regulated chemical liquid supply line system is not particularly limited, and preferable examples thereof are described below. The “temperature regulation” as mentioned herein refers to maintaining the chemical liquid (peeling solution) at a predetermined temperature. Typically, the chemical liquid is maintained at a predetermined temperature by heating.

Examples of Chemical Supply Line

(1) (a) Chemical liquid storage tank→(b) Temperature-regulating tank→(c) In-line temperature regulation→(d) Discharge to wafer→Return to (a) or (b),

(2) (a) Chemical liquid tank→(b) Temperature-regulating tank→(d) Discharge to wafer→Return to (a) or (b),

(3) (a) Chemical liquid tank→(c) In-line temperature regulation→(d) Discharge to wafer→Return to (a),

(4) (a) Chemical liquid tank→(b) Temperature-regulating tank→(e) Bath (Circulation temperature regulation),

(5) (a) Chemical liquid tank→(e) Bath (Circulation temperature regulation),

(6) (b) Temperature-regulating tank→(d) Discharge to wafer→Return to (b),

(7) (b) Temperature-regulating tank→(c) In-line temperature regulation→(d) Discharge to wafer→Return to (b),

(8) (b) Temperature-regulating tank→(e) Batch (Circulation temperature regulation), or

other use methods are available.

The chemical liquid which has been used in the pattern peeling method of the present invention can be re-used by circulation. A preferable method is not free-flowing (without re-use), but re-use by circulation. It is possible to continue circulation for 1 hour or more after heating, which makes it possible to perform repetitive treatments. The upper time limit of the circulating-reheating is not particularly limited, but an exchange within a week is preferred since the peeling performance is deteriorated with age. The exchange within 3 days is more preferred, and an exchange to a fresh liquid once a day is particularly preferred. Incidentally, in the peeling step of the line system, the measurement position of the temperature-regulated temperature may be determined appropriately by the relation to a line configuration or a wafer, but typically, the measurement position may be managed with the tank temperature. In the case where relatively more strict conditions in terms of performance are required, for example, if the measurement and the regulation are feasible, the temperature-regulated temperature may be defined by a wafer surface temperature. In this case, temperature measurement can be conducted using a radiation thermometer.

As the areas of silicon wafers have recently been increased, there has been a stronger demand for reduction for the occurrence of damage such as scratches on substrate surface. Since the pattern peeling method of the present invention only causes small damage to a substrate as described above, it can also be effectively used for a large-area substrate.

The present invention also relates to a method for manufacturing an electronic device, including the pattern peeling method of the present invention as described above, and an electronic device manufactured by the manufacture method.

The electronic device of the present invention is suitably mounted on electric electronic equipment (home electronics, OA/media-related equipment, optical equipment, telecommunication equipment, and the like).

Incidentally, the negative-type pattern formed by the developing step as described above is suitably used as an etching mask in a semiconductor device, or the like, but may also be used in other applications. Examples of other such applications include applications for guide pattern formation in DSA (Directed Self-Assembly) (see, for example, ACS Nano, Vol. 4, No. 8, pp. 4815-4823), that is, use as a so-called core material (core) in a spacer process (see, for example, JP1991-270227A (JP-H03-270227A) and JP2013-164509A).

### EXAMPLES

Examples are shown below, but the present invention is not limited thereto.

### Example A

### Synthesis of Resin (A-1)

A resin (A-1) having the following structure was obtained by carrying out polymerization by a known radical polymerization method, followed by purification. Here, the a/b/c/d/e was 35/10/40/10/5 (molar ratio). The weight-average molecular weight and the dispersity (Mw/Mn) of the resin (A-1) were 15,000 and 1.5, respectively.

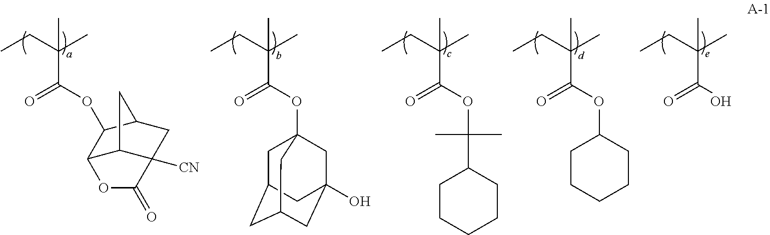

### Synthesis of Hydrophobic Resin (B-1)

A hydrophobic resin (B-1) having the following structure was obtained by carrying out polymerization by a known radical polymerization method, followed by purification. Here, the a/b/c/d/e was 39/57/2/2 (molar ratio). The weight-average molecular weight and the dispersity (Mw/Mn) of the hydrophobic resin (B-1) were 4,000 and 1.3, respectively.

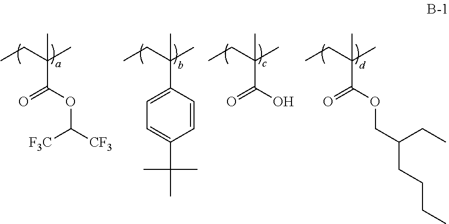

### Preparation of Resist Composition A

10 g of the resin (A-1), 0.8 g of the following acid generator (PAG-1), 0.06 g of the following basic compound (N-1), 0.09 g of the basic compound (N-2) used in combination therewith, 0.04 g of the following surfactant (W-1), and 0.06 g of the hydrophobic resin (B-1) were dissolved in a solvent (α-butyrolactone/propylene glycol monomethyl ether=70/30 (w/w)), and filtered through a polyethylene filter having a pore size of 0.03 μm to prepare a solution having a solid content concentration of 4% by mass. The prepared solution is defined as a resist composition A.

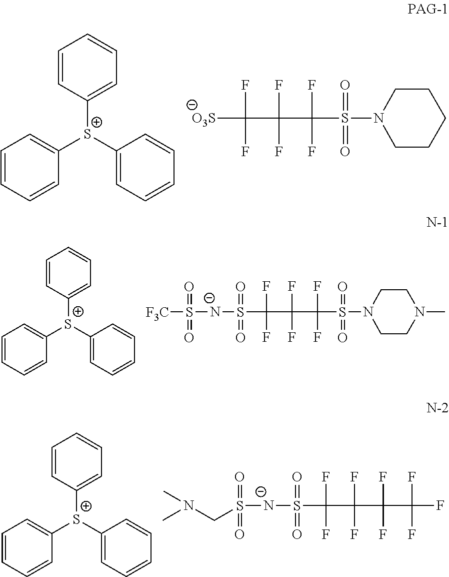

W-1: Megaface R₀₈ (manufactured by DIC Corporation) (fluorine- and silicon-based)

### Example 1

The resist composition A was applied onto a silicon wafer (12-inch aperture), and baked at 100° C. for 60 seconds to form a resist film having a film thickness of 85 nm. The obtained wafer was exposed using an ArF excimer laser liquid immersion scanner (manufactured by ASML, XT1700i, NA1.20, C-Quad, outer sigma 0.750, inner sigma 0.650, XY deflection) through a 6% half-tone mask having a 1:1 line-and-space pattern with a line width of 50 nm. Ultrapure water was used as the immersion liquid. Thereafter, the film was heated at 120° C. for 60 seconds, then developed by paddling with butyl acetate for 30 seconds, and spin-dried by rotating the wafer at a rotational speed of 4000 rpm for 30 seconds to obtain a negative-type pattern with 1:1 line-and-space having a line width of 50 nm.

The formed negative-type pattern was subjected to a dry etching treatment with a reactive gas. Thereafter, the negative-type pattern was peeled by means of a batch mode treatment device (immersed at 70° C. for 30 minutes), using dimethylsulfoxide as a peeling solution.

(Peelability)

The surface of the wafer after peeling the pattern was observed with an optical microscope, and the peelability was evaluated in accordance with the following criteria. The results are shown in Table 4. In terms of excellent peelability, A or B is preferred, and A is more preferred.
A: No resist residue is found.
B: Resist residues are substantially not found (some resist residues are found).
C: Many resist residues are found.

(Damage to Substrate)

The surface of the wafer after peeling the pattern was observed with an optical microscope, and the peelability was evaluated in accordance with the following criteria. The results are shown in Table 4. In terms of causing less damage to a substrate, A or B is preferred, and A is more preferred.
A: No scratch on the surface of a wafer is found.
B: Scratches on the surface of a wafer are substantially not found on the surface of a wafer (some scratches are found).
C: Many scratches are found on the surface of a wafer.

### Example 2

A negative-type pattern was formed by the same procedure as in Example 1 except that N-methylpyrrolidone was used instead of dimethylsulfoxide as a peeling solution, and then subjected to a dry etching treatment, and the negative-type pattern was then peeled. Further, various evaluations were carried out by the same procedure as in Example 1. The results are shown in Table 4.

### Example 3

A negative-type pattern was formed by the same procedure as in Example 1 except that a chemical liquid obtained by mixing concentrated sulfuric acid (96%-by mass aqueous sulfuric acid solution) and 30%-by-mass aqueous hydrogen peroxide at a volume ratio of 1:1 was used, and then subjected to a dry etching treatment, and the negative-type pattern was then peeled instead of dimethylsulfoxide as a peeling solution. Further, various evaluations were carried out by the same procedure as in Example 1. The results are shown in Table 4.

### Comparative Example 1

A negative-type pattern was formed by the same procedure as in Example 1 except that a 25%-by-mass aqueous tetramethylammonium hydroxide solution was used instead of dimethylsulfoxide as a peeling solution, and then subjected to a dry etching treatment, and the negative-type pattern was then peeled. Further, various evaluations were carried out by the same procedure as in Example 1. The results are shown in Table 4.

TABLE 4

| | Peeling | | Damage to |
|---|---|---|---|
| | solution | Peelability | a substrate |
| Example 1 | R-1 | B | A |
| Example 2 | R-2 | B | B |
| Example 3 | R-3 | A | A |
| Comparative | X-1 | B | C |
| Example 1 | | | |

In Table 4, R-1, R-2, R-3, and X-1, described as the peeling solutions, are each as follows.
R-1: Dimethylsulfoxide
R-2: N-Methylpyrrolidone
R-3: Chemical liquid formed by mixing concentrated sulfuric acid (96%-by-mass aqueous sulfuric acid solution) and 30% by mass of aqueous hydrogen peroxide at a volume ratio of 1:1
X-1: 25%-by-mass aqueous tetramethylammonium hydroxide solution

### Example B

### Preparation of Resist Composition

The components shown in Table 5 below were dissolved in the solvents shown in the same table to prepare resist compositions (a solid content concentration of 4% by mass). Incidentally, the ratio of the solvent in Table 5 below is intended to mean a mass ratio. Further, the case where both of the section “Type 1” and the section “Type 2” in each of the sections of the “acid generator” and the “basic compound” in table 5 contain results is ended to mean use of two types.

TABLE 5

| Resist | Resin | | Acid generator | | | | Basic compound | | | | Resin | | | |
|---|---|---|---|---|---|---|---|---|---|---|---|---|---|---|
| compo- | | Mass/ | Type | Mass/g | Type | Mass/g | Type | Mass/g | Type | Mass/g | | Mass/ | Solvent | |
| sition | Type | g | 1 | of type 1 | 2 | of type 2 | 1 | of type 1 | 2 | of type 2 | Type | g | Type | Ratio |
| Ar-01 | P-1 | 10 | PAG-1 | 0.5 | | | Q-1 | 0.1 | | | N-1 | 0.05 | SL-1/SL-2 | 70/30 |
| Ar-02 | P-2 | 10 | PAG-2 | 1.2 | | | Q-2 | 0.3 | | | N-2 | 0.05 | SL-1/SL-2 | 70/30 |
| Ar-03 | P-3 | 10 | PAG-3 | 0.35 | PAG-2 | 0.35 | Q-3 | 0.12 | | | N-3 | 0.05 | SL-1/SL-2 | 70/30 |
| Ar-04 | P-4 | 10 | PAG-4 | 1 | | | Q-4 | 0.05 | | | N-1 | 0.05 | SL-1/SL-2/SL-3 | 70/28/2 |
| Ar-05 | P-5 | 10 | PAG-5 | 0.7 | | | Q-5 | 0.1 | | | N-1 | 0.05 | SL-1/SL-2/SL-4 | 70/27/3 |
| Ar-06 | P-6 | 10 | PAG-6 | 2 | | | Q-1 | 0.2 | | | N-1 | 0.05 | SL-1/SL-3 | 90/10 |
| Ar-07 | P-1/P-7 | 5/5 | PAG-7 | 0.7 | | | Q-2 | 0.05 | Q-3 | 0.2 | N-1 | 0.05 | SL-1/SL-3 | 90/10 |
| Ar-08 | P-8 | 10 | PAG-1 | 0.5 | PAG-6 | 1.2 | Q-3 | 0.05 | Q-4 | 0.2 | N-1 | 0.05 | SL-1/SL-3 | 70/30 |

Various components used in Table 5 are summarized below.

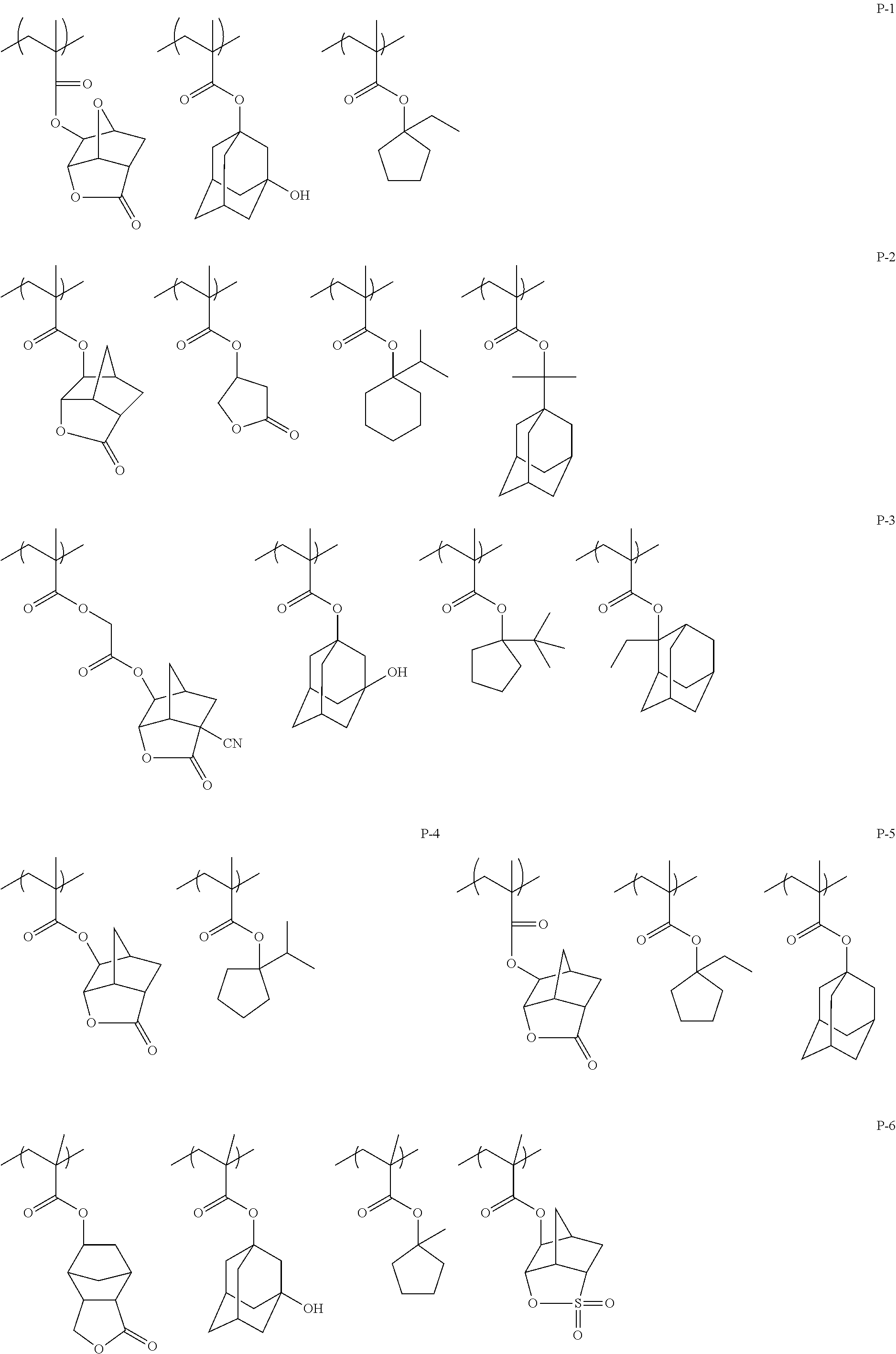

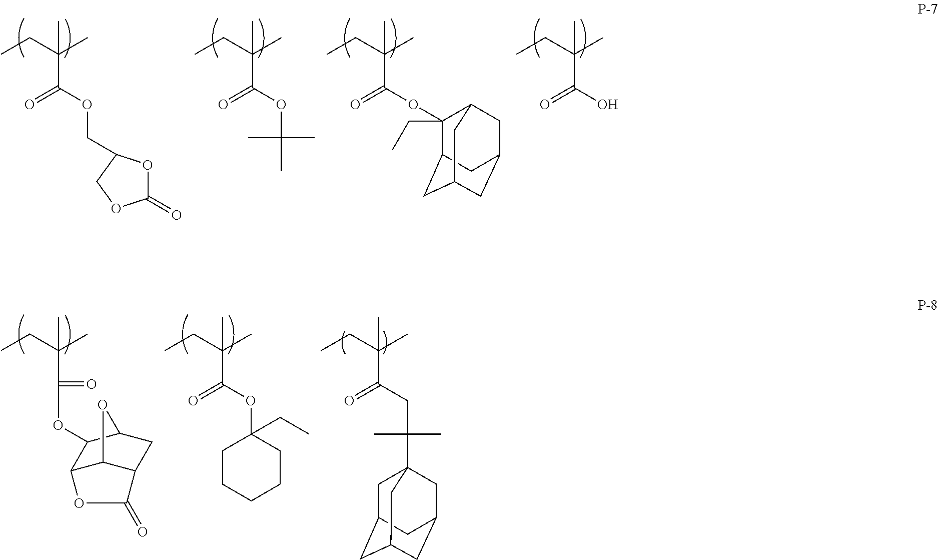

TABLE 6

| | Compositional | | Pd |
|---|---|---|---|
| Resin | ratio | Mw | (Mw/Mn) |
| P-1 | 30/10/60 | 12000 | 1.6 |
| P-2 | 20/20/80/10 | 8000 | 1.5 |
| P-3 | 35/20/35/10 | 8000 | 1.7 |
| P-4 | 40/60 | 15000 | 2.0 |
| P-5 | 45/50/5 | 12000 | 2.1 |
| P-6 | 20/10/50/20 | 7000 | 1.5 |
| P-7 | 60/30/5/5 | 12000 | 1.8 |
| P-8 | 40/40/20 | 22000 | 2.2 |

In Table 6, the compositional ratios represent the molar ratios of the repeating units included in the resins P-1 to P-8 as described above, and denote the compositional ratios of the repeating units in order starting from the left side in the formulae shown above.

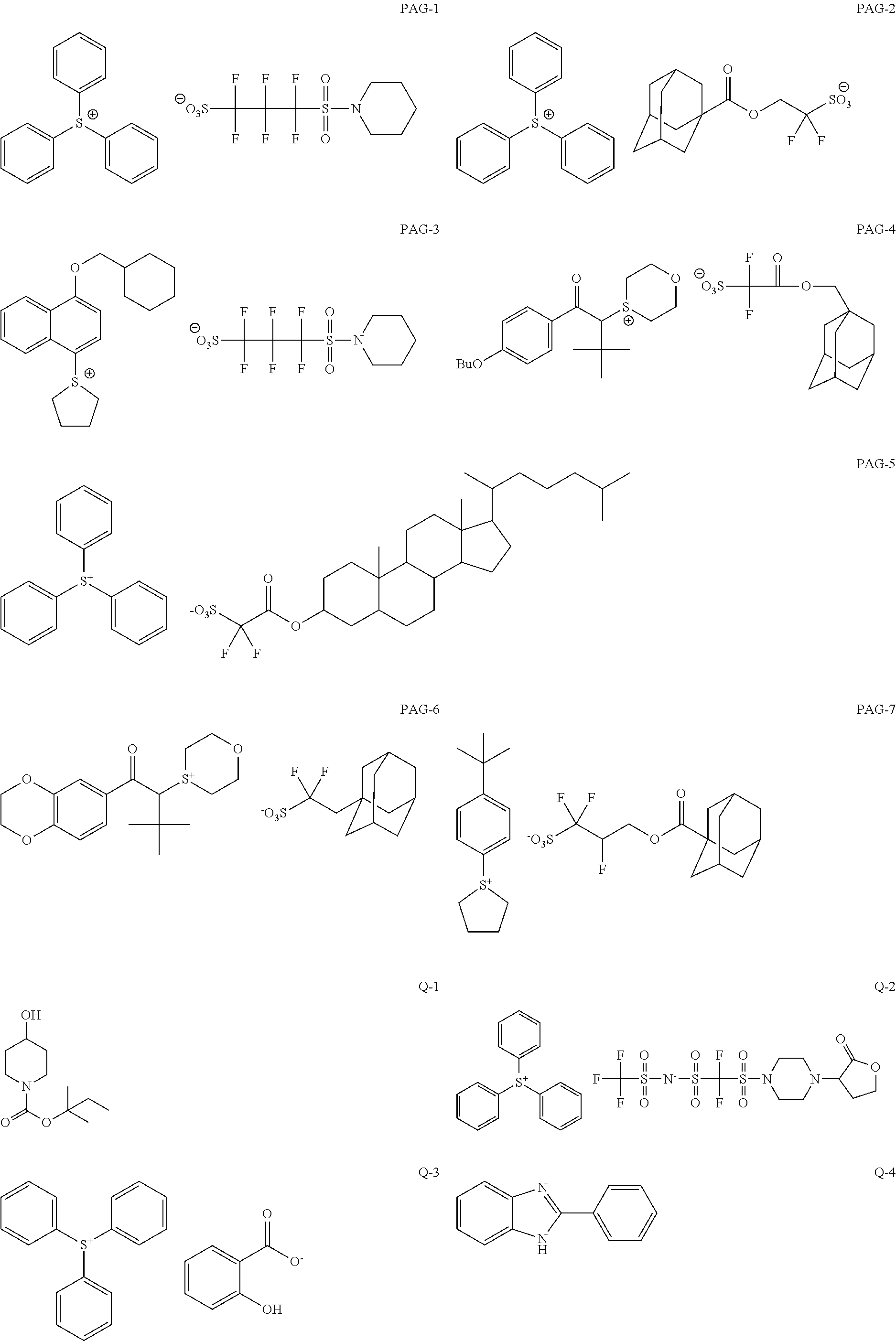

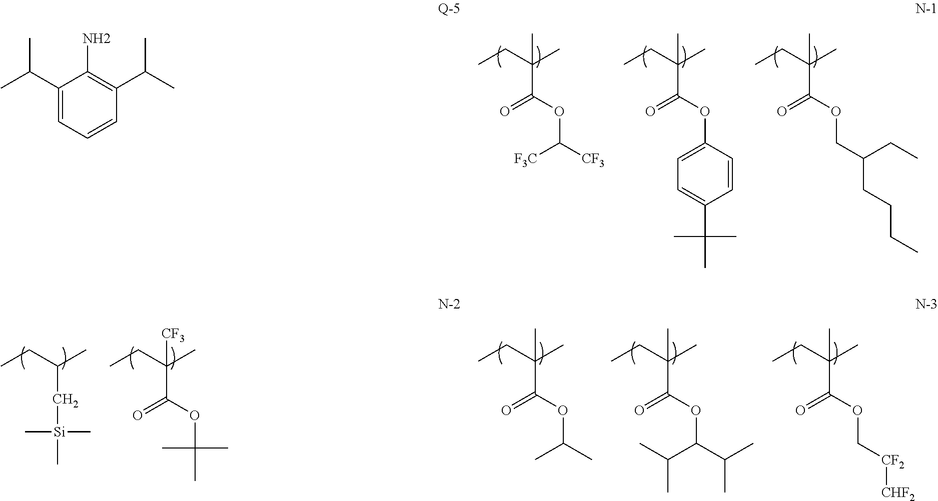

TABLE 7

| | Compositional | | Pd |
|---|---|---|---|
| Resin | ratio | Mw | (Mw/Mn) |
| N-1 | 40/20/40 | 4000 | 1.6 |
| N-2 | 50/50 | 6000 | 1.5 |
| N-3 | 30/65/5 | 15000 | 2 |

In Table 7, the compositional ratios represent the molar ratios of the repeating units included in the resins N-1 to N-3 as described above, and denote the compositional ratios of the repeating units in order starting from the left side in the formulae shown above.

As the solvent, the following ones were used.

SL-1: Propylene glycol monomethyl ether acetate (PGMEA)

SL-2: Propylene glycol monomethyl ether (PGME)

SL-3: Cyclohexanone

SL-4: γ-Butyrolactone

### Examples 1-1 to 1-3, Comparative Example 1-1, Examples 2-1 to 2-3, Comparative Example 2-1, Examples 3-1 to 3-3, Comparative Example 3-1, Examples 4-1 to 4-3, Comparative Example 4-1, Examples 5-1 to 5-3, Comparative Example 5-1, Examples 6-1 to 6-3, Comparative Example 6-1, Examples 7-1 to 7-3, Comparative Example 7-1, Examples 8-1 to 8-3, and Comparative Example 8-1

A negative-type pattern was formed by the same procedure as in Example 1 except that the composition shown in Table 8 below was used instead of the resist composition A and the peeling solution shown in Table 8 below was used as the peeling solution, and then subjected to a dry etching treatment, and the negative-type pattern was then peeled. Further, various evaluations were carried out by the same procedure as in Example 1. The results are shown in Table 8.

The resist compositions (Ar-01 to Ar-08) in Table 8 represent the resist compositions (Ar-01 to Ar-08) in Table 5, respectively. Further, the peeling solutions (R-1 to R-3, and X-1) in Table 8 represent the peeling solutions (R-1 to R-3, X-1) in Table 4, respectively.

TABLE 8

| | Resist | Peeling | | Damage to |
|---|---|---|---|---|
| | composition | solution | Peelability | substrate |
| Example 1-1 | Ar-01 | R-1 | B | A |
| Example 1-2 | Ar-01 | R-2 | B | B |
| Example 1-3 | Ar-01 | R-3 | A | A |
| Comparative | Ar-01 | X-1 | B | C |
| Example 1-1 | | | | |
| Example 2-1 | Ar-02 | R-1 | B | A |
| Example 2-2 | Ar-02 | R-2 | B | B |
| Example 2-3 | Ar-02 | R-3 | A | A |
| Comparative | Ar-02 | X-1 | B | C |
| Example 2-1 | | | | |
| Example 3-1 | Ar-03 | R-1 | B | A |
| Example 3-2 | Ar-03 | R-2 | B | B |
| Example 3-3 | Ar-03 | R-3 | A | A |
| Comparative | Ar-03 | X-1 | C | C |
| Example 3-1 | | | | |
| Example 4-1 | Ar-04 | R-1 | B | A |
| Example 4-2 | Ar-04 | R-2 | B | B |
| Example 4-3 | Ar-04 | R-3 | A | A |
| Comparative | Ar-04 | X-1 | C | C |
| Example 4-1 | | | | |
| Example 5-1 | Ar-05 | R-1 | B | A |
| Example 5-2 | Ar-05 | R-2 | B | B |
| Example 5-3 | Ar-05 | R-3 | A | A |
| Comparative | Ar-05 | X-1 | C | C |
| Example 5-1 | | | | |
| Example 6-1 | Ar-06 | R-1 | B | A |
| Example 6-2 | Ar-06 | R-2 | B | B |
| Example 6-3 | Ar-06 | R-3 | A | A |
| Comparative | Ar-06 | X-1 | B | C |
| Example 6-1 | | | | |
| Example 7-1 | Ar-07 | R-1 | B | A |
| Example 7-2 | Ar-07 | R-2 | B | B |
| Example 7-3 | Ar-07 | R-3 | A | A |
| Comparative | Ar-07 | X-1 | B | C |
| Example 7-1 | | | | |
| Example 8-1 | Ar-08 | R-1 | B | A |
| Example 8-2 | Ar-08 | R-2 | B | B |
| Example 8-3 | Ar-08 | R-3 | A | A |
| Comparative | Ar-08 | X-1 | C | C |
| Example 8-1 | | | | |

As seen from Tables 4 and 8, with the methods of Examples in the present application, using specific peeling solutions, the peelability was excellent and the damage to a substrate was small.

On the other hand, with the methods of Comparative Examples 1, 1-1, 2-1, 3-1, 4-1, 5-1, 6-1, 7-1 and 8-1, using peeling solutions other than specific peeling solutions, damage to a substrate was found.

Incidentally, the pattern formation, the dry etching treatment, and the pattern peeling were carried out and evaluated in the same manner as in Examples 1 to 3 and Comparative Example 1, Examples 1-1 to 1-3, Comparative Example 1-1, Examples 2-1 to 2-3, Comparative Example 2-1, Examples 3-1 to 3-3, Comparative Example 3-1, Examples 4-1 to 4-3, Comparative Example 4-1, Examples 5-1 to 5-3, Comparative Example 5-1, Examples 6-1 to 6-3, Comparative Example 6-1, Examples 7-1 to 7-3, Comparative Example 7-1, Examples 8-1 to 8-3, and Comparative Example 8-1 except that 1% by mass of tri(n-octyl)amine was added to butyl acetate of the developing liquid, and thus, the same results as in Tables 4 and 8 were obtained.

Examples of the ArF liquid immersion exposure are shown in Examples above, but the same effects are also shown with respect to exposure wavelength other than ArF liquid immersion exposure, for example, EUV exposure.

What is claimed is:

1. A pattern peeling method comprising:
a resist film forming step of applying an actinic ray-sensitive or radiation-sensitive resin composition onto a substrate to form a resist film;
an exposing step of exposing the resist film;
a developing step of developing the exposed resist film using a developing liquid containing an organic solvent to form a negative-type pattern; and
a peeling step of peeling the negative-type pattern using the following liquid A or B:
A: a liquid containing a sulfoxide compound and/or an amide compound; or
B: a liquid containing sulfuric acid and hydrogen peroxide.

2. The pattern peeling method according to claim 1, wherein the liquid A is a liquid containing at least one selected from the group consisting of dimethylsulfoxide and N-methylpyrrolidone.

3. The pattern peeling method according to claim 1, wherein the actinic ray-sensitive or radiation-sensitive resin composition contains a resin capable of decreasing the solubility in a developing liquid containing an organic solvent by the action of an acid, and a compound capable of generating an acid by irradiation with actinic rays or radiation.

4. The pattern peeling method according to claim 3, wherein the actinic ray-sensitive or radiation-sensitive resin composition further contains a hydrophobic resin.

5. The pattern peeling method according to claim 1, wherein the organic solvent is butyl acetate.

6. A method for manufacturing an electronic device, including the pattern peeling method according to claim 1.

7. The pattern peeling method according to claim 2, wherein the actinic ray-sensitive or radiation-sensitive resin composition contains a resin capable of decreasing the solubility in a developing liquid containing an organic solvent by the action of an acid, and a compound capable of generating an acid by irradiation with actinic rays or radiation.

8. The pattern peeling method according to claim 2, wherein the organic solvent is butyl acetate.

9. The pattern peeling method according to claim 3, wherein the organic solvent is butyl acetate.

10. The pattern peeling method according to claim 4, wherein the organic solvent s butyl acetate.

11. The pattern peeling method according to claim 7, wherein the organic solvent is butyl acetate.

12. A method for manufacturing an electronic device, including the pattern peeling method according to claim 2.

13. A method for manufacturing an electronic device, including the pattern peeling method according to claim 3.

14. A method for manufacturing an electronic device, including the pattern peeling method according to claim 4.

15. A method for manufacturing an electronic device, including the pattern peeling method according to claim 5.

16. A method for manufacturing an electronic device, including the pattern peeling method according to claim 7.

17. A method for manufacturing an electronic device, including the pattern peeling method according to claim 8.

18. A method for manufacturing an electronic device, including the pattern peeling method according to claim 9.

19. A method for manufacturing an electronic device, including the pattern peeling method according to claim 10.

20. A method for manufacturing an electronic device, including the pattern peeling method according to claim 11.
